(19) United States
(12) Patent Application Publication
(10) Pub. No.: US 2026/0262313 A1
(43) Pub. Date: Sep. 3, 2026

(54) PHOTODETECTION DEVICE AND ELECTRONIC APPARATUS

(71) Applicant: SONY SEMICONDUCTOR SOLUTIONS CORPORATION, KANAGAWA (JP)

(72) Inventors: MIZUKI ONO, KANAGAWA (JP); YUKIHIRO ANDO, KANAGAWA (JP); KOHEI DOI, KANAGAWA (JP)

(21) Appl. No.: 18/878,890

(22) PCT Filed: May 29, 2023
(86) PCT No.: PCT/JP2023/019946

§ 371 Date: Dec. 25, 2024

(30) Foreign Application Priority Data
Jul. 12, 2022 (JP) 2022-111571

(51) Int. Cl. H10F 39/00; H10F 39/18

(52) U.S. Cl. CPC H10F 39/807; H10F 39/014; H10F 39/182; H10F 39/8057; H10F 39/806; H10F 39/8063

(57) ABSTRACT

There is provided a photodetection device capable of relatively easily forming a transmission path of a negative bias. Specifically, a through-trench portion is provided in a region between photoelectric conversion portions of a conductor substrate. Then, a through-trench portion has a first trench portion that is formed on a back surface side of a semiconductor substrate and has an opening portion on the back surface, and a second trench portion that is formed on a front surface side opposite to the back surface and has opening portions respectively on a bottom surface of the first trench portion and the front surface. Furthermore, a width of the first trench portion is wider than a width of the second trench portion. Furthermore, the photodetection device further includes a second conductor portion that is arranged in the second trench portion and includes a second conductor, an insulating film arranged between an inner side surface of the second trench portion and the second conductor portion, and a first conductor portion that is arranged in the first trench portion, is in contact with an end portion of the second conductor portion on the back surface side, and includes a first conductor.

### TECHNICAL FIELD

The present technology (technology according to the present disclosure) relates to a photodetection device and an electronic apparatus.

### BACKGROUND ART

In the related art, for example, there has been proposed a photodetection device including a semiconductor substrate, a photoelectric conversion portion formed in a two-dimensional array on the semiconductor substrate, a through-trench portion formed between the photoelectric conversion portions, a conductor portion disposed in the through-trench portion, an insulating film disposed between an inner side surface of the through-trench portion and the conductor portion, and an inter-pixel light shielding portion formed along the through-trench portion on a light receiving surface side of the semiconductor substrate (for example, refer to Patent Document 1). In the photodetection device disclosed in Patent Document 1, the conductor portion and the inter-pixel light shielding portion are connected through a contact, and it is possible to suppress generation of a dark current by applying a negative bias to the conductor portion from the outside of the pixel region through the inter-pixel light shielding portion and the contact. Furthermore, since the inter-pixel light shielding portion is connected to the conductor portion, a resistance value of a transmission path of the negative bias can be reduced by the amount of the inter-pixel light shielding portion, and IR drop can be suppressed.

### CITATION LIST

PATENT DOCUMENT

Patent Document 1: WO 2020/017344 A

### SUMMARY OF THE INVENTION

### Problems to be Solved by the Invention

In recent years, miniaturization of pixels has progressed, but in the photodetection device disclosed in Patent Document 1, as the miniaturization of pixels progresses, a margin for misalignment between the conductor portion and the contact is decreased, and thus, there is a high possibility that the contact will miss the conductor portion, and it becomes difficult to form connection between the conductor portion and the inter-pixel light shielding portion. Therefore, it is difficult to form a transmission path of a negative bias.

An object of the present disclosure is to provide a photodetection device and an electronic apparatus capable of relatively easily forming a transmission path of a negative bias.

### Solutions to Problems

A photodetection device of the present disclosure includes (a) a semiconductor substrate; (b) a plurality of photoelectric conversion portions formed in a two-dimensional array on the semiconductor substrate; (c) a plurality of microlenses arranged on a first surface side as a light receiving surface of the semiconductor substrate; and (d) a through-trench portion that is formed in at least a part of a region between the photoelectric conversion portions of the semiconductor substrate and penetrates the semiconductor substrate in a thickness direction of the semiconductor substrate, (e) in which the through-trench portion has a first trench portion that is formed on the first surface side of the semiconductor substrate and has an opening portion on the first surface, and a second trench portion that is formed on a second surface side opposite to the first surface and has opening portions respectively on a bottom surface of the first trench portion and the second surface, (f) a width of the first trench portion is wider than a width of the second trench portion, and the photodetection device further includes (g) a first conductor portion that is arranged in the first trench portion and includes a first conductor, (h) a second conductor portion which is arranged in the second trench portion, of which an end portion on the first surface side is in contact with the first conductor portion, and which includes a second conductor different from the first conductor; and (i) an insulating film arranged between an inner side surface of the second trench portion and the second conductor portion.

Another photodetection device of the present disclosure includes (a) a semiconductor substrate; (b) a plurality of photoelectric conversion portions formed in a two-dimensional array on the semiconductor substrate; (c) a plurality of microlenses arranged on a first surface side as a light receiving surface of the semiconductor substrate; (d) a through-trench portion that is formed in at least a part of a region between the photoelectric conversion portions of the semiconductor substrate and penetrates the semiconductor substrate in a thickness direction of the semiconductor substrate; (e) a fixed charge film that is arranged to cover the first surface of the semiconductor substrate; (f) a first conductor portion that is arranged between the fixed charge film and the microlens and includes a first conductor; (g) a second conductor portion which is arranged in the through-trench portion, of which an end portion on the first surface side is in contact with the first conductor portion, and which includes a second conductor different from the first conductor; and (h) an insulating film arranged between an inner side surface of the through-trench portion and the second conductor portion, (i) in which an end portion of the insulating film on the first surface side protrudes from an opening portion on the first surface side of the through-trench portion to the microlens side.

Another photodetection device of the present disclosure includes (a) a semiconductor substrate; (b) a plurality of photoelectric conversion portions formed in a two-dimensional array on the semiconductor substrate; (c) a plurality of microlenses arranged on a first surface side as a light receiving surface of the semiconductor substrate; and (d) a through-trench portion that is formed in at least a part of a region between the photoelectric conversion portions of the semiconductor substrate and penetrates the semiconductor substrate in a thickness direction of the semiconductor substrate, (e) in which the through-trench portion has a first trench portion that is formed on the first surface side of the semiconductor substrate and has an opening portion on the first surface, and a second trench portion that is formed on a second surface side opposite to the first surface and has opening portions respectively on a bottom surface of the first trench portion and the second surface, a width of the first trench portion is wider than a width of a boundary portion of the second trench portion with the first trench portion, and the photodetection device further includes (f)a conductor portion arranged in the first trench portion and the second trench portion; and (g) an insulating film arranged between an inner side surface of the first trench portion and the conductor portion and between an inner side surface of the second trench portion and the conductor portion, (h) the photoelectric conversion portion includes a first conductivity type semiconductor region, and (i) the semiconductor substrate has a pinning region that is formed between the photoelectric conversion portion and the through-trench portion to be continuously along the inner side surface of the first trench portion and the inner side surface of the second trench portion and that includes a semiconductor region of a conductivity type opposite to the first conductivity type.

An electronic apparatus of the present disclosure includes a photodetection device including (a) a semiconductor substrate, (b) a plurality of photoelectric conversion portions formed in a two-dimensional array on the semiconductor substrate, (c) a plurality of microlenses arranged on a first surface side as a light receiving surface of the semiconductor substrate, and (d) a through-trench portion that is formed in at least a part of a region between the photoelectric conversion portions of the semiconductor substrate and penetrates the semiconductor substrate in a thickness direction of the semiconductor substrate, (e) in which the through-trench portion has a first trench portion that is formed on the first surface side of the semiconductor substrate and has an opening portion on the first surface, and a second trench portion that is formed on a second surface side opposite to the first surface and has opening portions respectively on a bottom surface of the first trench portion and the second surface, (f) a width of the first trench portion is wider than a width of the second trench portion, and the photodetection device further includes (g) a first conductor portion that is arranged in the first trench portion and includes a first conductor, (h) a second conductor portion which is arranged in the second trench portion, of which an end portion on the first surface side is in contact with the first conductor portion, and which includes a second conductor different from the first conductor, and (i) an insulating film arranged between an inner side surface of the second trench portion and the second conductor portion.

Another electronic apparatus of the present disclosure includes a photodetection device including (a) a semiconductor substrate, (b) a plurality of photoelectric conversion portions formed in a two-dimensional array on the semiconductor substrate, (c) a plurality of microlenses arranged on a first surface side as a light receiving surface of the semiconductor substrate, (d) a through-trench portion that is formed in at least a part of a region between the photoelectric conversion portions of the semiconductor substrate and penetrates the semiconductor substrate in a thickness direction of the semiconductor substrate, (e) a fixed charge film that is arranged to cover the first surface of the semiconductor substrate, (f) a first conductor portion that is arranged between the fixed charge film and the microlens and includes a first conductor, (g) a second conductor portion which is arranged in the through-trench portion, of which an end portion on the first surface side is in contact with the first conductor portion, and which includes a second conductor different from the first conductor, and (h) an insulating film arranged between an inner side surface of the through-trench portion and the second conductor portion, (i) in which an end portion of the insulating film on the first surface side protrudes from an opening portion on the first surface side of the through-trench portion to the microlens side.

Another electronic apparatus of the present disclosure includes a photodetection device including (a) a semiconductor substrate, (b) a plurality of photoelectric conversion portions formed in a two-dimensional array on the semiconductor substrate, (c) a plurality of microlenses arranged on a first surface side as a light receiving surface of the semiconductor substrate, and (d) a through-trench portion that is formed in at least a part of a region between the photoelectric conversion portions of the semiconductor substrate and penetrates the semiconductor substrate in a thickness direction of the semiconductor substrate, (e) in which the through-trench portion has a first trench portion that is formed on the first surface side of the semiconductor substrate and has an opening portion on the first surface, and a second trench portion that is formed on a second surface side opposite to the first surface and has opening portions respectively on a bottom surface of the first trench portion and the second surface, a width of the first trench portion is wider than a width of a boundary portion of the second trench portion with the first trench portion, and the photodetection device further includes (f) a conductor portion arranged in the first trench portion and the second trench portion, and (g) an insulating film arranged between an inner side surface of the first trench portion and the conductor portion and between an inner side surface of the second trench portion and the conductor portion, (h) the photoelectric conversion portion includes a first conductivity type semiconductor region, and (i) the semiconductor substrate has a pinning region that is formed between the photoelectric conversion portion and the through-trench portion to be continuously along the inner side surface of the first trench portion and the inner side surface of the second trench portion and that includes a semiconductor region of a conductivity type opposite to the first conductivity type.

### BRIEF DESCRIPTION OF DRAWINGS

FIG. 1 is a diagram illustrating an overall configuration of a solid-state imaging device according to a first embodiment.

FIG. 2 is a diagram illustrating a sectional configuration of the solid-state imaging device in a case of being cut along a line A-A′ of FIG. 1.

FIG. 3 is a diagram illustrating a planar configuration of a first trench portion and a second trench portion in a B region of FIG. 1.

FIG. 4 is a diagram illustrating a sectional configuration of a solid-state imaging device according to a modification example.

FIG. 5A is a diagram illustrating a manufacturing method for a solid-state imaging device.

FIG. 5B is a diagram illustrating the manufacturing method for the solid-state imaging device.

FIG. 5C is a diagram illustrating the manufacturing method for the solid-state imaging device.

FIG. 5D is a diagram illustrating the manufacturing method for the solid-state imaging device.

FIG. 5E is a diagram illustrating the manufacturing method for the solid-state imaging device.

FIG. 5F is a diagram illustrating the manufacturing method for the solid-state imaging device.

FIG. 5G is a diagram illustrating the manufacturing method for the solid-state imaging device.

FIG. 6 is a diagram illustrating a sectional configuration of a solid-state imaging device according to a modification example.

FIG. 7 is a diagram illustrating a planar configuration of a first trench portion and a second trench portion illustrated in FIG. 6.

FIG. 8 is a diagram illustrating a sectional configuration of a solid-state imaging device according to a modification example.

FIG. 9 is a diagram illustrating a planar configuration of a first trench portion and a second trench portion illustrated in FIG. 8.

FIG. 10 is a diagram illustrating a planar configuration of a first trench portion and a second trench portion of a solid-state imaging device according to a modification example.

FIG. 11 is a diagram illustrating a sectional configuration of a solid-state imaging device 1 in a case of being cut along a line C-C′ of FIG. 10.

FIG. 12 is a diagram illustrating a planar configuration of a first trench portion and a second trench portion of a solid-state imaging device according to a modification example.

FIG. 13 is a diagram illustrating a sectional configuration of the solid-state imaging device 1 in a case of being cut along a line D-D′ of FIG. 12.

FIG. 14 is a diagram illustrating a planar configuration of a first trench portion, a second trench portion, and a third conductor portion of a solid-state imaging device according to a modification example.

FIG. 15 is a diagram illustrating a sectional configuration of a solid-state imaging device according to a modification example.

FIG. 16 is a diagram illustrating a sectional configuration of a solid-state imaging device according to a second embodiment.

FIG. 17 is a diagram illustrating a sectional configuration of a solid-state imaging device according to a modification example.

FIG. 18A is a diagram illustrating a manufacturing method for a solid-state imaging device.

FIG. 18B is a diagram illustrating the manufacturing method for the solid-state imaging device.

FIG. 18C is a diagram illustrating the manufacturing method for the solid-state imaging device.

FIG. 18D is a diagram illustrating the manufacturing method for the solid-state imaging device.

FIG. 18E is a diagram illustrating the manufacturing method for the solid-state imaging device.

FIG. 18F is a diagram illustrating the manufacturing method for the solid-state imaging device.

FIG. 19 is a diagram illustrating a sectional configuration of a solid-state imaging device according to a modification example.

FIG. 20 is a diagram illustrating a sectional configuration of a solid-state imaging device according to a modification example.

FIG. 21 is a diagram illustrating a sectional configuration of a solid-state imaging device according to a modification example.

FIG. 22 is a diagram illustrating a sectional configuration of a solid-state imaging device according to a modification example.

FIG. 23 is a diagram illustrating a sectional configuration of a solid-state imaging device according to a modification example.

FIG. 24 is a diagram illustrating a sectional configuration of a solid-state imaging device according to a modification example.

FIG. 25 is a diagram illustrating a sectional configuration of a solid-state imaging device according to a modification example.

FIG. 26 is a diagram illustrating a sectional configuration of a solid-state imaging device according to a modification example.

FIG. 27 is a diagram illustrating a planar configuration of a through-trench portion illustrated in FIGS. 25 and 26.

FIG. 28 is a diagram illustrating a sectional configuration of a solid-state imaging device according to a modification example.

FIG. 29 is a diagram illustrating a planar configuration of a through-trench portion illustrated in FIG. 28.

FIG. 30 is a diagram illustrating a sectional configuration of a solid-state imaging device according to a modification example.

FIG. 31 is a diagram illustrating a sectional configuration of a solid-state imaging device according to a third embodiment.

FIG. 32 is a diagram illustrating a planar configuration of a first trench portion in a B region of FIG. 1.

FIG. 33 is a diagram illustrating a sectional configuration of a cross portion and a slit portion.

FIG. 34A is a diagram illustrating a manufacturing method for a solid-state imaging device.

FIG. 34B is a diagram illustrating the manufacturing method for the solid-state imaging device.

FIG. 34C is a diagram illustrating the manufacturing method for the solid-state imaging device.

FIG. 34D is a diagram illustrating the manufacturing method for the solid-state imaging device.

FIG. 34E is a diagram illustrating the manufacturing method for the solid-state imaging device.

FIG. 34F is a diagram illustrating the manufacturing method for the solid-state imaging device.

FIG. 34G is a diagram illustrating the manufacturing method for the solid-state imaging device.

FIG. 34H is a diagram illustrating the manufacturing method for the solid-state imaging device.

FIG. 34I is a diagram illustrating the manufacturing method for the solid-state imaging device.

FIG. 34J is a diagram illustrating the manufacturing method for the solid-state imaging device.

FIG. 34K is a diagram illustrating the manufacturing method for the solid-state imaging device.

FIG. 34L is a diagram illustrating the manufacturing method for the solid-state imaging device.

FIG. 34M is a diagram illustrating the manufacturing method for the solid-state imaging device.

FIG. 35 is a diagram illustrating a sectional configuration of a solid-state imaging device according to a modification example.

FIG. 36 is a diagram illustrating a sectional configuration of a solid-state imaging device according to a modification example.

FIG. 37 is a diagram illustrating a sectional configuration of a solid-state imaging device according to a modification example.

FIG. 38 is a diagram illustrating a schematic configuration of an electronic apparatus according to a fourth embodiment.

### MODE FOR CARRYING OUT THE INVENTION

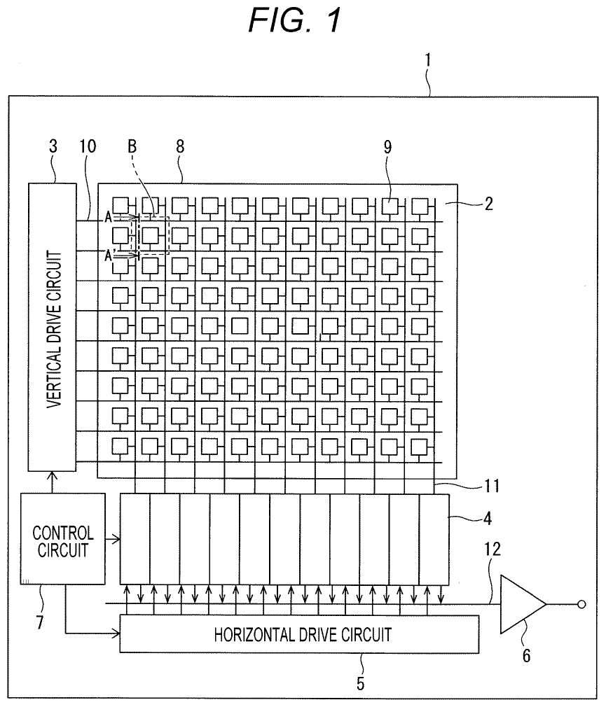

Hereinafter, an example of a photodetection device and an electronic apparatus according to embodiments of the present disclosure will be described with reference to FIGS. 1 to 38. The embodiments of the present disclosure will be described in the following order. Note that, the present disclosure is not limited to the following examples. Furthermore, the effects described in the present specification are illustrative and are not restrictive, and there may be additional effects.
1. First embodiment: solid-state imaging device
1-1 Overall configuration of solid-state imaging device
1-2 Configuration of main part
1-3 Manufacturing method for solid-state imaging device
1-4 Modification example
2. Second embodiment: solid-state imaging device
2-1 Configuration of main part
2-2 Manufacturing method for solid-state imaging device
2-3 Modification example
3. Third embodiment: solid-state imaging device
3-1 Configuration of main part
3-2 Manufacturing method for solid-state imaging device
3-3 Modification example
4. Fourth embodiment: application example to electronic apparatus

### 1. First Embodiment: Solid-State Imaging Device

### 1-1 Overall Configuration Of Solid-State Imaging Device

A solid-state imaging device 1 (“photodetection device” in a broad sense) according to a first embodiment of the present disclosure will be described. FIG. 1 is a diagram illustrating an overall configuration of a solid-state imaging device 1 according to a first embodiment.

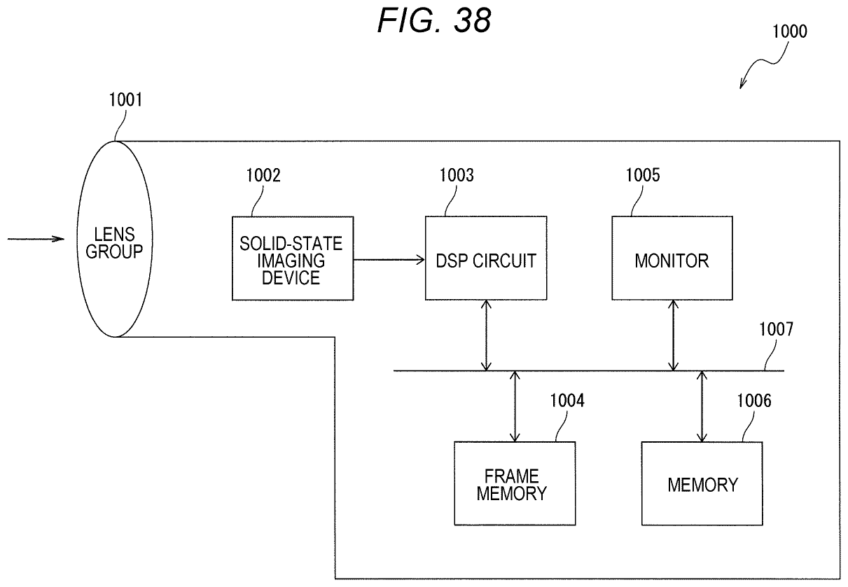

The solid-state imaging device 1 in FIG. 1 is a back-illuminated complementary metal oxide semiconductor (CMOS) image sensor. As illustrated in FIG. 38, the solid-state imaging device 1 (1002) captures image light (incident light) from a subject through a lens group 1001, converts the amount of incident light that is imaged on an imaging surface, into an electrical signal in units of pixels, and outputs the signal as a pixel signal.

As illustrated in FIG. 1, the solid-state imaging device 1 includes a pixel region 2, a vertical drive circuit 3, a column signal processing circuit 4, a horizontal drive circuit 5, an output circuit 6, and a control circuit 7.

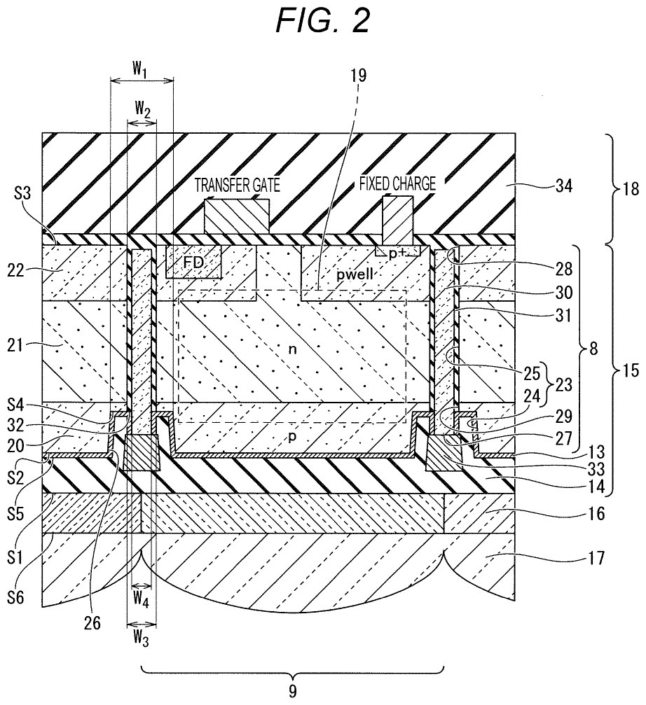

The pixel region 2 includes a plurality of pixels 9 arranged in a two-dimensional array, on a semiconductor substrate 8. Each pixel 9 includes a photoelectric conversion portion 19 illustrated in FIG. 2, and a plurality of pixel transistors. Examples of the plurality of pixel transistors include a transfer transistor, a reset transistor, an amplification transistor, and a selection transistor.

The vertical drive circuit 3 includes, for example, a shift register, selects a desired pixel drive wiring 10, supplies a pulse for driving the pixel 9 to the selected pixel drive wiring 10, and drives the pixels 9 in units of rows. That is, the vertical drive circuit 3 selectively scans each pixel 9 in the pixel region 2 sequentially in a vertical direction in units of rows, and supplies a pixel signal based on a signal charge generated in accordance with an amount of received light in the photoelectric conversion portion 19 of each pixel 9, to the column signal processing circuit 4 through a vertical signal line 11.

The column signal processing circuit 4 is arranged, for example, for each column of the pixels 9, and performs signal processing such as noise removal on signals output from the pixels 9 of one row for each pixel column. For example, the column signal processing circuit 4 performs signal processing such as correlated double sampling (CDS) for removing a fixed pattern noise unique to pixels, and analog-digital (AD) conversion.

The horizontal drive circuit 5 includes, for example, a shift register, sequentially outputs a horizontal scanning pulse to the column signal processing circuit 4, sequentially selects each of the column signal processing circuits 4, and causes each of the column signal processing circuits 4 to output the pixel signal subjected to the signal processing, to a horizontal signal line 12.

The output circuit 6 performs signal processing on the pixel signal sequentially supplied from each of the column signal processing circuits 4 through the horizontal signal line 12, and outputs the pixel signal. As the signal processing, for example, buffering, black level adjustment, column variation correction, various types of digital signal processing and the like can be used.

The control circuit 7 generates a control signal and a clock signal as a reference for operations of the vertical drive circuit 3, the column signal processing circuit 4, the horizontal drive circuit 5, and the like, on the basis of a vertical synchronization signal, a horizontal synchronization signal, and a master clock signal. Then, the control circuit 7 outputs the generated clock signal and control signal to the vertical drive circuit 3, the column signal processing circuit 4, the horizontal drive circuit 5, and the like.

### 1-2 Configuration of Main Part

Next, a detailed structure of the solid-state imaging device 1 will be described. FIG. 2 is a diagram illustrating a sectional configuration of the solid-state imaging device 1 in a case of being cut along a line A-A′ of FIG. 1.

As illustrated in FIG. 2, in the solid-state imaging device 1, a light receiving layer 15 is arranged in which the semiconductor substrate 8, a fixed charge film 13, and an insulating film 14 are stacked in this order. Furthermore, a plurality of color filters 16 and a plurality of microlenses 17 arranged in a two-dimensional array are arranged in this order on a surface (hereinafter, also referred to as a “back surface S1”) of the light receiving layer 15 on the insulating film 14 side so as to correspond to the respective pixels 9. That is, the plurality of microlenses 17 is arranged on the light receiving surface (hereinafter, also referred to as a “back surface S2”, and a “first surface” in a broad sense) side of the semiconductor substrate 8. Moreover, a wiring layer 18 is arranged on a surface (hereinafter, also referred to as a “front surface S3”) of the light receiving layer 15 on the semiconductor substrate 8 side. Note that, in the following description, a surface (a “second surface” in a broad sense) on a side opposite to the light receiving surface of the semiconductor substrate 8 is also referred to as the “front surface S3”.

The semiconductor substrate 8 includes, for example, a silicon (Si) substrate. In the semiconductor substrate 8, the photoelectric conversion portion 19 is formed in each region of each pixel 9. That is, the photoelectric conversion portion 19 is formed in a two-dimensional array on the semiconductor substrate 8. In the photoelectric conversion portion 19, a p-type semiconductor region 20, an n-type semiconductor region 21, and a p-well region 22 are formed in this order from the back surface S2 side to the front surface S3 side of the semiconductor substrate 8. Then, the photoelectric conversion portion 19 constitutes a photodiode by a p-n junction, and generates a charge corresponding to the amount of received light. Furthermore, the photoelectric conversion portion 19 accumulates charges generated by the photoelectric conversion in electrostatic capacitance (junction capacitance) generated in the p-n junction.

Furthermore, in the semiconductor substrate 8, a through-trench portion 23 is formed in at least a part of regions between the photoelectric conversion portions 19. FIG. 2 illustrates a case where the through-trench portion 23 is formed in both a region extending along a row direction and a region extending along a column direction of the two-dimensional array of the photoelectric conversion portions 19 in the regions between the photoelectric conversion portions 19 of the semiconductor substrate 8. That is, the through-trench portions 23 are formed in a lattice shape in all the regions between the photoelectric conversion portions 19. The through-trench portion 23 is formed to penetrate the semiconductor substrate 8 in a thickness direction of the semiconductor substrate 8. The through-trench portion 23 includes a first trench portion 24 formed on the back surface S2 side of the semiconductor substrate 8, and a second trench portion 25 formed on the front surface S3 side of the semiconductor substrate 8. The first trench portion 24 has an opening portion 26 on the back surface S2 of the semiconductor substrate 8, and is formed in a depth direction of the semiconductor substrate 8 from the opening portion 26. Furthermore, the second trench portion 25 has an opening portion 28 on the front surface S3 of the semiconductor substrate 8 and an opening portion 29 on a bottom surface S4 of the first trench portion 24, and is formed in the depth direction of the semiconductor substrate 8 from the opening portion 28. Furthermore, a width W₁ of the first trench portion 24 is larger than a width W₂ of the second trench portion 25. Preferably, the width W₁ of the first trench portion 24 is larger than the width W₂ of the second trench portion 25 by 100 nm or more.

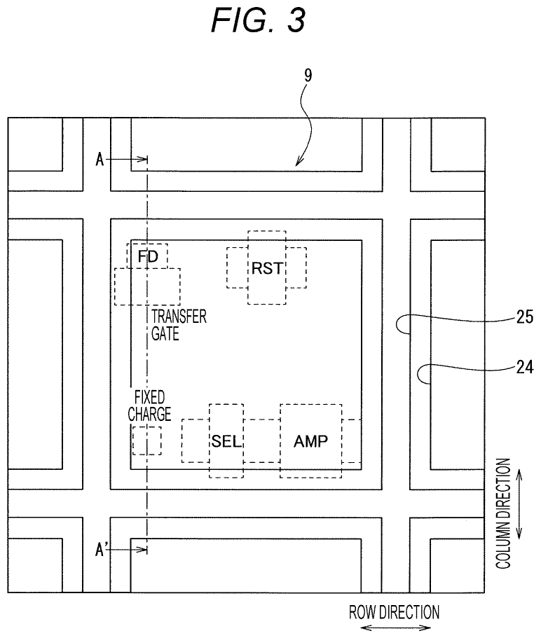

Furthermore, as illustrated in FIG. 3, in a case of being viewed from the thickness direction of the semiconductor substrate 8, the center of the second trench portion 25 in a width direction is positioned to overlap the center of the first trench portion 24 in the width direction. FIG. 3 is a diagram illustrating a planar configuration of the first trench portion 24 and the second trench portion 25 in a B region of FIG. 1. In FIG. 3, other configurations such as the microlens 17 are omitted.

A second conductor portion 30 including a predetermined conductor (hereinafter, also referred to as a “second conductor”) is arranged inside the second trench portion 25 from the front surface S3 side of the semiconductor substrate 8 to the bottom surface S4 side of the first trench portion 24. In a case of being viewed from the thickness direction of the semiconductor substrate 8, the second conductor portion 30 is formed in the same lattice shape as the through-trench portion 23 so as to surround each photoelectric conversion portion 19. Therefore, by applying a negative bias to the second conductor portion 30, the second trench portion 25 side of the photoelectric conversion portion 19 can be brought into a high hole concentration state (hole accumulation state), and generation of a dark current around the through-trench portion 23 can be suppressed. An end portion 27 of the second conductor portion 30 on the back surface S2 side protrudes from the opening portion 29 of the second trench portion 25 on the bottom surface S4 side to the microlens 17 side. Therefore, the end portion 27 of the second conductor portion 30 is positioned in the first trench portion 24 (between the opening portion 26 and the bottom surface S4 of the first trench portion 24), and is electrically connected to a first conductor portion 33 by being in contact with the first conductor portion 33.

As a material (second conductor) of the second conductor portion 30, for example, polysilicon to which at least one of phosphorus (P) and boron (B) is added can be adopted. Here, for example, in a case where a metal such as tungsten or aluminum is used as the second conductor, since the metal has a high light absorption rate, the quantum efficiency QE may be decreased. Furthermore, in a case where a metal is used, the metal may diffuse into the photoelectric conversion portion 19. On the other hand, in the first embodiment, by using polysilicon to which phosphorus or boron is added as the second conductor, since the light absorption rate is low, a decrease in the quantum efficiency QE can be suppressed, and diffusion of the metal into the photoelectric conversion portion 19 can be prevented.

An insulating film 31 is arranged between the inner side surface of the second trench portion 25 and the second conductor portion 30. The insulating film 31 covers the entire inner side surface of the second trench portion 25. Therefore, the insulating film 31 electrically insulates the second conductor portion 30 from the photoelectric conversion portion 19. An end portion 32 of the insulating film 31 on the back surface S2 side is positioned in the same plane as the bottom surface S4 of the first trench portion 24. Furthermore, as a material of the insulating film 31, for example, silicon oxide (SiO₂) can be adopted.

The first conductor portion 33 including a predetermined conductor (hereinafter, also referred to as a “first conductor”) different from the second conductor is arranged inside the first trench portion 24. In a case of being viewed from the thickness direction of the semiconductor substrate 8, the first conductor portion 33 is formed in the same lattice shape as the through-trench portion 23 and the second conductor portion 30 so as to surround each photoelectric conversion portion 19. In the first trench portion 24, the first conductor portion 33 is in contact with the end portion 27 of the second conductor portion 30 protruding from the opening portion 26 of the second trench portion 25 on the bottom surface S4 side. That is, the first conductor portion 33 covers the end portion 27 of the second conductor portion 30, and is electrically connected to the second conductor portion 30. Therefore, the first conductor portion 33 functions as a lattice-shaped wiring connected to each portion of the second conductor portion 30, a resistance value of a transmission path of a negative bias can be reduced as a whole, and a potential drop (IR drop) of the negative bias due to a resistance component of the transmission path can be suppressed. Therefore, it is possible to suppress deterioration of shading characteristics in the pixel 9 far from the outer periphery of the pixel region 2, that is, the pixel 9 in a central portion of the pixel region 2.

Furthermore, the first conductor portion 33 also functions as an inter-pixel light shielding portion that prevents light from entering the end portion 27 by covering the end portion 27 of the second conductor portion 30. Furthermore, a width W₃ of the first conductor portion 33 is larger than a width W₄ of the second conductor portion 30. For example, the width W₃ of the first conductor portion 33 is designed to be a width such that the first conductor portion 33 does not step off the second conductor portion 30 and the side surface of the first conductor portion 33 is not in contact with the inner side surface of the first trench portion 24 even in a case where misalignment occurs between the first conductor portion 33 and the second conductor portion 30 at the time of manufacturing.

As a material (first conductor) of the first conductor portion 33, for example, a material having a resistivity lower than that of the material (second conductor) of the second conductor portion 30 can be adopted. Therefore, the resistance value of the first conductor portion 33 can be reduced, and the potential drop (IR drop) of the negative bias applied from the outside of the pixel region 2 can be more appropriately suppressed. Therefore, it is possible to more appropriately suppress deterioration of shading characteristics in the pixel 9 far from the outer periphery of the pixel region 2, that is, the pixel 9 in the central portion of the pixel region 2. Examples of the material having a resistivity lower than that of the second conductor include a metal material (tungsten (W), aluminum (Al), copper (Cu), and the like) and indium tin oxide (ITO).

The fixed charge film 13 continuously covers the back surface S2 of the semiconductor substrate 8 (the back surface S2 of the photoelectric conversion portion 19) and the inner surface (inner side surface, bottom surface S4) of the first trench portion 24. That is, in a case of being viewed from the thickness direction of the semiconductor substrate 8, the fixed charge films 13 are arranged in the same two-dimensional array as the photoelectric conversion portions 19 to overlap the respective photoelectric conversion portions 19. Therefore, the back surface S2 side of the photoelectric conversion portion 19 can be brought into a high hole concentration state (hole accumulation state), and generation of the dark current can be suppressed. In FIG. 2, the fixed charge film 13 also covers the side surface of the second conductor portion 30 protruding from the opening portion 26 on the bottom surface S4 side. As a material of the fixed charge film 13, for example, a high refractive index material film or a high dielectric film having a negative charge, which can generate fixed charges and enhance pinning by being formed on the semiconductor substrate 8, can be adopted. For example, an oxide or nitride containing at least one element of hafnium (Hf), aluminum (Al), zirconium (Zr), tantalum (Ta), or titanium (Ti) is exemplified. In particular, hafnium oxide (HfO₂) is more preferable from the viewpoint that the formation on the semiconductor substrate 8 can suppress the generation of blisters and hardly causes peeling from a planar portion of the semiconductor substrate 8.

The insulating film 14 is arranged on a back surface S5 side of the fixed charge film 13, and continuously covers the back surface S5 of the fixed charge film 13 and the first conductor portion 33 such that the entire back surface S1 side of the light receiving layer 15 is a flat surface. As a material of the insulating film 14, for example, silicon oxide (SiO₂) can be adopted.

In a case of being viewed from the microlens 17 side, the color filter 16 is arranged on the back surface S1 side of the insulating film 14, at a position overlapping each photoelectric conversion portion 19. That is, one color filter 16 is formed for one photoelectric conversion portion 19. As the color filter 16, for example, a plurality of types of filters that transmits light of a predetermined wavelength included in light collected by the microlens 17 can be adopted. Therefore, each of the plurality of color filters 16 transmits light of a predetermined wavelength corresponding to the color filter 16, and causes the transmitted light to be incident on the photoelectric conversion portion 19.

The microlens 17 is arranged on the back surface S6 side of the color filter 16, at a position overlapping each photoelectric conversion portion 19. That is, one microlens 17 is formed for one photoelectric conversion portion 19. Therefore, each microlens 17 condenses image light (incident light) from a subject, and causes the condensed incident light to be incident on the corresponding photoelectric conversion portion 19.

The wiring layer 18 is arranged on the front surface S3 side of the semiconductor substrate 8. The wiring layer 18 has an interlayer insulating film 34 and wiring (not illustrated) stacked in a plurality of layers with the interlayer insulating film 34 interposed therebetween. Then, the wiring layer 18 drives the pixel transistor forming each pixel 9 through the plurality of layers of wiring.

In the solid-state imaging device 1 having the above configuration, light is emitted from the back surface S2 side of the semiconductor substrate 8, the emitted light passes through the microlens 17 and the color filter 16, and the transmitted light is photoelectrically converted by the photoelectric conversion portion 19 to generate a signal charge. Then, the generated signal charge is output as the pixel signal from the vertical signal line 11 in FIG. 1 formed by the wiring of the wiring layer 18.

Furthermore, in the solid-state imaging device 1 according to the first embodiment, the width W₁ of the first trench portion 24 is made larger than the width W₂ of the second trench portion 25. Therefore, the width W₃ of the first conductor portion 33 arranged in the first trench portion 24 can be increased, and the possibility that the first conductor portion 33 steps off the second conductor portion 30 at the connection point between the first conductor portion 33 and the second conductor portion 30 can be reduced. Therefore, the first conductor portion 33 and the second conductor portion 30 can be relatively easily connected. Therefore, the transmission path of the negative bias can be relatively easily formed.

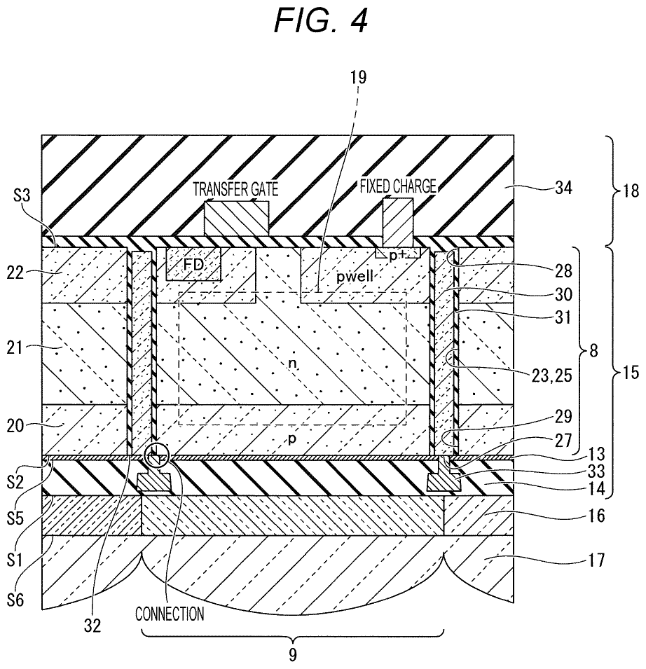

Here, for example, as illustrated in FIG. 4, a case will be considered in which the first trench portion 24 is omitted, the second trench portion 25 penetrates the semiconductor substrate 8 in the thickness direction of the semiconductor substrate 8, and the end portion 27 of the second conductor portion 30 on the back surface S2 side is positioned in the same plane as the back surface S2 of the semiconductor substrate 8. In this case, in a case where the first conductor portion 33 is shifted at the connection point between the first conductor portion 33 and the second conductor portion 30, the first conductor portion 33 is connected to the semiconductor substrate 8, and a leakage current may be generated.

On the other hand, in the first embodiment, the end portion 27 of the second conductor portion 30 on the back surface S2 side protrudes from the opening portion 29 on the bottom surface S4 side of the first trench portion 24 to the microlens 17 side. Then, the first conductor portion 33 is in contact with the end portion 27 of the second conductor portion 30 on the back surface S2 side protruding from the opening portion 26 on the bottom surface S4 side in the first trench portion 24. Therefore, even in a case where misalignment between the first conductor portion 33 and the second conductor portion 30 occurs at the time of connection between the first conductor portion 33 and the second conductor portion 30, it is possible to prevent the semiconductor substrate 8 and the second conductor portion 30 from being electrically connected, and to suppress the leakage current.

### 1-3 Manufacturing Method for Solid-State Imaging Device

Next, the manufacturing method for the solid-state imaging device 1 will be described.

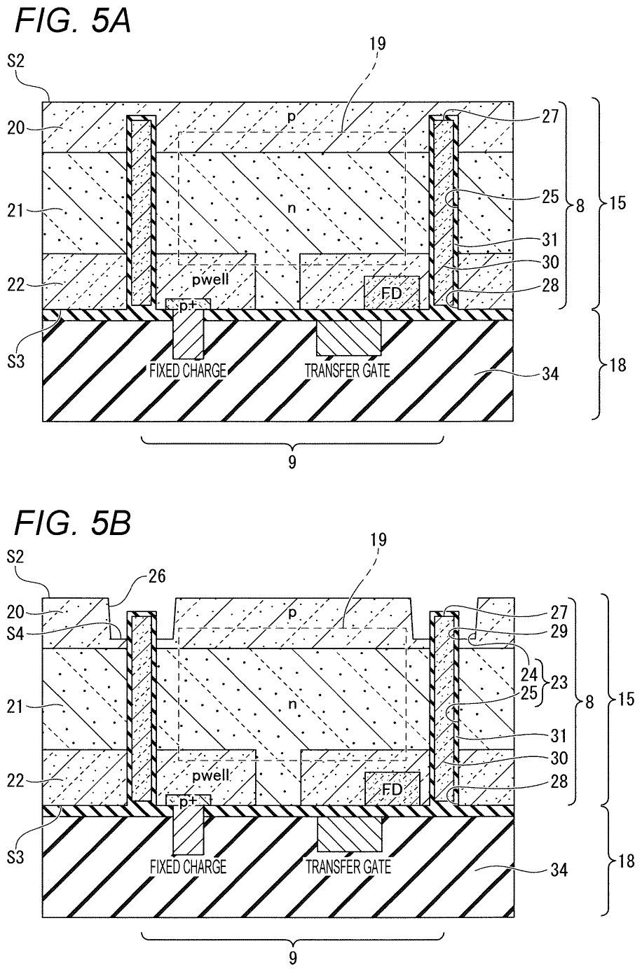

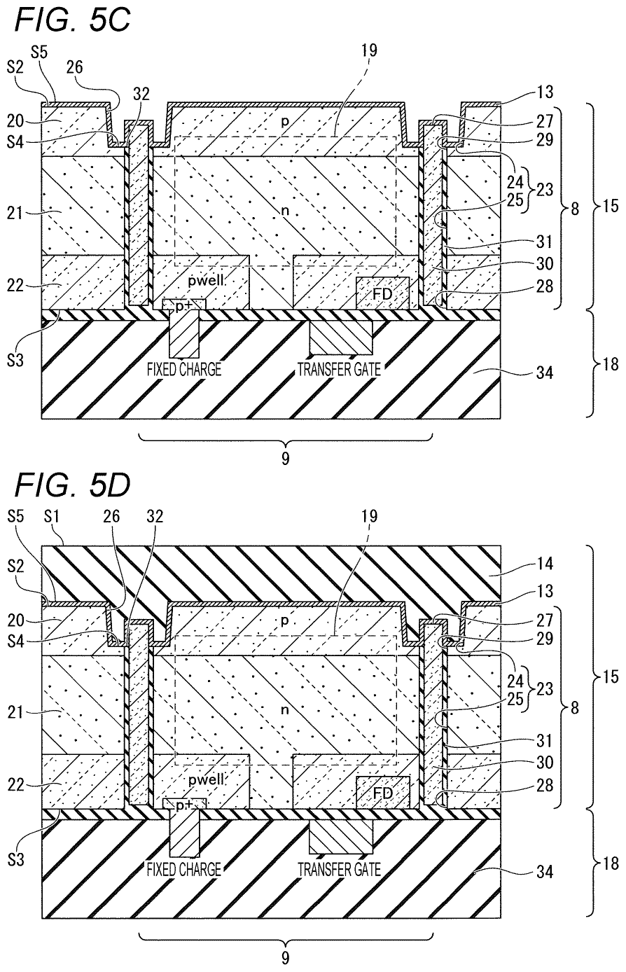

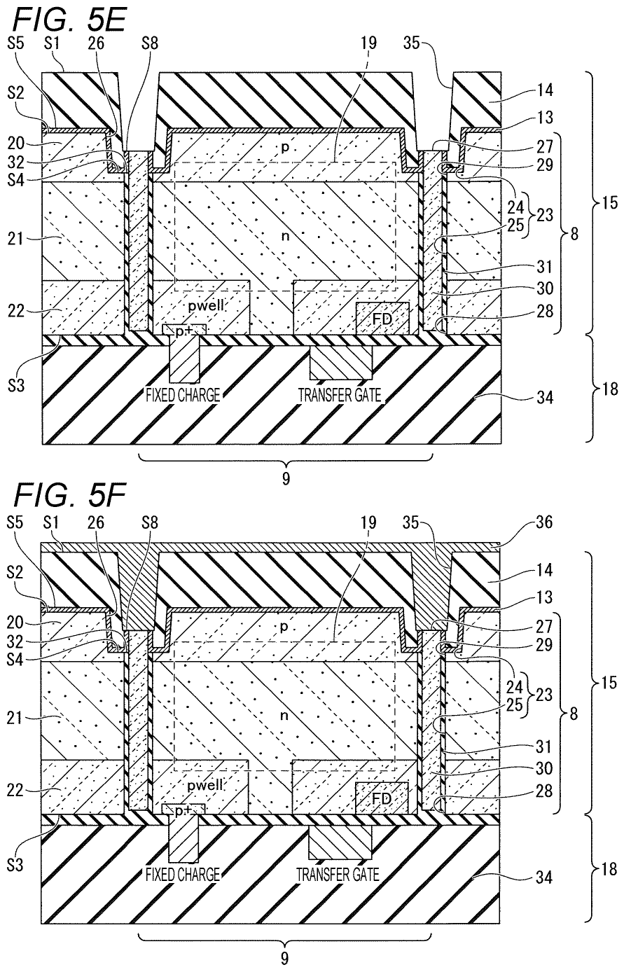

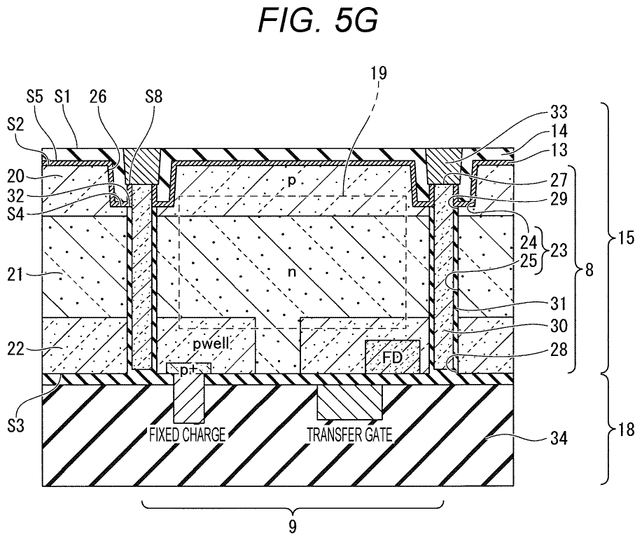

First, as illustrated in FIG. 5A, the semiconductor substrate 8 in which the photoelectric conversion portion 19, the second trench portion 25, the insulating film 31, and the second conductor portion 30 are formed and thinned is prepared. As the second trench portion 25, a bottomed trench portion dug from the front surface S3 side of the semiconductor substrate 8 is formed. Furthermore, a bottom surface S7 of the second trench portion 25 is formed at a position (position on the back surface S2 side) deeper than the opening portion 29 of the second trench portion 25 of the solid-state imaging device 1 illustrated in FIG. 2. As a method of thinning, for example, a method disclosed in Japanese Patent Application Laid-Open No. 2011-96851 can be adopted.

Subsequently, as illustrated in FIG. 5B, by using a lithography method and a dry etching method, etching is performed on the back surface S2 side of the semiconductor substrate 8 to form the first trench portion 24 on the back surface S2 side of the semiconductor substrate 8. Furthermore, the bottom surface S4 of the first trench portion 24 is formed at a position (position on the front surface S3 side) deeper than the bottom surface S7 of the second trench portion 25 illustrated in FIG. 5A. At that time, the insulating film 31 and the second conductor portion 30 are left as they are without being etched, and the end portion 27 of the second conductor portion 30 covered with the insulating film 14 protrudes from the bottom surface S4 of the first trench portion 24.

Subsequently, as illustrated in FIG. 5C, after the insulating film 14 is removed from the end portion 27 of the second conductor portion 30 protruding from the opening portion 26 on the bottom surface S4 side, the fixed charge film 13 is formed on the back surface S2 side of the semiconductor substrate 8. The fixed charge film 13 is formed to continuously cover the back surface S2 of the semiconductor substrate 8, the inner surface (inner side surface, bottom surface S4) of the second trench portion 25, and the end portion 27 of the second conductor portion 30. Subsequently, as illustrated in FIG. 5D, after the insulating film 14 is formed on the back surface S5 side of the fixed charge film 13, the back surface S1 side of the insulating film 14 is planarized by using a chemical mechanical polishing (CMP) method. The insulating film 14 is formed by filling the inside of the first trench portion 24 with the insulating film 14.

Subsequently, as illustrated in FIG. 5E, by using a lithography method and a dry etching method, etching is performed on the back surface S1 side of the insulating film 14 to form a groove 35 at a position where the first conductor portion 33 is to be formed. The groove 35 is formed such that the end portion 27 of the second conductor portion 30 is exposed from a bottom surface S8 of the groove 35. Subsequently, as illustrated in FIG. 5F, by using a physical vapor deposition (PVD) method, a conductor layer 36 including a material (for example, tungsten (W)) of the first conductor portion 33 is formed on the back surface S1 side of the insulating film 14. The conductor layer 36 is formed such that the inside of the groove 35 is filled with the conductor layer 36. Subsequently, as illustrated in FIG. 5G, by using the CMP method, the conductor layer 36 and the insulating film 14 on the back surface S1 side are removed to form the first conductor portion 33. The first conductor portion 33 is connected to the end portion 27 of the second conductor portion 30 on the bottom surface S8 of the groove 35.

Subsequently, as illustrated in FIG. 2, after a portion of the insulating film 14 on the back surface S1 side is formed, the color filter 16 and the microlens 17 are formed in this order on the back surface S1 side of the insulating film 14.

The solid-state imaging device 1 illustrated in FIG. 2 is manufactured by such a procedure.

### 1-4 Modification Example

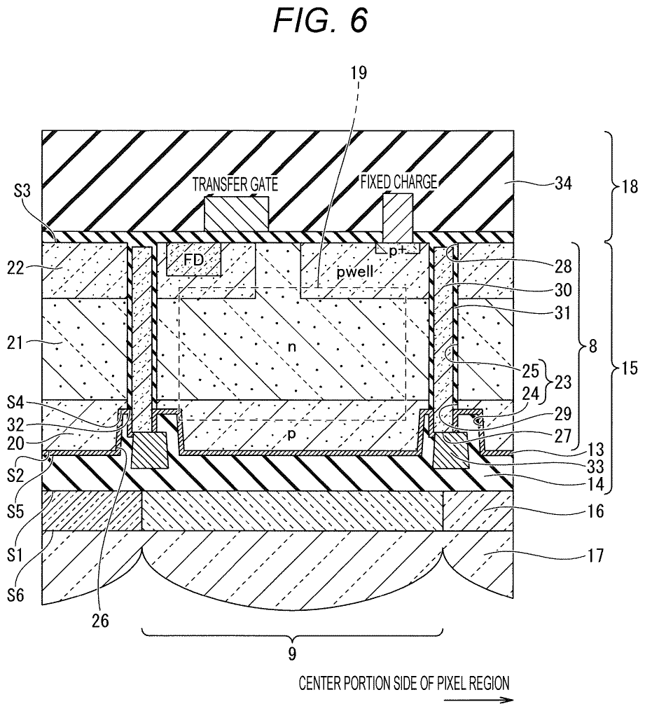

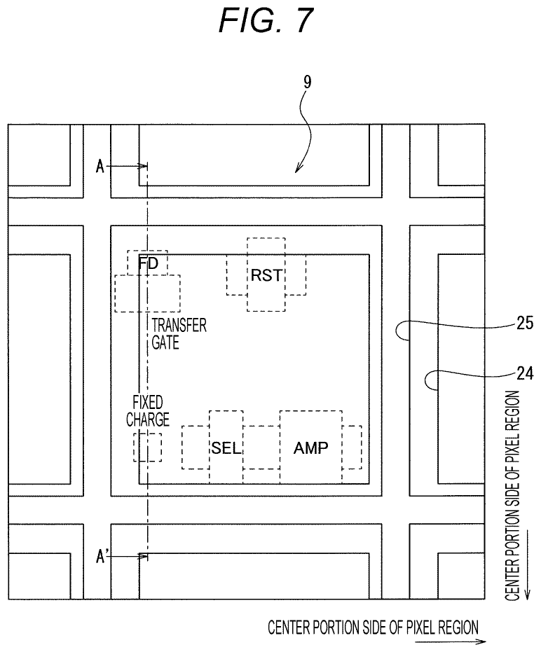

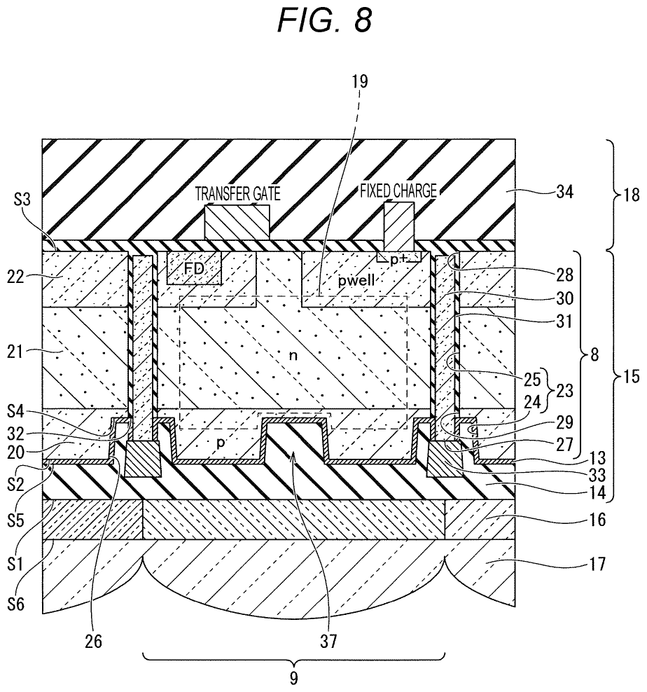

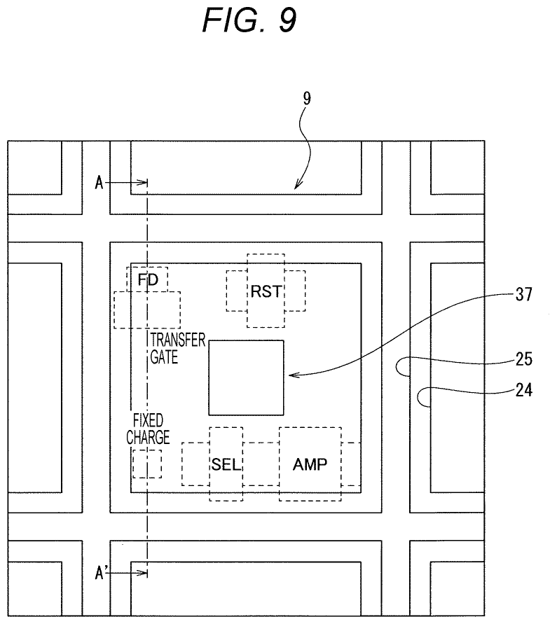

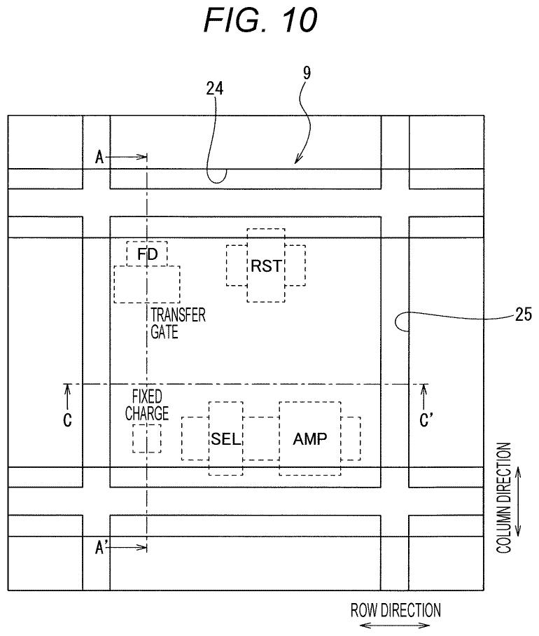

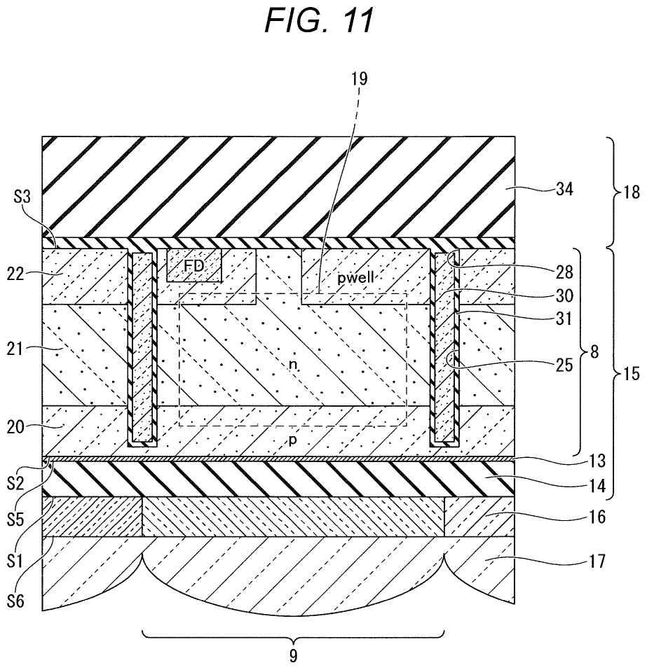

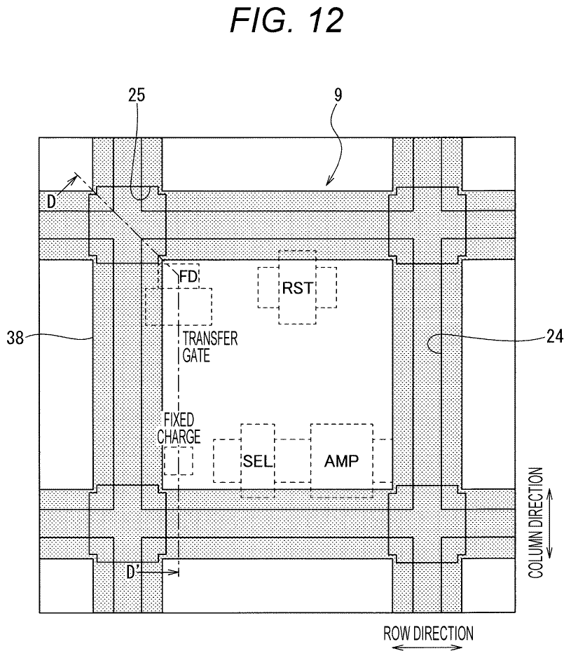

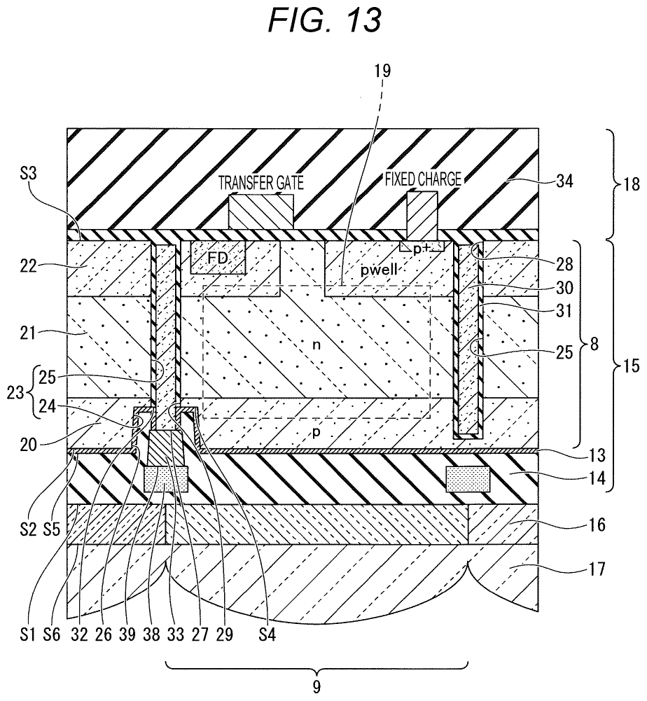

(1) Note that, in the first embodiment, an example has been described in which, in a case of being viewed from the thickness direction of the semiconductor substrate 8, the center of the first trench portion 24 in the width direction and the center of the second trench portion 25 in the width direction overlap each other, but other configurations can also be adopted. For example, as illustrated in FIGS. 6 and 7, the center of the first trench portion 24 in the width direction may be shifted from the center of the second trench portion 25 in the width direction. As an example, in a case of being viewed from the thickness direction of the semiconductor substrate 8, each of the center of the first trench portion 24 in the width direction and the center of the first conductor portion 33 in the width direction may be positioned closer to the center portion side of the pixel region 2 (two-dimensional array of pixels 9) than the center of the second trench portion 25 in the width direction. Therefore, on the end portion side (high image height side) of the pixel region 2, the incident light can be suppressed from being blocked by the first conductor portion 33, and output variation between the pixel 9 on the center portion side (low image height side) and the pixel 9 on the high image height side of the pixel region 2 can be suppressed.
(2) Furthermore, in the first embodiment, an example has been described in which the first trench portion 24 (STI) in which the fixed charge film 13, the insulating film 14, and the first conductor portion 33 are arranged is formed on the back surface S2 side of the semiconductor substrate 8, but other configurations can also be adopted. For example, as illustrated in FIGS. 8 and 9, a diffraction structure 37 for diffracting the incident light may be further formed on the back surface S2 side of the semiconductor substrate 8. As an example, in a case of being viewed from the thickness direction of the semiconductor substrate 8, as the diffraction structure 37, a rectangular tubular recess may be formed at the center portion of the photoelectric conversion portion 19. That is, when the STI of the first trench portion 24 is formed, the STI in which the first conductor portion 33 is not arranged is formed immediately below the microlens 17. Therefore, the light condensed and incident by the microlens 17 is diffracted in an oblique direction, so that the optical path length becomes long and the quantum efficiency QE can be increased.
(3) Furthermore, in the first embodiment, an example has been described in which the through-trench portions 23 are formed in all the regions between the photoelectric conversion portions 19 of the semiconductor substrate 8 to form a layout of a cross pattern, but other configurations can also be adopted. For example, as illustrated in FIGS. 10 and 11, the through-trench portion 23 may have a configuration in which the through-trench portion 23 is formed only in a part of the regions between the photoelectric conversion portions 19 (layout of a stripe pattern). As an example, the through-trench portion 23 is formed in one of the region extending along the row direction and the region extending along the column direction of the two-dimensional array of the photoelectric conversion portions 19 in the regions between the photoelectric conversion portions 19 of the semiconductor substrate 8. FIG. 10 illustrates a case where the through-trench portion 23 is formed only along the row direction. The second trench portions 25 are formed in all the regions between the photoelectric conversion portions 19 of the semiconductor substrate 8. As illustrated in FIG. 11, the second trench portion 25 in the region (in FIG. 10, the region extending along the column direction) where the through-trench portion 23 is not formed is a bottomed trench portion. FIG. 11 is a diagram illustrating a sectional configuration of the solid-state imaging device 1 in a case of being cut along a line C-C′ of FIG. 10.
(4) Furthermore, for example, as illustrated in FIGS. 12 and 13, the through-trench portion 23 may be formed only at a position where a region extending along the row direction and a region extending along the column direction of the two-dimensional array of the photoelectric conversion portions 19 intersect each other among the regions between the photoelectric conversion portions 19 of the semiconductor substrate 8 in a case of being viewed from the thickness direction of the semiconductor substrate 8. In this case, the second trench portions 25 are formed in all the regions between the photoelectric conversion portions 19 of the semiconductor substrate 8. As illustrated in FIG. 13, the second trench portion 25 in the region (in FIG. 12, all the regions other than the intersecting position) where the through-trench portion 23 is not formed is a bottomed trench portion. FIG. 13 is a diagram illustrating a sectional configuration of the solid-state imaging device 1 in a case of being cut along a line D-D′ of FIG. 11. Therefore, the first conductor portion 33 functions as a cross-shaped wiring connected to each intersection portion of the second conductor portion 30, and is inferior to the lattice-shaped wiring by the first conductor portion 33 illustrated in the first embodiment, a resistance value of a transmission path of a negative bias can be reduced as a whole, a potential drop (IR drop) of the negative bias due to a resistance component of the transmission path can be suppressed, the deterioration of the shading characteristics can be suppressed. FIG. 13 is a diagram illustrating a sectional configuration of the solid-state imaging device 1 in a case of being cut along a line D-D′ of FIG. 12.

Furthermore, in the insulating film 14, a third conductor portion 38 including a predetermined conductor (hereinafter, also referred to as a “third conductor”) is arranged between the first conductor portion 33 and the color filter 16 (microlens 17). In a case of being viewed from the thickness direction of the semiconductor substrate 8, the third conductor portion 38 is formed in the same lattice shape as the through-trench portion 23 and the second conductor portion 30 so as to surround each photoelectric conversion portion 19. That is, in a case of being viewed from the thickness direction of the semiconductor substrate 8, the third conductor portion 38 is formed at both a position overlapping a region extending along the row direction and a position overlapping a region extending along the column direction of the two-dimensional array of the photoelectric conversion portions 19 among the regions between the photoelectric conversion portions 19 of the semiconductor substrate 8. Furthermore, the third conductor portion 38 is in contact with an end portion 39 of the first conductor portion 33 protruding from the opening portion 26 on the bottom surface S4 side. That is, the third conductor portion 38 is electrically connected to the first conductor portions 33. FIG. 13 illustrates a case where the third conductor portion 38 covers the end portion 39 of the first conductor portion 33. Therefore, the third conductor portion 38 functions as a net-shaped wiring connected to each first conductor portion 33, a resistance value of a transmission path of a negative bias can be further reduced as a whole, and a potential drop (IR drop) of the negative bias due to a resistance component of the transmission path can be further suppressed. Therefore, it is possible to further suppress deterioration of shading characteristics in the pixel 9 far from the outer periphery of the pixel region 2, that is, the pixel 9 in the central portion of the pixel region 2.

As a material (third conductor) of the third conductor portion 38, for example, the same material as the first conductor or a material having a resistivity lower than that of the material (second conductor) of the second conductor portion 30 can be adopted. Therefore, the resistance value of the third conductor portion 38 can be reduced, and the potential drop (IR drop) of the negative bias applied from the outside of the pixel region 2 can be more appropriately suppressed. Therefore, it is possible to more appropriately suppress deterioration of shading characteristics in the pixel 9 far from the outer periphery of the pixel region 2, that is, the pixel 9 in the central portion of the pixel region 2. Examples of the material having a resistivity lower than that of the second conductor include a metal material (tungsten (W), aluminum (Al), copper (Cu), and the like) and ITO.

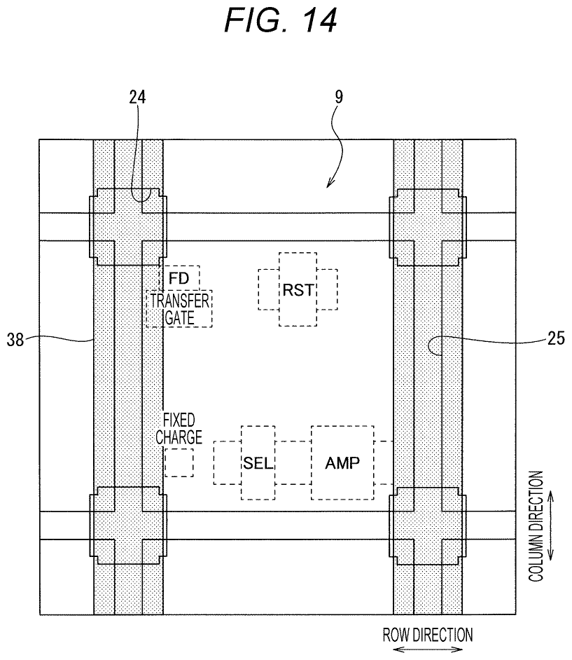

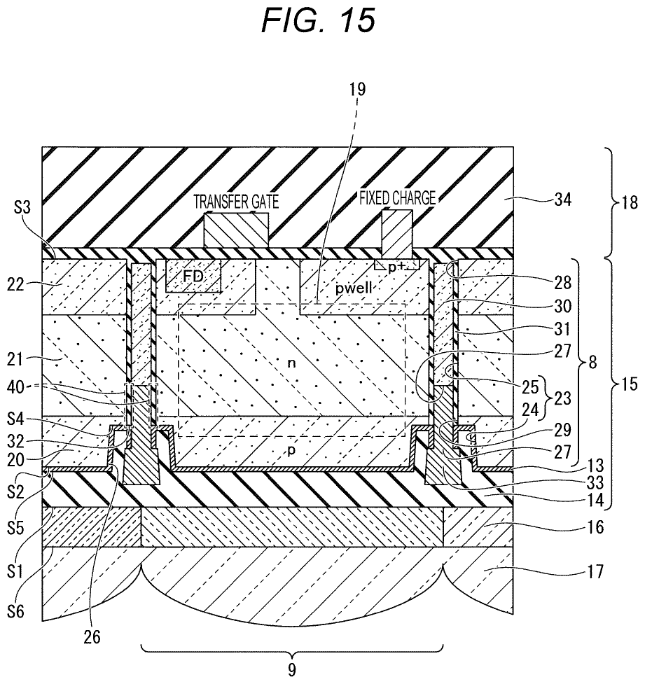

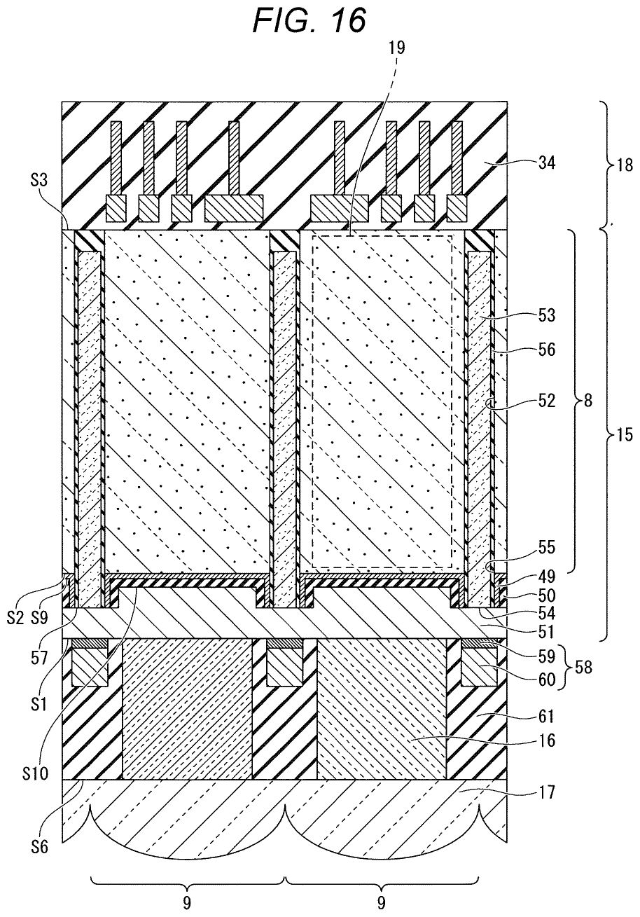

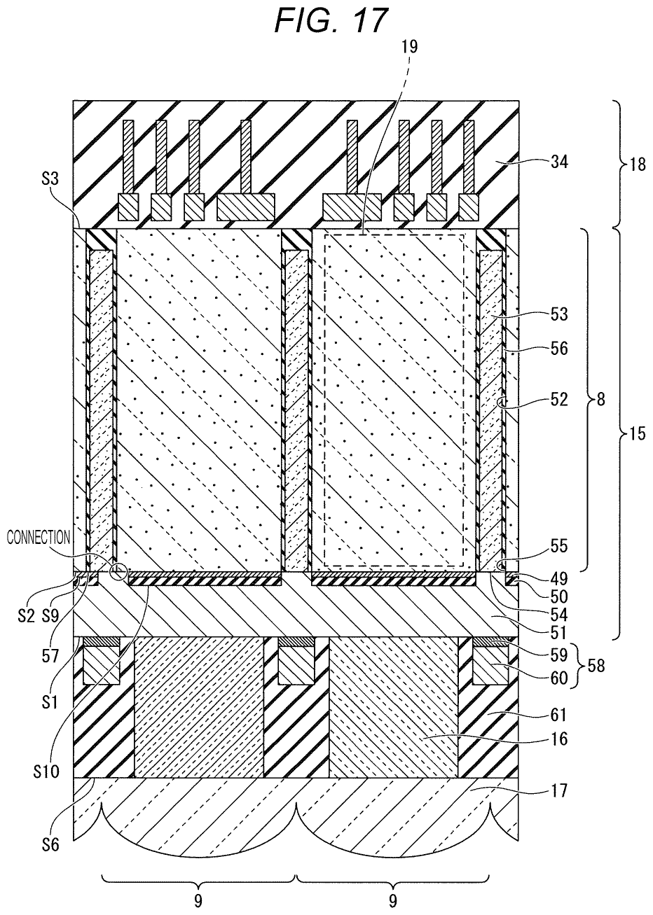

Note that FIG. 12 illustrates a case where the third conductor portion 38 is formed at a position overlapping each of a region extending along the row direction and a region extending along the column direction of the two-dimensional array of the photoelectric conversion portions 19 among the regions between the photoelectric conversion portions 19 of the semiconductor substrate 8 in a case of being viewed from the thickness direction of the semiconductor substrate 8 to form a layout of a cross pattern. Other configurations can be adopted as the layout of the third conductor portion 38. For example, as illustrated in FIG. 14, the third conductor portion 38 may have a configuration (layout of stripe pattern) in which the third conductor portion 38 is formed only in a part of the position overlapping the regions between the photoelectric conversion portions 19. As an example, in a case of being viewed from the thickness direction of the semiconductor substrate 8, the third conductor portion 38 is formed at one of a position overlapping a region extending along the row direction and a position overlapping a region extending along the column direction of the two-dimensional array of the photoelectric conversion portions 19 among the regions between the photoelectric conversion portions 19 of the semiconductor substrate 8. FIG. 14 illustrates a case where the third conductor portion 38 is formed only along the column direction.
(5) Furthermore, in the first embodiment, an example has been described in which the end portion 27 of the second conductor portion 30 on the back surface S2 side protrudes from the opening portion 26 of the first trench portion 24 on the bottom surface S4 side to the microlens 17 side, and the first conductor portion 33 is in contact with the end portion 27 of the protruding second conductor portion 30, but other configurations can be adopted. For example, as illustrated in FIG. 15, the end portion 27 of the second conductor portion 30 on the back surface S2 side may be recessed to the front surface S3 side from the bottom surface S4 of the first trench portion 24 such that the end portion 27 is positioned in the second trench portion 25. In this case, the first conductor portion 33 enters the second trench portion 25, and is in contact with the end portion 27 of the recessed second conductor portion 30. Therefore, for example, since a metal material has low light transmittance, a metal material such as tungsten (W), aluminum (Al), copper (Cu), or the like is used as the material of the first conductor portion 33, so that it is possible to prevent light incident on the photoelectric conversion portion 19 of a certain pixel 9 from entering the photoelectric conversion portion 19 of the adjacent pixel 9, and it is possible to suppress color mixing for each pixel 9.

Furthermore, an interlayer film 40 may be arranged between the first conductor portion 33 and the inner side surface of the second trench portion 25. As the interlayer film 40, for example, an insulating film, a fixed charge film, or a multilayer film in which the insulating film and the fixed charge film are stacked can be adopted. Examples of the material of the insulating film include the same material as the insulating film 31. Furthermore, examples of the material of the fixed charge film include the same material as the fixed charge film 13. FIG. 15 illustrates a case where the insulating film 31 is extended and used as the interlayer film 40.
(6) Furthermore, in the first embodiment, an example has been described in which the insulating film 14 is used as a film that continuously covers the back surface S5 of the fixed charge film 13 and the first conductor portion 33, but other configurations can be adopted. For example, a transparent conductive film may be used instead of the insulating film 14. Therefore, the transparent conductive film functions as a sheet-shaped wiring connected to each first conductor portion 33, a resistance value of a transmission path of a negative bias can be further reduced as a whole, and a potential drop (IR drop) of the negative bias due to a resistance component of the transmission path can be further suppressed. Therefore, it is possible to further suppress deterioration of shading characteristics in the pixel 9 far from the outer periphery of the pixel region 2, that is, the pixel 9 in the central portion of the pixel region 2. As a material of the transparent conductive film, for example, ITO can be adopted.
(7) Furthermore, the present technology is applicable to any photodetection device including not only the above-described solid-state imaging device 1 as an image sensor but also a ranging sensor, which is also referred to as a time of flight (ToF) sensor and measures a distance, and the like. The ranging sensor is a sensor that emits irradiation light toward an object, detects reflected light obtained by the irradiation light being reflected by a front surface of the object, and calculates a distance to the object on the basis of a flight time from the emission of the irradiation light to the reception of the reflected light. As a light receiving pixel structure of the ranging sensor, the structure of the pixel 9 described above may be adopted.

### 2. Second Embodiment: Solid-State Imaging Device

### 2-1 Configuration Of Main Part

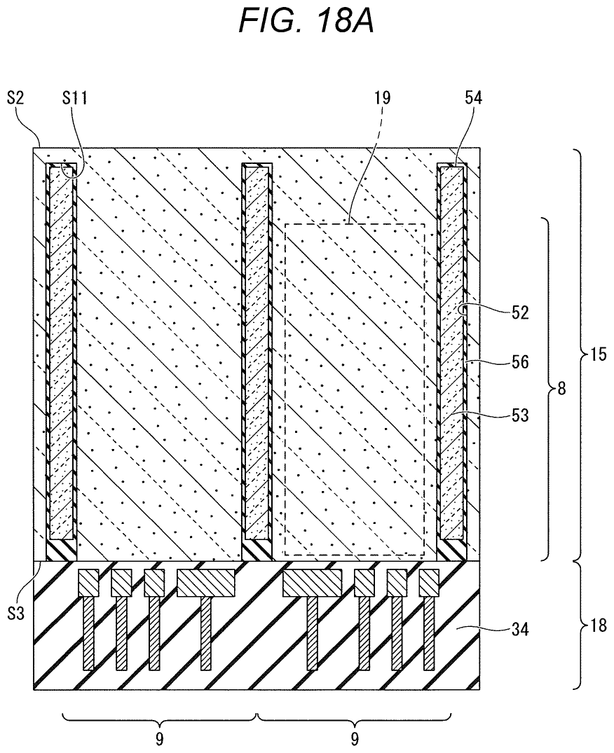

Next, the solid-state imaging device 1 according to a second embodiment of the present disclosure will be described. An overall configuration of the solid-state imaging device 1 according to the second embodiment is similar to that in FIG. 1, and thus illustration thereof will be omitted. FIG. 16 is a diagram illustrating a sectional configuration of the solid-state imaging device 1 according to the second embodiment. In FIG. 16, portions corresponding to those in FIG. 2 are denoted by the same reference numerals, and redundant description will be omitted.

As illustrated in FIG. 16, in the solid-state imaging device 1, the light receiving layer 15 is arranged in which the semiconductor substrate 8, a fixed charge film 49, an anti-reflective film 50, and a transparent conductive film 51 (“first conductor portion” in a broad sense) are stacked in this order. Furthermore, a plurality of color filters 16 and a plurality of microlenses 17 arranged in a two-dimensional array are arranged in this order on a surface (back surface S1) of the light receiving layer 15 on the transparent conductive film 51 side so as to correspond to the respective pixels 9. That is, the plurality of microlenses 17 is arranged on the light receiving surface (the back surface S2, and the “first surface” in a broad sense) side of the semiconductor substrate 8. Furthermore, the transparent conductive film 51 is arranged between the fixed charge film 49 and the microlens 17. Moreover, the wiring layer 18 is arranged on a surface (front surface S3) of the light receiving layer 15 on the semiconductor substrate 8 side. Note that, in the following description, a surface (a “second surface” in a broad sense) on a side opposite to the light receiving surface of the semiconductor substrate 8 is also referred to as the “front surface S3”.

The semiconductor substrate 8 includes, for example, a silicon (Si) substrate. In the semiconductor substrate 8, the photoelectric conversion portion 19 is formed in each region of each pixel 9. That is, the photoelectric conversion portion 19 is formed in a two-dimensional array on the semiconductor substrate 8. In the photoelectric conversion portion 19, an n-type semiconductor region is formed on the back surface S2 side of the semiconductor substrate 8, and a p-type semiconductor region is formed on the front surface S3 side. Then, the photoelectric conversion portion 19 constitutes a photodiode by a p-n junction, and generates a charge corresponding to the amount of received light. Furthermore, the photoelectric conversion portion 19 accumulates the charge generated by photoelectric conversion in electrostatic capacitance (junction capacitance) generated in the p-n junction between the n-type semiconductor region and the p-type semiconductor region.

Furthermore, in the semiconductor substrate 8, a through-trench portion 52 is formed in at least a part of regions between the photoelectric conversion portions 19. FIG. 16 illustrates a case where the through-trench portion 52 is formed in each of a region extending along a row direction and a region extending along a column direction of the two-dimensional array of the photoelectric conversion portions 19 in the regions between the photoelectric conversion portions 19 of the semiconductor substrate 8. That is, the through-trench portions 52 are formed in a lattice shape in all the regions between the photoelectric conversion portions 19. The through-trench portion 52 is formed to penetrate the semiconductor substrate 8 in a thickness direction of the semiconductor substrate 8.

A conductor portion 53 (“second conductor portion” in a broad sense) including a predetermined conductor (hereinafter, also referred to as a “second conductor”) is arranged inside the through-trench portion 52 from the front surface S3 side to the back surface S2 side of the semiconductor substrate 8. In a case of being viewed from the thickness direction of the semiconductor substrate 8, the conductor portion 53 is formed in the same lattice shape as the through-trench portion 52 so as to surround each photoelectric conversion portion 19. Therefore, by applying a negative bias to the conductor portion 53, the through-trench portion 52 side of the photoelectric conversion portion 19 can be brought into a high hole concentration state (hole accumulation state), and generation of a dark current around the through-trench portion 23 can be suppressed. An end portion 54 of the conductor portion 53 on the back surface S2 side protrudes from an opening portion 55 of the through-trench portion 52 on the back surface S2 side to the microlens 17 side such that the height of the conductor portion 53 from the back surface S2 of the semiconductor substrate 8 is the same as the height of an insulating film 56 from the back surface S2 of the semiconductor substrate 8. Therefore, on the back surface S2 side of the semiconductor substrate 8, the end portion 54 of the conductor portion 53 is exposed from between the end portions 57 of the insulating film 56, and thus the exposed end portion 54 is electrically connected to the transparent conductive film 51 by being in contact with the transparent conductive film 51.

As a material (second conductor) of the conductor portion 53, for example, polysilicon to which at least one of phosphorus (P) and boron (B) is added can be adopted. Here, for example, in a case where a metal such as tungsten (W) or aluminum (Al) is used as the second conductor, there is a possibility that the metal diffuses into the photoelectric conversion portion 19. Furthermore, since the metal has a high light absorption rate, the quantum efficiency QE may be decreased. On the other hand, in the second embodiment, by using polysilicon to which phosphorus (P) or boron (B) is added as the second conductor, diffusion of a metal into the photoelectric conversion portion 19 can be prevented, and since the light absorption rate is low, a decrease in the quantum efficiency QE can be suppressed.

The insulating film 56 is arranged between the inner side surface of the through-trench portion 52 and the conductor portion 53. The insulating film 56 covers the entire inner side surface of the through-trench portion 52. Therefore, the insulating film 56 electrically insulates the conductor portion 53 from the photoelectric conversion portion 19. Furthermore, the end portion 57 of the insulating film 56 on the back surface S2 side protrudes from the opening portion 55 of the through-trench portion 52 on the back surface S2 side to the microlens 17 side. Furthermore, the insulating film 56 closes the front surface S3 side of the through-trench portion 52. As a material of the insulating film 56, for example, silicon oxide (SiO₂) can be adopted.

The fixed charge film 49 covers the back surface S2 of the semiconductor substrate 8 (the back surface S2 of the photoelectric conversion portion 19). That is, in a case of being viewed from the thickness direction of the semiconductor substrate 8, the fixed charge films 49 are arranged in the same two-dimensional array as the photoelectric conversion portions 19 to overlap the respective photoelectric conversion portions 19. Therefore, the back surface S2 side of the photoelectric conversion portion 19 can be brought into a high hole concentration state (hole accumulation state), and generation of the dark current can be suppressed. In FIG. 16, the fixed charge film 49 also covers the side surface of the conductor portion 53 (covered with the insulating film 56) protruding from the opening portion 55 on the back surface S2 side. As a material of the fixed charge film 49, for example, a high refractive index material film or a high dielectric film having a negative charge, which can generate fixed charges and enhance pinning by being formed on the semiconductor substrate 8, can be adopted. For example, an oxide or nitride containing at least one element of hafnium (Hf), aluminum (Al), zirconium (Zr), tantalum (Ta), or titanium (Ti) is exemplified. In particular, hafnium oxide (HfO₂) is preferable.

The anti-reflective film 50 covers a back surface S9 of the fixed charge film 49. That is, in a case of being viewed from the thickness direction of the semiconductor substrate 8, the anti-reflective films 50 are arranged in the same two-dimensional array as the photoelectric conversion portions 19 to overlap the respective photoelectric conversion portions 19. Therefore, it is possible to suppress reflection of light incident on the photoelectric conversion portion 19 at the interface between the transparent conductive film 51 and the fixed charge film 49. As a material of the anti-reflective film 50, for example, tantalum oxide (TaO) can be adopted.

The transparent conductive film 51 is arranged on the back surface S10 side of the anti-reflective film 50, and continuously covers a back surface S10 of the anti-reflective film 50 and the end portion 54 of the conductor portion 53 on the back surface S2 side. That is, the transparent conductive film 51 is arranged between the photoelectric conversion portion 19 and the microlens 17. Furthermore, the transparent conductive film 51 is in contact with the end portion 54 of the conductor portion 53 protruding from the opening portion 55 on the back surface S2 side. That is, the transparent conductive film 51 is electrically connected to the end portion 54 exposed from between the end portions 57 of the insulating film 56. Therefore, the transparent conductive film 51 functions as a sheet-shaped wiring connected to each portion of the conductor portion 53, a resistance value of a transmission path of a negative bias can be reduced as a whole, and a potential drop (IR drop) of the negative bias due to a resistance component of the transmission path can be suppressed. Therefore, it is possible to suppress deterioration of shading characteristics in the pixel 9 far from the outer periphery of the pixel region 2, that is, the pixel 9 in the central portion of the pixel region 2.

As a material (“first conductor” in a broad sense) of the transparent conductive film 51, for example, a material having a resistivity lower than that of the material (second conductor) of the conductor portion 53 can be adopted. That is, the first conductor is a conductor different from the second conductor. Therefore, the resistance value of the transparent conductive film 51 can be reduced, the potential drop (IR drop) of the negative bias applied from the outside of the pixel region 2 can be more appropriately suppressed, and deterioration of shading characteristics in the pixel 9 in the central portion of the pixel region 2 can be more appropriately suppressed. Examples of the material having a resistivity lower than that of the second conductor include ITO.

In a case of being viewed from the microlens 17 side, the color filter 16 is arranged on the back surface S1 side of the transparent conductive film 51, at a position overlapping each photoelectric conversion portion 19. That is, one color filter 16 is formed for one photoelectric conversion portion 19. As the color filter 16, for example, a plurality of types of filters that transmits light of a predetermined wavelength included in light collected by the microlens 17 can be adopted. Therefore, each of the plurality of color filters 16 transmits light of a predetermined wavelength corresponding to the color filter 16, and causes the transmitted light to be incident on the photoelectric conversion portion 19.

Furthermore, an inter-pixel light shielding portion 58 is arranged in a portion on the transparent conductive film 51 side, between the color filters 16. In a case of being viewed from the thickness direction of the semiconductor substrate 8, the inter-pixel light shielding portion 58 is formed in the same lattice shape as the through-trench portion 52 and the conductor portion 53 so as to surround each photoelectric conversion portion 19. Therefore, the inter-pixel light shielding portion 58 covers the end portion 54 of the conductor portion 53, so that it is possible to prevent light from entering the end portion 54. Furthermore, the inter-pixel light shielding portion 58 is in contact with the back surface S1 of the transparent conductive film 51, and is electrically connected to the conductor portion 53 through the transparent conductive film 51. Therefore, the inter-pixel light shielding portion 58 functions as a lattice-shaped wiring connected to each portion of the transparent conductive film 51, a resistance value of a transmission path of a negative bias can be reduced as a whole, and a potential drop (IR drop) of the negative bias due to a resistance component of the transmission path can be further suppressed. Therefore, it is possible to further suppress deterioration of shading characteristics in the pixel 9 in the central portion of the pixel region 2.

As a material of the inter-pixel light shielding portion 58, for example, a material having a resistivity lower than that of the material (second conductor) of the conductor portion 53 can be adopted. Therefore, the resistance value of the inter-pixel light shielding portion 58 can be reduced, and the potential drop (IR drop) of the negative bias applied from the outside of the pixel region 2 can be more appropriately suppressed. Therefore, it is possible to more appropriately suppress deterioration of shading characteristics in the pixel 9 in the central portion of the pixel region 2. Examples of the material having a resistivity lower than that of the second conductor include a metal material (tungsten (W), aluminum (Al), copper (Cu), and the like). FIG. 16 illustrates a case where the inter-pixel light shielding portion 58 has a first light shielding film 59 including titanium (Ti) on the transparent conductive film 51 side and has a second light shielding film 60 including tungsten (W) on the microlens 17 side.

Furthermore, an insulating film 61 is arranged in a portion on the transparent conductive film 51 side, between the color filters 16. As a material of the insulating film 56, for example, silicon oxide (SiO₂) can be adopted.

The microlens 17 is arranged on the back surface S6 side of the color filter 16, at a position overlapping each photoelectric conversion portion 19. That is, one microlens 17 is formed for one photoelectric conversion portion 19. Therefore, each microlens 17 condenses image light (incident light) from a subject, and causes the condensed incident light to be incident on the corresponding photoelectric conversion portion 19.

The wiring layer 18 is arranged on the front surface S3 side of the semiconductor substrate 8. The wiring layer 18 has an interlayer insulating film 34 and wiring (not illustrated) stacked in a plurality of layers with the interlayer insulating film 34 interposed therebetween. Then, the wiring layer 18 drives the pixel transistor forming each pixel 9 through the plurality of layers of wiring.

In the solid-state imaging device 1 having the above configuration, light is emitted from the back surface S2 side of the semiconductor substrate 8, the emitted light passes through the microlens 17 and the color filter 16, and the transmitted light is photoelectrically converted by the photoelectric conversion portion 19 to generate a signal charge. Then, the generated signal charge is output as the pixel signal from the vertical signal line 11 in FIG. 1 formed by the wiring of the wiring layer 18.

Furthermore, in the solid-state imaging device 1 according to the second embodiment, the end portion 57 of the insulating film 56 on the back surface S2 side protrudes from the opening portion 55 of the through-trench portion 52 on the back surface S2 side to the microlens 17 side. Then, the back surface S2 of the semiconductor substrate 8 is covered with the fixed charge film 49. Therefore, the back surface S2 and the side surface of the photoelectric conversion portion 19 can be covered with the insulating film 56 and the fixed charge film 49, and the photoelectric conversion portion 19 and the transparent conductive film 51 can be prevented from being electrically connected. Therefore, the transparent conductive film 51 and the conductor portion 53 can be relatively easily connected. Therefore, the transmission path of the negative bias can be relatively easily formed.

Here, for example, in a case where p-type impurities are diffused into the semiconductor substrate 8 from the front surface S3 side of the semiconductor substrate 8 and a p-type impurity region is formed on the through-trench portion 52 side of the photoelectric conversion portion 19, generation of a dark current can be suppressed by setting a high hole concentration state. However, in the method of forming the p-type impurity region, the volume of the photoelectric conversion portion 19 is decreased by the amount of the p-type impurity region. On the other hand, for example, with a method in which the conductor portion 53 is arranged inside the through-trench portion 52 and a negative bias is applied to the conductor portion 53 to bring the through-trench portion 52 side of the photoelectric conversion portion 19 into a high hole concentration state, a p-type impurity region is not used, and thus the volume of the photoelectric conversion portion 19 is not decreased.

However, in the method of applying the negative bias, since a negative bias is applied to each portion of the conductor portion 53 through the conductor portion 53 from the outside of the pixel region 2, when the resistance value of the conductor portion 53 is high, a leakage current may be generated. Therefore, in the pixel 9 far from the outer periphery of the pixel region 2, that is, in the pixel 9 in the central portion of the pixel region 2, there is a possibility that IR drop of a negative bias occurs and the shading characteristics deteriorate. The IR drop becomes more noticeable as the chip size is increased. Therefore, due to the recent increase in chip size, there is a possibility that IR drop becomes a problem even in a case where the conductor portion 53 includes a material having a low resistance value such as a metal material.

Therefore, for example, as illustrated in FIG. 17, it is conceivable to suppress IR drop of a negative bias by arranging the transparent conductive film 51 between the back surface S2 of the semiconductor substrate 8 and the color filter 16 and electrically connecting the transparent conductive film 51 and the conductor portion 53. However, when the formation position of the contact from the transparent conductive film 51 is shifted at the connection point between the transparent conductive film 51 and the conductor portion 53, the transparent conductive film 51 is connected to the semiconductor substrate 8, and a leakage current may be generated.

On the other hand, in the second embodiment, the back surface S2 and the side surface of the photoelectric conversion portion 19 are covered with the insulating film 56 and the fixed charge film 49. Therefore, the photoelectric conversion portion 19 and the transparent conductive film 51 can be prevented from being electrically connected, and a leakage current can be suppressed.

### 2-2 Manufacturing Method for Solid-State Imaging Device

Next, the manufacturing method for the solid-state imaging device 1 will be described.

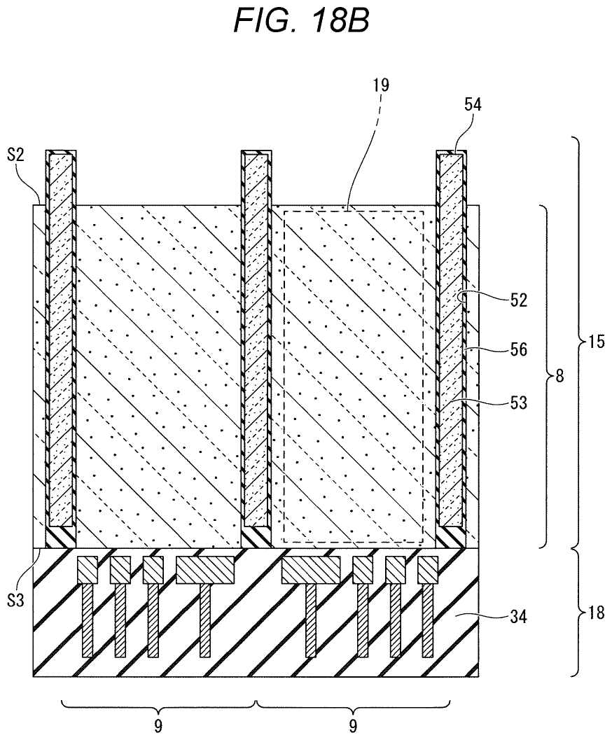

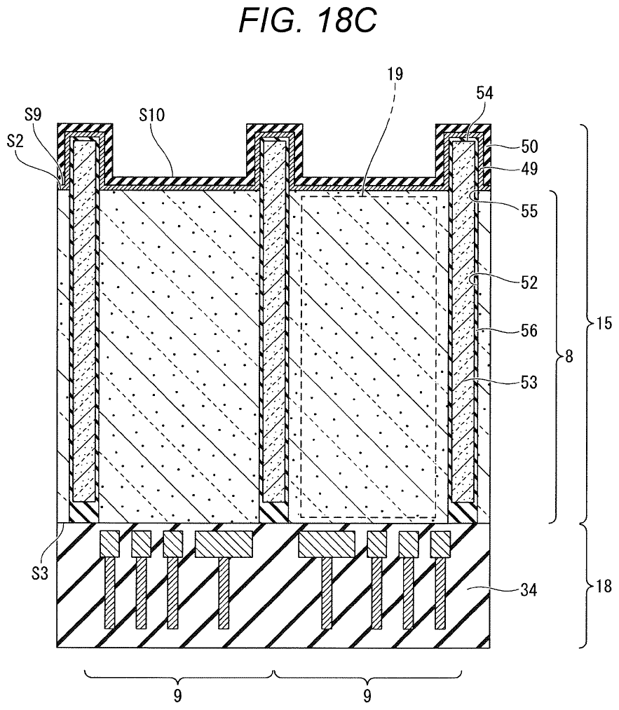

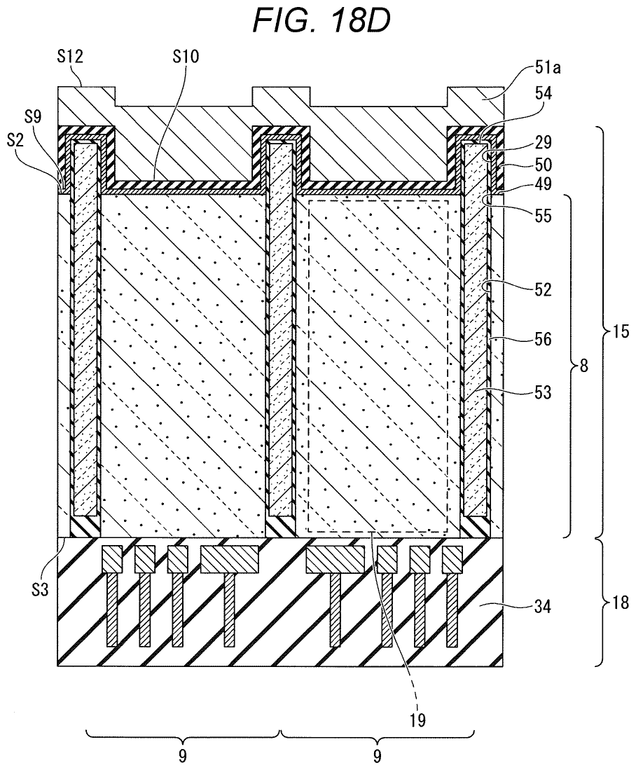

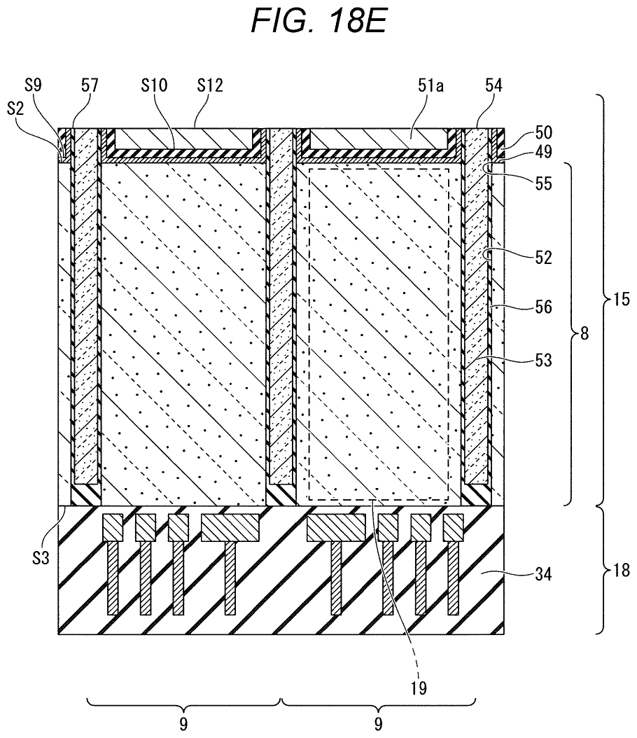

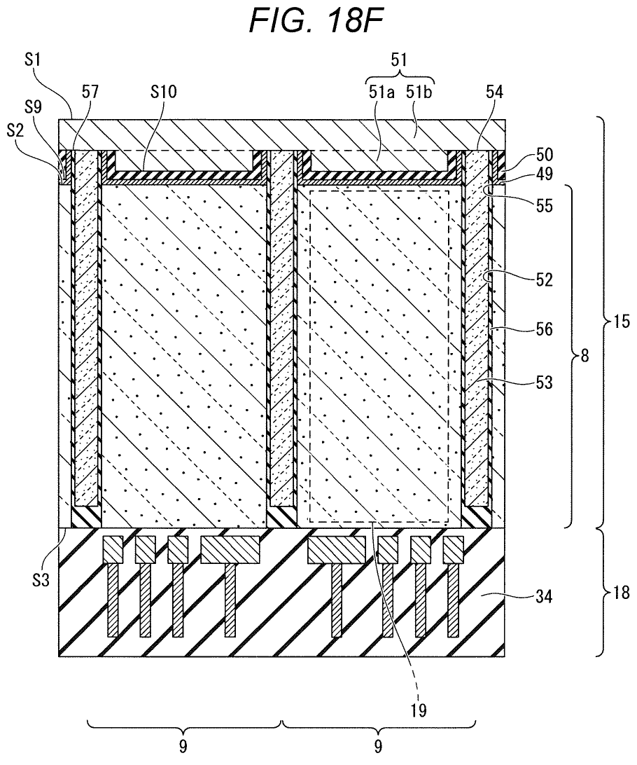

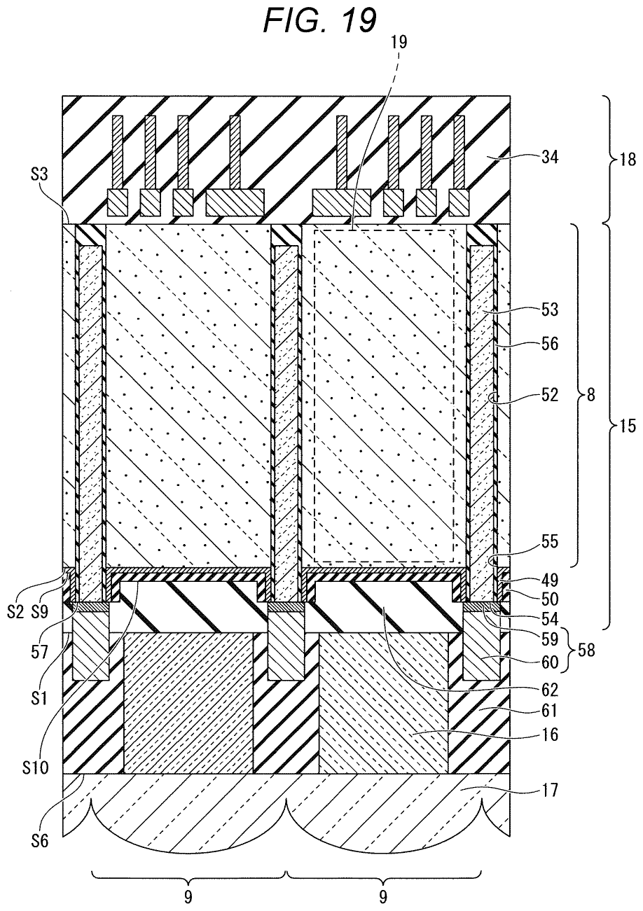

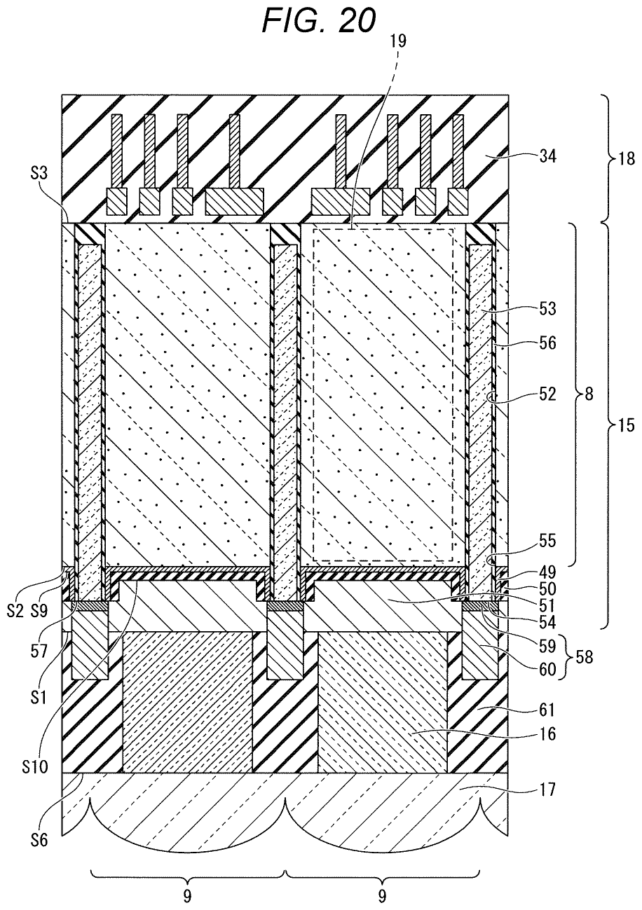

First, as illustrated in FIG. 18A, the semiconductor substrate 8 in which the photoelectric conversion portion 19, the through-trench portion 52, the insulating film 56, and the conductor portion 53 are formed and thinned is prepared. As the through-trench portion 52, a bottomed trench portion dug from the front surface S3 side of the semiconductor substrate 8 is formed. Furthermore, a bottom surface S11 of the through-trench portion 52 is formed at a position (position on the back surface S2 side) deeper than the opening portion 55 of the through-trench portion 52 of the solid-state imaging device 1 illustrated in FIG. 16. Furthermore, as the thinning method, for example, chemical mechanical polishing (CMP) can be adopted.

Subsequently, as illustrated in FIG. 18B, by using a lithography method and a dry etching method, etching is performed on the back surface S2 side of the semiconductor substrate 8 to cause the end portion 54 of the conductor portion 53 covered with the insulating film 56 to protrude from the back surface S2 side of the semiconductor substrate 8 (operation type dry etching). The height of the conductor portion 53 from the back surface S2 of the semiconductor substrate 8 is, for example, about 1 μm±0.7 μm.

Subsequently, as illustrated in FIG. 18C, the fixed charge film 49 and the anti-reflective film 50 are formed in this order on the back surface S2 side of the semiconductor substrate 8. The fixed charge film 49 and the anti-reflective film 50 are formed to continuously cover the back surface S2 of the semiconductor substrate 8 and the side surface and the top surface of the conductor portion 53 (with the insulating film 56). The fixed charge film 49 is, for example, an aluminum oxide film (AlxOy) having a thickness of about 14 nm. Furthermore, the anti-reflective film 50 is, for example, a tantalum oxide film (TaO) having a thickness of about 44 nm. Subsequently, as illustrated in FIG. 18D, a first transparent conductive film 51a is formed on the back surface S10 side of the anti-reflective film 50. As a material of the first transparent conductive film 51a, for example, ITO can be adopted. Subsequently, as illustrated in FIG. 18E, by using the CMP method, the back surface S12 side of the first transparent conductive film 51a, the insulating film 56, and the conductor portion 53 is planarized. The planarizing is performed up to a position deeper than the end portion 54 of the conductor portion 53 such that the end portion 54 of the conductor portion 53 is exposed from between the insulating films 56.

Subsequently, as illustrated in FIG. 18F, a second transparent conductive film 51b is formed on a back surface S12 of the first transparent conductive film 51a to form the transparent conductive film 51. The second transparent conductive film 51b (transparent conductive film 51) is connected to the end portion 54 of the conductor portion 53 exposed from between the insulating films 56. As a material of the second transparent conductive film 51b, the same material as the material of the first transparent conductive film 51a can be adopted.

Subsequently, as illustrated in FIG. 16, the color filter 16 (including the inter-pixel light shielding portion 58) and the microlens 17 are formed in this order on the back surface S1 side of the transparent conductive film 51.

The solid-state imaging device 1 illustrated in FIG. 16 is manufactured by such a procedure.

### 2-3 Modification Example

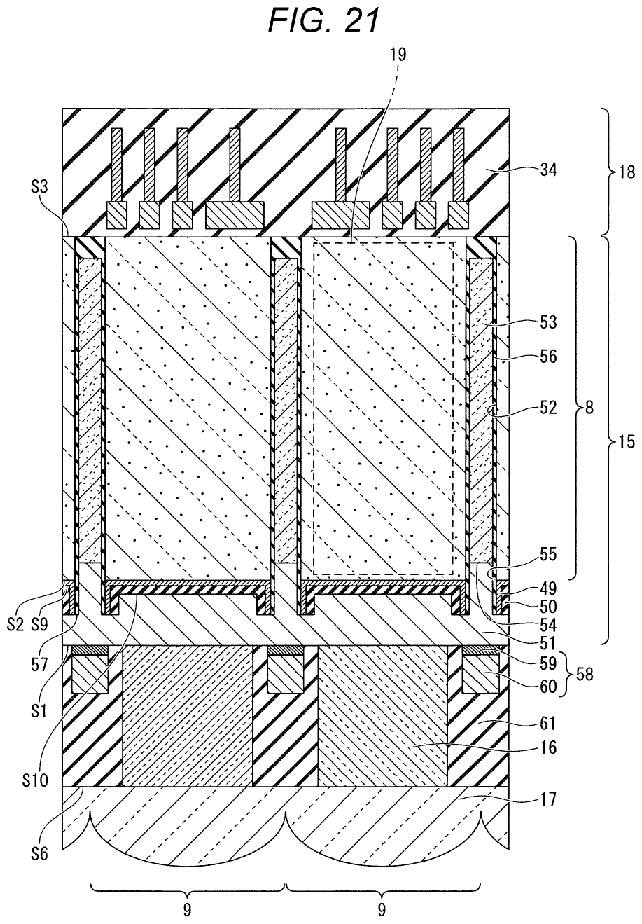

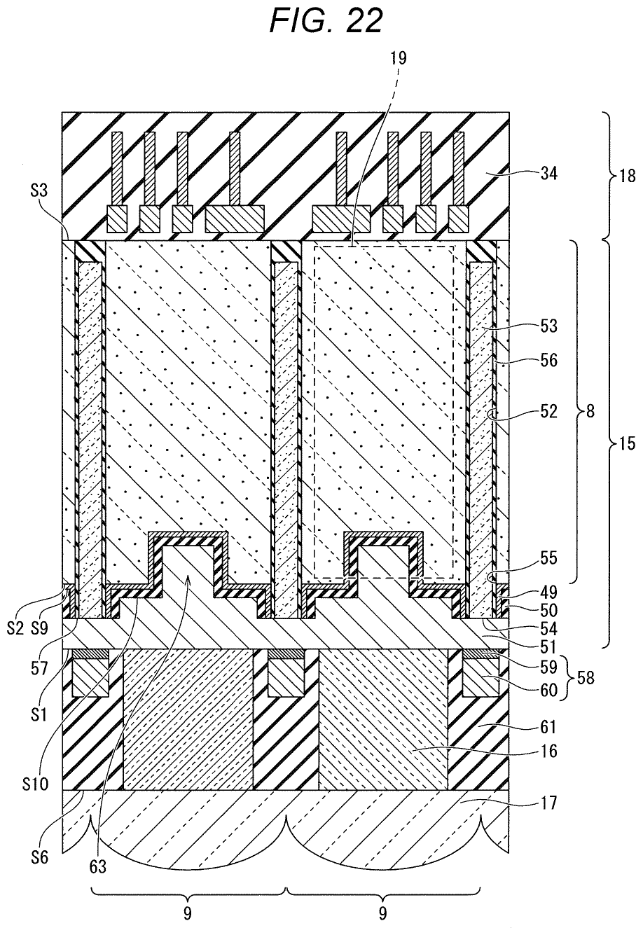

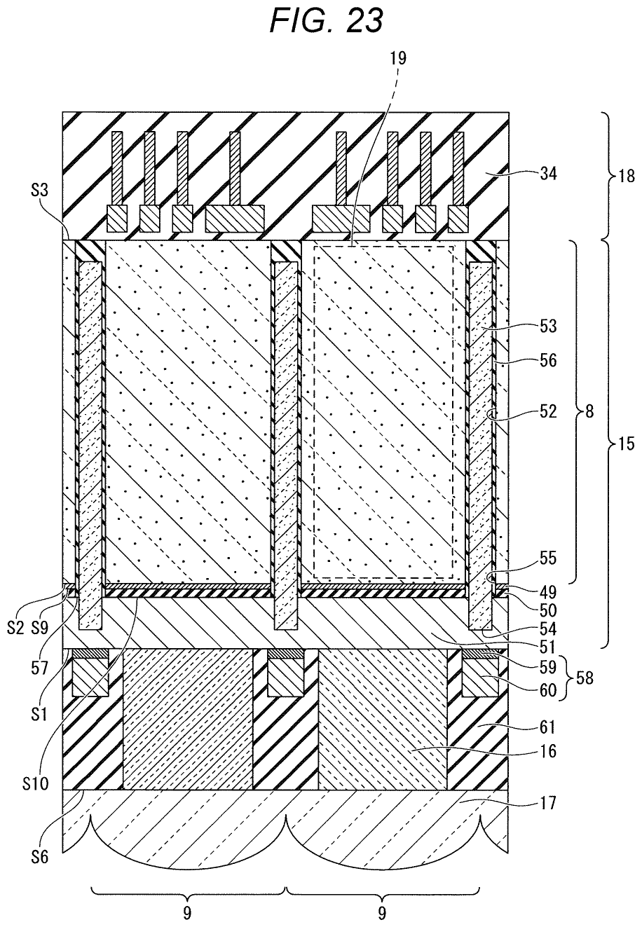

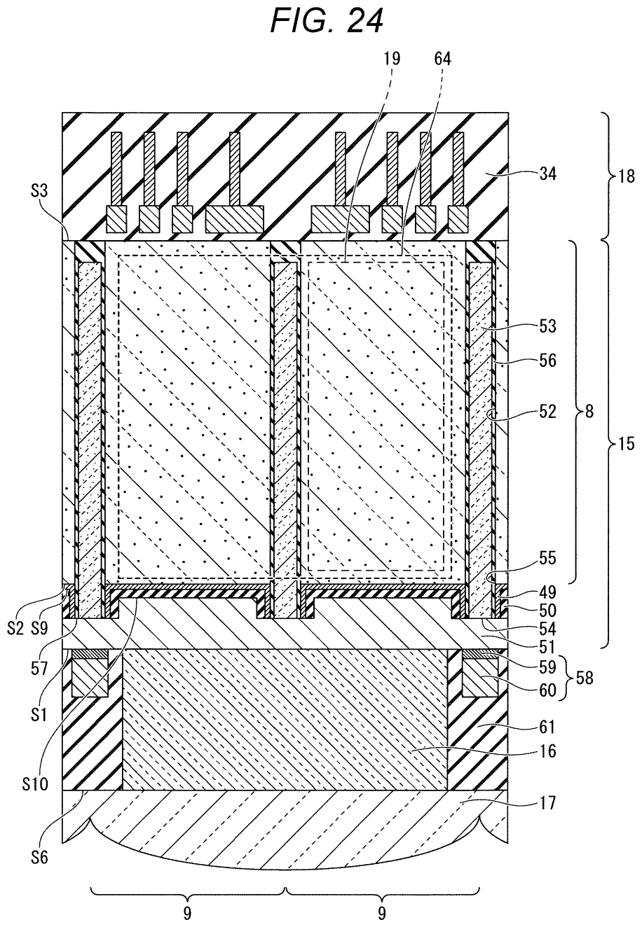

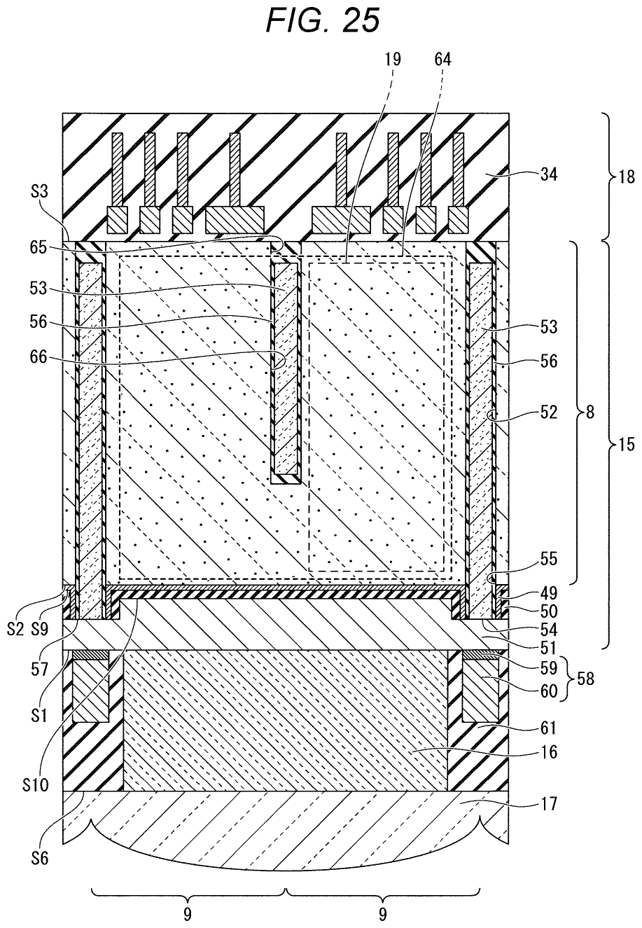

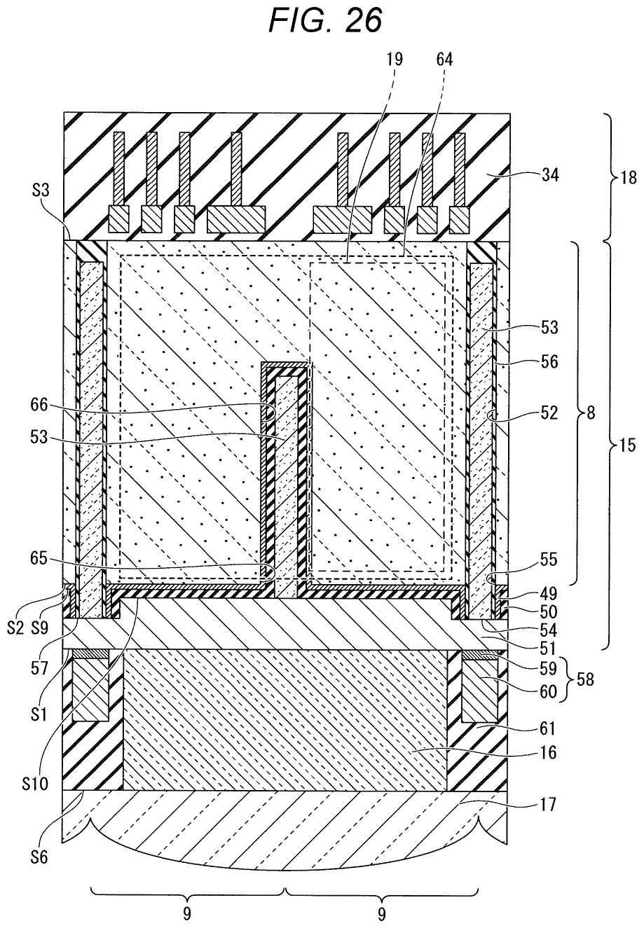

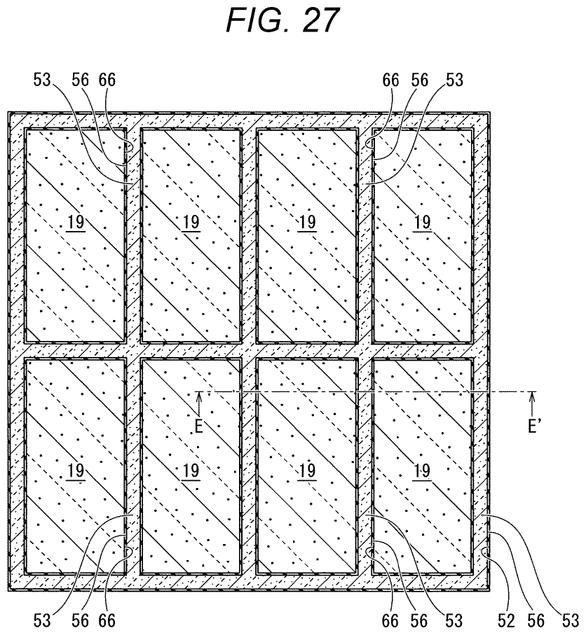

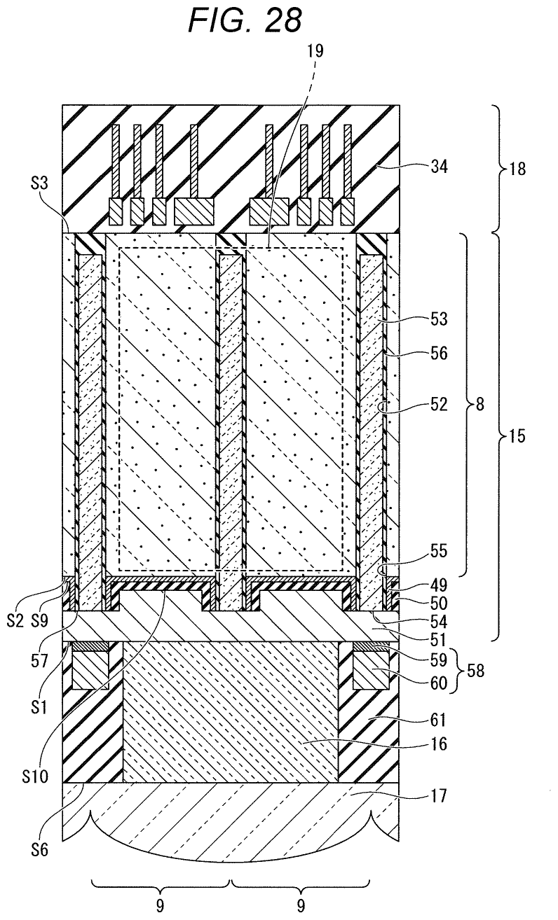

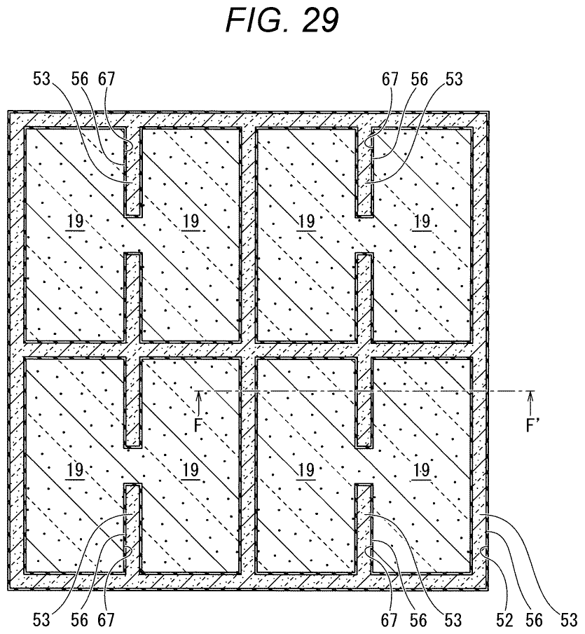

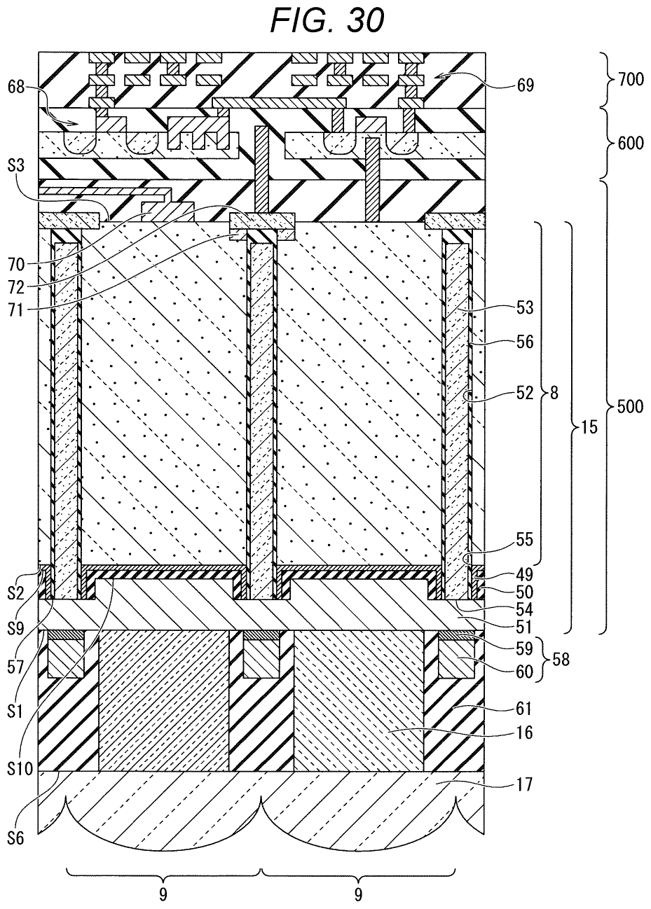

(1) Note that, in the second embodiment, an example has been described in which the conductor portion 53 and the inter-pixel light shielding portion 58 are electrically connected through the transparent conductive film 51, but other configurations can be adopted. For example, as illustrated in FIGS. 19 and 20, the conductor portion 53 and the inter-pixel light shielding portion 58 may be directly electrically connected. As an example, the inter-pixel light shielding portion 58 is formed to protrude from between the color filters 16 to the end portion 54 of the conductor portion 53 such that the inter-pixel light shielding portion 58 (the “first conductor portion” in a broad sense) is in contact with the end portion 54 of the conductor portion 53. That is, the inter-pixel light shielding portion 58 arranged between the through-trench portion 52 and the microlens 17 is used as the “first conductor portion” of the second embodiment. Therefore, the inter-pixel light shielding portion 58 directly covers the end portion 54 of the conductor portion 53, so that it is possible to more appropriately prevent light from entering the end portion 54, and it is possible to suppress light absorption by the conductor portion 53 (polysilicon or the like). Furthermore, the light prevented from entering the end portion 54 can be reflected and directed toward the photoelectric conversion portion 19. FIG. 19 illustrates a case where an insulating film 62 is used instead of the transparent conductive film 51 illustrated in FIG. 16. As a material of the insulating film 62, for example, silicon oxide (SiO) can be adopted. Furthermore, FIG. 20 illustrates a case where only the configuration of the inter-pixel light shielding portion 58 is changed without changing the transparent conductive film 51 to the insulating film 62. Therefore, as compared with a case of changing the transparent conductive film 51 to the insulating film 62, a resistance value of a transmission path of a negative bias can be further reduced as a whole, and a potential drop (IR drop) of the negative bias due to a resistance component of the transmission path can be further suppressed. Therefore, it is possible to further suppress deterioration of shading characteristics in the pixel 9 in the central portion of the pixel region 2.
(2) Furthermore, in the second embodiment, an example in which only the conductor portion 53 is arranged in the through-trench portion 52, that is, an example in which only one type of conductor is arranged has been described, but other configurations can be adopted. For example, a plurality of types of conductors may be arranged in the through-trench portion 52. As an example, as illustrated in FIG. 21, two types of conductors are arranged. In FIG. 21, the end portion 54 of the conductor portion 53 on the back surface S2 side is recessed to the front surface S3 side from the end portion 57 of the insulating film 56 on the back surface S2 side so that the end portion 54 is positioned in the through-trench portion 52. In this case, the transparent conductive film 51 enters the through-trench portion 52, and is in contact with the end portion 54 of the recessed conductor portion 53. Therefore, it is possible to more appropriately prevent light from entering the end portion 54 of the conductor portion 53, and it is possible to suppress light absorption by the conductor portion 53. Furthermore, as another example, the material (second conductor) of the conductor portion 53 may include a plurality of types of conductors. For example, the end portion 54 side of the conductor portion 53 illustrated in FIG. 16 may be include a metal material.
(3) Furthermore, in the second embodiment, an example has been described in which the fixed charge film 49, the anti-reflective film 50, and the transparent conductive film 51 are formed on the back surface S2 side of the semiconductor substrate 8, but other configurations can be adopted. For example, as illustrated in FIG. 22, a recessed structure 63 recessed to the back surface S2 side of the semiconductor substrate 8 may be further formed on the back surface S2 of the semiconductor substrate 8. As an example, in a case of being viewed from the thickness direction of the semiconductor substrate 8, as the recessed structure 63, a recess may be formed at the center portion of the photoelectric conversion portion 19. Therefore, when the transparent conductive film 51 is arranged in the recessed structure 63 and the transparent conductive film 51 approaches the back surface S2 side, a potential gradient can be formed in the photoelectric conversion portion 19 such that the charge generated in the photoelectric conversion portion 19 is transferred from the back surface S2 side to the front surface S3 of the semiconductor substrate 8.
(4) Furthermore, in the second embodiment, an example has been described in which a protrusion amount of the conductor portion 53 and a protrusion amount of the insulating film 56 from the back surface S2 of the semiconductor substrate 8 are the same, but other configurations can be adopted. For example, as illustrated in FIG. 23, the end portion 54 of the conductor portion 53 on the back surface S2 side may protrude further to the microlens 17 side than the end portion 57 of the insulating film 56. That is, the end portion 54 of the conductor portion 53 on the back surface S2 side may protrude to the microlens 17 side from the back surface S2 such that the height of the conductor portion 53 from the back surface S2 of the semiconductor substrate 8 is higher than the height of the insulating film 56 from the back surface S2. FIG. 23 illustrates a case where a portion of the side surface of the conductor portion 53 closer to the microlens 17 than the back surface S10 of the anti-reflective film 50 is omitted from the insulating film 56 illustrated in FIG. 16. In this case, the transparent conductive film 51 is in contact with the top surface and the side surface of the end portion 54 of the conductor portion 53. Therefore, a contact area between the conductor portion 53 and the transparent conductive film 51 can be increased, a resistance value of a transmission path of a negative bias can be further reduced as a whole, and a potential drop (IR drop) of the negative bias due to a resistance component of the transmission path can be more appropriately suppressed.
(5) Furthermore, in the second embodiment, an example has been described in which the plurality of microlenses 17 includes one individual microlens 17 arranged for one photoelectric conversion portion 19, but other configurations can also be adopted. For example, as illustrated in FIG. 24, a configuration may be adopted in which the plurality of microlenses 17 includes one shared microlens 17 arranged for one photoelectric conversion portion group 64 including two or more adjacent photoelectric conversion portions 19. FIG. 24 illustrates a case where one shared microlens 17 is arranged for the photoelectric conversion portions 19 of 2 rows×2 columns.
(6) Furthermore, in the second embodiment, an example has been described in which the through-trench portions 52 are formed in all the regions between the photoelectric conversion portions 19 of the semiconductor substrate 8, but other configurations can also be adopted. For example, as illustrated in FIGS. 25, 26, and 27, the through-trench portion 52 may have a configuration in which the through-trench portion 52 is formed only in a part of the regions between the photoelectric conversion portions 19. As an example, one shared microlens 17 is arranged for the photoelectric conversion portion group 64 including a total of two photoelectric conversion portions 19 of 1 row×2 columns, and the through-trench portion 52 is formed only in a region of the outer periphery of the photoelectric conversion portion group 64. In this case, in the region between the two photoelectric conversion portions 19 constituting the photoelectric conversion portion group 64, a bottomed trench portion 66 having an opening portion 65 only on one of the back surface S2 and the front surface S3 of the semiconductor substrate 8 is formed. That is, the bottomed trench portion 66 is formed in a region other than the region where the through-trench portion 52 is formed, among the regions between the photoelectric conversion portions 19. FIG. 25 illustrates a case where the opening portion 65 is provided in the front surface S3, and the insulating film 56 and the conductor portion 53 are arranged in the trench portion 66 in this order from the inner surface (inner side surface, bottom surface) side. Furthermore, FIG. 26 illustrates a case where the opening portion 65 is provided in the back surface S2, and the fixed charge film 49, the anti-reflective film 50, and the conductor portion 53 are arranged in the trench portion 66 in this order from the inner surface side. FIGS. 25 and 26 are diagrams illustrating a sectional configuration of the solid-state imaging device 1 in a case of being cut along a line E-E′ of FIG. 27.
(7) Furthermore, for example, as illustrated in FIGS. 28 and 29, in a case of being viewed from the microlens 17 side, the through-trench portion 52 may have protrusion portions 67 that protrude to the inside of the photoelectric conversion portion 19, at portions facing each other with the photoelectric conversion portion 19 interposed therebetween. In FIGS. 28 and 29, the protrusion portion 67 is formed to penetrate the semiconductor substrate 8 in the thickness direction of the semiconductor substrate 8, similarly to the portions facing each other with the photoelectric conversion portion 19 interposed therebetween. Furthermore, the insulating film 56 and the conductor portion 53 are arranged inside the protrusion portion 67. Therefore, a dual photo diode (PD) including two photodiodes for one pixel 9 can be configured. FIG. 28 is a diagram illustrating a sectional configuration of the solid-state imaging device 1 in a case of being cut along a line F-F′ of FIG. 29.
(8) Furthermore, for example, as illustrated in FIG. 30, the solid-state imaging device 1 may have a configuration in which a first substrate 500 having the semiconductor substrate 8, a second substrate 600 having a pixel transistor 68, and a third substrate 700 having a logic circuit 69 are stacked in this order. As an example, a stacked structure is assumed in which the first substrate 500 (a “sensor substrate” in a broad sense) having the semiconductor substrate 8, a transfer gate 70, and a floating diffusion 71, the second substrate 600 having the pixel transistor 68 that reads signal charges accumulated in the floating diffusion 71, and the third substrate 700 (a “logic substrate” in a broad sense) having the logic circuit 69 that processes the read pixel signals are stacked in this order. Examples of the pixel transistor 68 that reads signal charges include a reset transistor, an amplification transistor, and a selection transistor. Furthermore, examples of the logic circuit 69 include the vertical drive circuit 3, the column signal processing circuit 4, the horizontal drive circuit 5, the output circuit 6, and the control circuit 7. In FIG. 30, the first substrate 500 includes a pad portion 72 that connects the floating diffusions 71 of each of the pixels 9 of 2 rows×2 columns to each other. Therefore, wiring for connecting the floating diffusion 71 to the pixel transistor 68 can be reduced.
(9) Furthermore, the present technology is applicable to any photodetection device including not only the above-described solid-state imaging device 1 as an image sensor but also a ranging sensor, which is also referred to as a time of flight (ToF) sensor and measures a distance, and the like. The ranging sensor is a sensor that emits irradiation light toward an object, detects reflected light obtained by the irradiation light being reflected by a front surface of the object, and calculates a distance to the object on the basis of a flight time from the emission of the irradiation light to the reception of the reflected light. As a light receiving pixel structure of the ranging sensor, the structure of the pixel 9 described above may be adopted.

### 3. Third Embodiment: Solid-State Imaging Device

### 3-1 Configuration of Main Part

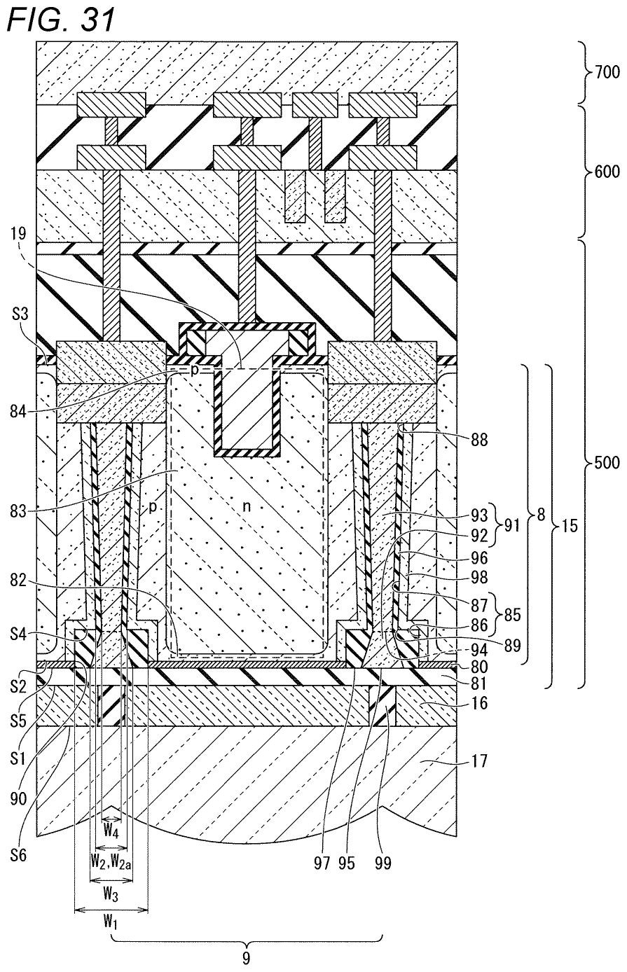

Next, the solid-state imaging device 1 according to a third embodiment of the present disclosure will be described. An overall configuration of the solid-state imaging device 1 according to the third embodiment is similar to that in FIG. 1, and thus illustration thereof will be omitted. FIG. 31 is a diagram illustrating a sectional configuration of the solid-state imaging device 1 according to the third embodiment. In FIG. 31, portions corresponding to those in FIG. 2 are denoted by the same reference numerals, and redundant description will be omitted.

As illustrated in FIG. 31, in the solid-state imaging device 1, the light receiving layer 15 is arranged in which the semiconductor substrate 8, a pinning film 80, and an insulating film 81 are stacked in this order. Furthermore, the plurality of color filters 16 and the plurality of microlenses 17 arranged in a two-dimensional array are arranged in this order on the surface (hereinafter, also referred to as the “back surface S1”) of the light receiving layer 15 on the insulating film 81 side so as to correspond to the respective pixels 9. That is, the plurality of microlenses 17 is arranged on the light receiving surface (hereinafter, also referred to as the “back surface S2”, and the “first surface” in a broad sense) side of the semiconductor substrate 8. Note that, in the following description, the surface (the “second surface” in a broad sense) on a side opposite to the light receiving surface of the semiconductor substrate 8 is also referred to as the “front surface S3”. Furthermore, FIG. 31 illustrates a case where the first substrate 500 having the semiconductor substrate 8, the second substrate 600 having a source follower (SF) circuit and a wiring layer (back end of line (BEOL)), and the third substrate 700 having a logic circuit are stacked in this order.

The semiconductor substrate 8 includes, for example, a silicon (Si) substrate. In the semiconductor substrate 8, the photoelectric conversion portion 19 is formed in each region of each pixel 9. That is, the photoelectric conversion portion 19 is formed in a two-dimensional array on the semiconductor substrate 8. In the photoelectric conversion portion 19, a p-type semiconductor region 82, an n-type semiconductor region 83, and a p-type semiconductor region 84 are formed in this order from the back surface S2 side to the front surface S3 side of the semiconductor substrate 8. That is, the photoelectric conversion portion 19 includes an n-type (in a broad sense, “first conductivity type”) semiconductor region. Then, the photoelectric conversion portion 19 constitutes a photodiode by a p-n junction, and generates a charge corresponding to the amount of received light. Furthermore, the photoelectric conversion portion 19 accumulates charges generated by the photoelectric conversion in electrostatic capacitance (junction capacitance) generated in the p-n junction.

Furthermore, in the semiconductor substrate 8, a through-trench portion 85 is formed in at least a part of regions between the photoelectric conversion portions 19. FIG. 31 illustrates a case where the through-trench portion 85 is formed in both a region extending along a row direction and a region extending along a column direction of the two-dimensional array of the photoelectric conversion portions 19 in the regions between the photoelectric conversion portions 19 of the semiconductor substrate 8. That is, the through-trench portions 85 are formed in a lattice shape in all the regions between the photoelectric conversion portions 19. The through-trench portion 85 is formed to penetrate the semiconductor substrate 8 in a thickness direction of the semiconductor substrate 8. The through-trench portion 85 includes a first trench portion 86 formed on the back surface S2 side of the semiconductor substrate 8, and a second trench portion 87 formed on the front surface S3 side of the semiconductor substrate 8.

The second trench portion 87 has an opening portion 88 on the front surface S3 side of the semiconductor substrate 8 and an opening portion 89 on the bottom surface S4 side of the first trench portion 86, and is formed in the depth direction of the semiconductor substrate 8 from the opening portion 88 on the front surface S3 side. Furthermore, the width W₂ of the second trench portion 87 is continuously decreased from the front surface S3 side of the semiconductor substrate 8 to the bottom surface S4 side of the first trench portion 86. Furthermore, the first trench portion 86 has an opening portion 90 on the back surface S2 of the semiconductor substrate 8, and is formed in the depth direction of the semiconductor substrate 8 from the opening portion 89 of the second trench portion 87 so as to be continuous with the second trench portion 87. Furthermore, the width W₁ of the first trench portion 86 is constant regardless of the position in the depth direction of the semiconductor substrate 8. Furthermore, the width W₁ of the first trench portion 86 is wider than a width W₂ₐ of a narrow portion of the second trench portion 87, that is, a boundary portion between the second trench portion 87 and the first trench portion 86. Furthermore, the center of the second trench portion 87 in the width direction is positioned to overlap the center of the first trench portion 86 in the width direction.

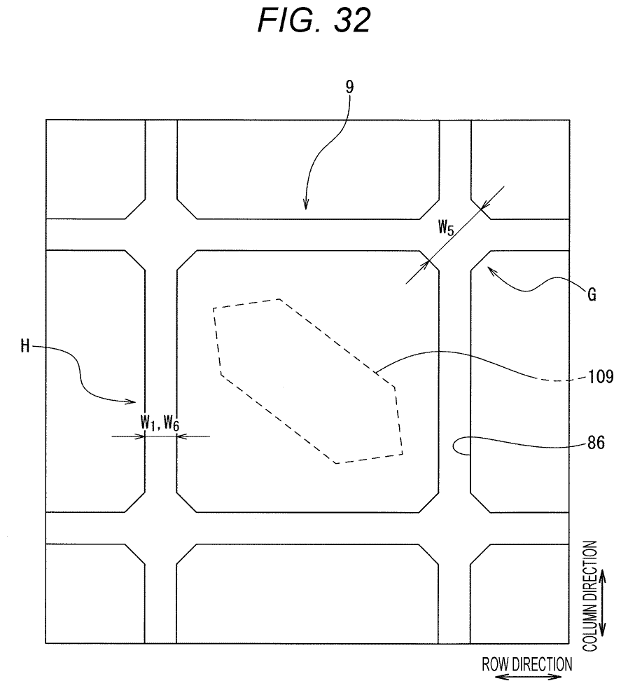

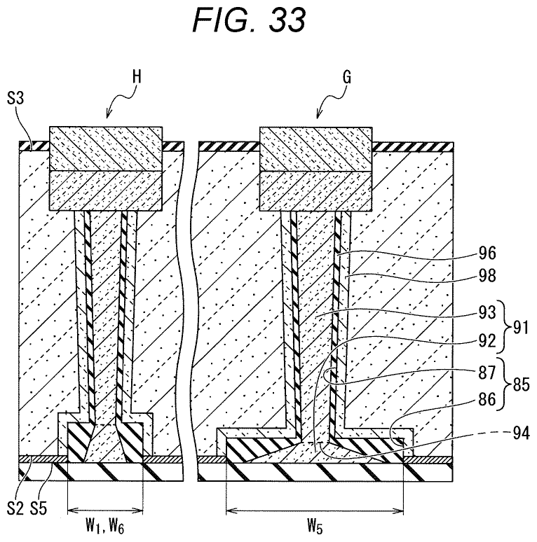

Furthermore, as illustrated in FIGS. 32 and 33, in a case of being viewed from the thickness direction of the semiconductor substrate 8, an interface between the first trench portion 86 and the second trench portion 87 at a position (hereinafter, also referred to as “cross portion G”) where a region extending along the row direction and a region extending along the column direction of the two-dimensional array intersect each other in the region between the photoelectric conversion portions 19 of the semiconductor substrate 8 is formed on a side closer to the back surface S2 than an interface at another position (hereinafter, also referred to as “slit portion H”). Therefore, for example, as compared with a case where the interface of the cross portion G and the interface of the slit portion H are at the same depth position, in the cross portion G, a range in which the first trench portion 86 is formed, that is, a range in which the groove having a relatively wide width is formed can be narrowed, and a decrease in the volume of the photoelectric conversion portion 19 can be suppressed.

Note that the difference between the interface of the cross portion G and the interface of the slit portion H at the depth position can be configured by utilizing the fact that an etching speed of the second trench portion 87 in the cross portion G is faster than an etching speed of the second trench portion 87 in the slit portion H due to the microloading effect when the second trench portion 87 is formed. Furthermore, a width W₅ of the first trench portion 86 of the cross portion G is larger than a width W₆ of the first trench portion 86 of the slit portion H. FIG. 32 is a diagram illustrating a planar configuration of the first trench portion 86 in a B region of FIG. 1. Furthermore, from the viewpoint of the volume of the photoelectric conversion portion 19, the interface between the first trench portion 86 and the second trench portion 87 in the slit portion H is also desirably formed on the back surface S2 side as much as possible.

Furthermore, a conductor portion 91 including a predetermined conductor is arranged from the front surface S3 side to the back surface S2 side of the semiconductor substrate 8, in the through-trench portion 85(first trench portion 86, second trench portion 87). In a case of being viewed from the thickness direction of the semiconductor substrate 8, the conductor portion 91 is formed in the same lattice shape as the through-trench portion 85 so as to surround each photoelectric conversion portion 19. Therefore, by applying a negative bias to the conductor portion 91, the through-trench portion 85 side of the photoelectric conversion portion 19 can be brought into a high hole concentration state (hole accumulation state), and generation of a dark current around the through-trench portion 85 can be suppressed. The conductor portion 91 includes a first conductor portion 92 formed on the back surface S2 side of the semiconductor substrate 8, and a second conductor portion 93 formed on the front surface S3 side of the semiconductor substrate 8. The second conductor portion 93 is formed in the depth direction of the semiconductor substrate 8 from the opening portion 88 side of the second trench portion 87. Furthermore, the width W₄ of the second conductor portion 93 is decreased from the front surface S3 side of the semiconductor substrate 8 to the bottom surface S4 side of the first trench portion 86. Furthermore, the first conductor portion 92 is formed in the depth direction of the semiconductor substrate 8 from the opening portion 89 side of the second trench portion 87. Furthermore, the width W₃ of the first conductor portion 92 is increased from the bottom surface S4 side of the first trench portion 86 toward the back surface S2 of the semiconductor substrate 8.

Furthermore, an end portion 94 of the second conductor portion 93 on the back surface S2 side protrudes from the opening portion 89 of the second trench portion 87 on the bottom surface S4 side to the microlens 17 side. Therefore, the end portion 94 of the conductor portion 91 is positioned in the first trench portion 86, and is electrically connected to the first conductor portion 92 by being in contact with the first conductor portion 92. That is, the first conductor portion 92 covers the end portion 94 of the second conductor portion 93, and is electrically connected to the second conductor portion 93. Therefore, the first conductor portion 92 functions as a lattice-shaped wiring connected to each portion of the second conductor portion 93, a resistance value of a transmission path of a negative bias can be reduced as a whole, and a potential drop (IR drop) of the negative bias due to a resistance component of the transmission path can be suppressed. Therefore, it is possible to suppress deterioration of shading characteristics in the pixel 9 far from the outer periphery of the pixel region 2, that is, the pixel 9 in the central portion of the pixel region 2. FIG. 31 illustrates a case where the first conductor portion 92 and the second conductor portion 93 integrally include the same material. Furthermore, an end portion 95 of the first conductor portion 92 (conductor portion 91) on the back surface S2 side protrudes from the opening portion 90 of the first trench portion 86, and is in contact with the insulating film 81.

As a material (predetermined conductor) of the conductor portion 91, for example, polysilicon to which at least one of phosphorus (P) and boron (B) is added can be adopted. Here, for example, in a case where a metal such as tungsten or aluminum is used as the predetermined conductor, since the metal has a high light absorption rate, the quantum efficiency QE may be decreased. Furthermore, in a case where a metal is used, the metal may diffuse into the photoelectric conversion portion 19. On the other hand, in the first embodiment, by using polysilicon to which phosphorus or boron is added as the predetermined conductor, since the light absorption rate is low, a decrease in the quantum efficiency QE can be suppressed, and diffusion of the metal into the photoelectric conversion portion 19 can be prevented.

Furthermore, an insulating film 96 is arranged between the inner side surface of the through-trench portion 85 (first trench portion 86, second trench portion 87) and the conductor portion 91 (first conductor portion 92, second conductor portion 93). The insulating film 96 covers the entire inner side surface of the through-trench portion 85. Therefore, the insulating film 96 electrically insulates the conductor portion 91 from the photoelectric conversion portion 19. An end portion 97 of the insulating film 96 on the back surface S2 side protrudes from the opening portion 90 of the first trench portion 86, and is in contact with the insulating film 81. As a material of the insulating film 96, for example, silicon oxide (SiO₂) can be adopted.

Furthermore, the semiconductor substrate 8 has a pinning region 98 including a p-type (a “semiconductor region of a conductivity type opposite to the first conductivity type” in a broad sense) semiconductor region between the photoelectric conversion portion 19 and the through-trench portion 85. FIG. 31 illustrates a case where the pinning region 98 is formed from the front surface S3 side to the back surface S2 side of the semiconductor substrate 8 so as to continuously follow the inner side surface of the first trench portion 86 and the inner side surface of the second trench portion 87. The pinning region 98 is formed in a frame shape so as to surround each of the photoelectric conversion portions 19 in a case of being viewed from the microlens 17 side. As the impurities constituting the p-type semiconductor region, for example, boron (B) can be adopted. Therefore, regardless of the degree of application of a negative bias, the through-trench portion 85 side of the photoelectric conversion portion 19 can be brought into a high hole concentration state (hole accumulation state), and generation of a dark current around the through-trench portion 85 can be further suppressed.

The pinning film 80 covers a portion between the first trench portions 86 (the back surface S2 of the photoelectric conversion portion 19) in the back surface S2 of the semiconductor substrate 8. That is, in a case of being viewed from the thickness direction of the semiconductor substrate 8, the pinning films 80 are arranged in the same two-dimensional array as the photoelectric conversion portions 19 to overlap the respective photoelectric conversion portions 19. As the pinning film 80, a p-type impurity region and a fixed charge film can be adopted. As a material of the fixed charge film, for example, a high refractive index material film or a high dielectric film having a negative charge, which can generate fixed charges and enhance pinning by being formed on the semiconductor substrate 8, can be adopted. For example, an oxide or nitride containing at least one element of hafnium (Hf), aluminum (Al), zirconium (Zr), tantalum (Ta), or titanium (Ti) is exemplified. In particular, hafnium oxide (HfO₂) is more preferable from the viewpoint that the formation on the semiconductor substrate 8 can suppress the generation of blisters and hardly causes peeling from a planar portion of the semiconductor substrate 8. Therefore, the back surface S2 side of the photoelectric conversion portion 19 can be brought into a high hole concentration state (hole accumulation state), and generation of the dark current can be suppressed.

The insulating film 81 is arranged on the back surface S5 side of the pinning film 80, and continuously covers the back surface S5 of the pinning film 80 and the first conductor portion 92 such that the entire back surface S1 side of the light receiving layer 15 is a flat surface. As a material of the insulating film 81, for example, silicon oxide (SiO₂) can be adopted.

In a case of being viewed from the microlens 17 side, the color filter 16 is arranged on the back surface S1 side of the insulating film 81, at a position overlapping each photoelectric conversion portion 19. That is, one color filter 16 is formed for one photoelectric conversion portion 19. As the color filter 16, for example, a plurality of types of filters that transmits light of a predetermined wavelength included in light collected by the microlens 17 can be adopted. Therefore, each of the plurality of color filters 16 transmits light of a predetermined wavelength corresponding to the color filter 16, and causes the transmitted light to be incident on the photoelectric conversion portion 19. As an array of the color filters 16, for example, a Bayer array can be adopted. Furthermore, an inter-pixel light shielding portion 99 is arranged between the color filters 16. In a case of being viewed from the microlens 17 side, the inter-pixel light shielding portion 99 is formed in the same lattice shape as the through-trench portion 52 and the conductor portion 53 so as to surround each photoelectric conversion portion 19. Therefore, the inter-pixel light shielding portion 58 can prevent light from entering the end portion 95 of the first conductor portion 92 (the conductor portion 91).

The microlens 17 is arranged on the back surface S6 side of the color filter 16, at a position overlapping each photoelectric conversion portion 19. That is, one microlens 17 is formed for one photoelectric conversion portion 19. Therefore, each microlens 17 condenses image light (incident light) from a subject, and causes the condensed incident light to be incident on the corresponding photoelectric conversion portion 19.

In the solid-state imaging device 1 having the above configuration, light is emitted from the back surface S2 side of the semiconductor substrate 8, the emitted light passes through the microlens 17 and the color filter 16, and the transmitted light is photoelectrically converted by the photoelectric conversion portion 19 to generate a signal charge. Then, the generated signal charge is output as the pixel signal from the vertical signal line 11 in FIG. 1 formed by the wiring of the wiring layer 18.

Furthermore, in the solid-state imaging device 1 according to the third embodiment, the width W₁ of the first trench portion 86 is made larger than the width W₂ₐ of the boundary portion of the second trench portion 87 with the first trench portion 86. Therefore, the width W₃ of the first conductor portion 92 arranged in the first trench portion 86 can be increased. Therefore, for example, in a case where a negative bias is applied to the end portion 95 of the first conductor portion 92 on the back surface S2 side through a contact (not illustrated) outside the pixel region 2, a margin for misalignment between the first conductor portion 92 and the contact becomes large, and thus, it is possible to reduce the possibility that the contact steps off the first conductor portion 92. As a result, the contact and the first conductor portion 92 can be relatively easily connected. Therefore, the transmission path of the negative bias can be relatively easily formed.

Here, for example, in a case where p-type impurities are diffused into the semiconductor substrate 8 from the front surface S3 side of the semiconductor substrate 8 by using high energy ion implantation and a p-type impurity region is formed on the through-trench portion 85 side of the photoelectric conversion portion 19, generation of a dark current can be suppressed by setting a high hole concentration state. However, in the method using the high energy ion implantation, in a case where the semiconductor substrate 8 is thick, since the p-type impurity region spreads in a direction parallel to the front surface S3, there is a possibility that the volume of the photoelectric conversion portion 19 is decreased by the amount of the p-type impurity region. Furthermore, there is a possibility that crystal defects are generated in the photoelectric conversion portion 19 by high energy ion implantation, and a dark current or a white spot derived from the crystal defects is generated.

On the other hand, in the solid-state imaging device 1 according to the third embodiment, the pinning region 98 including a p-type (conductivity type opposite to the first conductivity type) semiconductor region formed continuously along the inner side surface of the first trench portion 86 and the inner side surface of the second trench portion 87 is provided between the photoelectric conversion portion 19 and the through-trench portion 85. That is, the pinning region 98 is configured to be obtained by performing sidewall doping with p-type impurities from the inner side surface of the through-trench portion 85 to the photoelectric conversion portion 19 side. Therefore, for example, as compared with a method in which impurities diffuse from the front surface S3 side of the semiconductor substrate 8 to form a p-type impurity region, the range where the p-type impurities are diffused is narrowed, so that the range where the p-type impurity region is formed is narrowed, and a decrease in the volume of the photoelectric conversion portion 19 can be suppressed. Furthermore, for example, unlike the method using high energy ion implantation, it is possible to suppress generation of crystal defects in the photoelectric conversion portion 19, and it is possible to suppress generation of a dark current or a white spot derived from the crystal defects.

### 3-2 Manufacturing Method for Solid-State Imaging Device

Next, the manufacturing method for the solid-state imaging device 1 will be described.

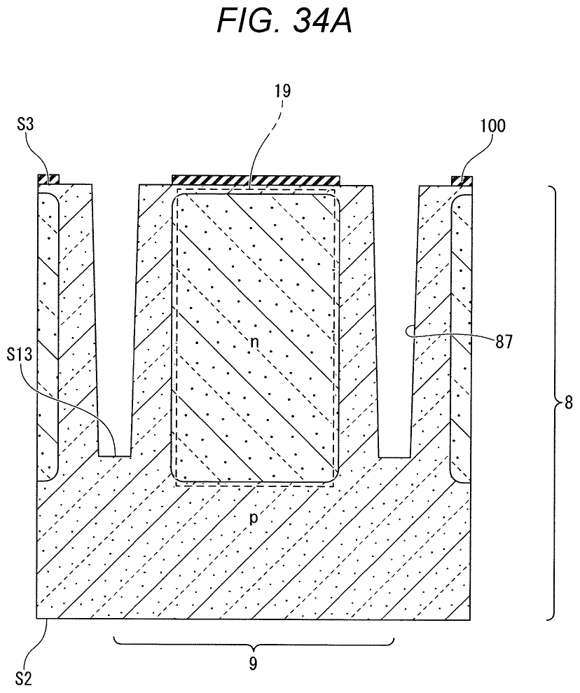

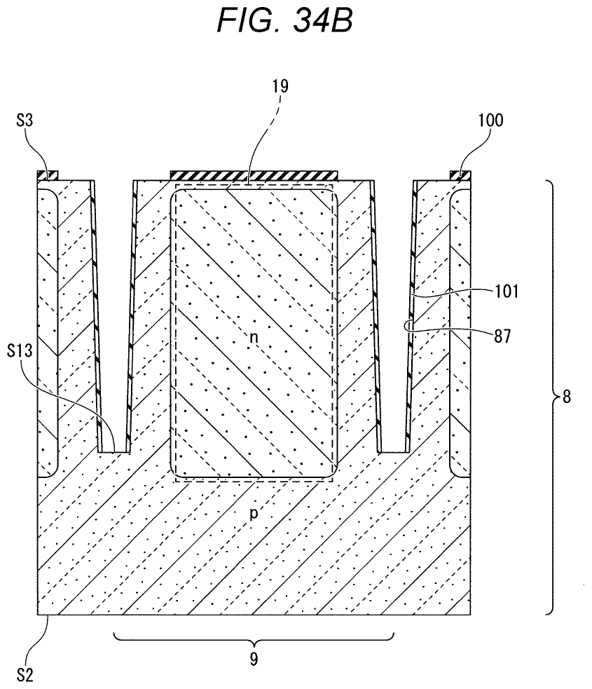

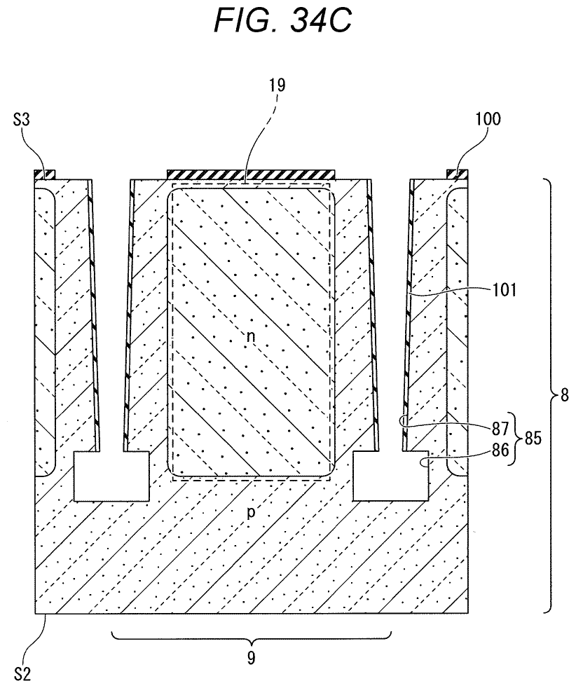

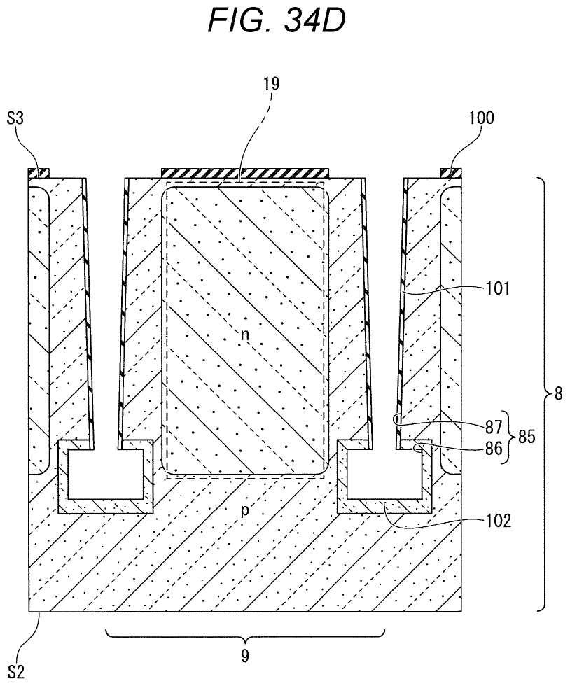

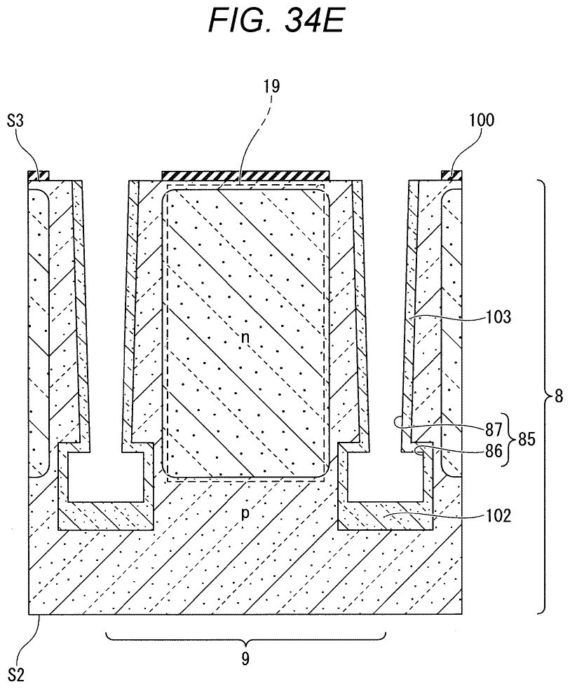

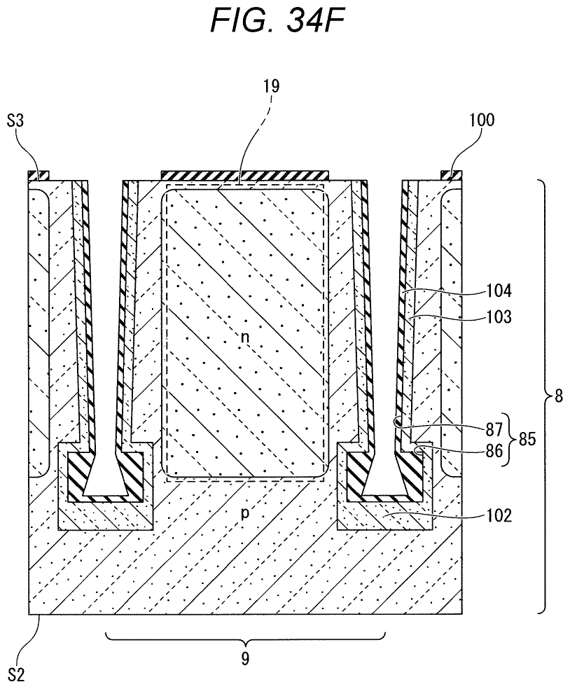

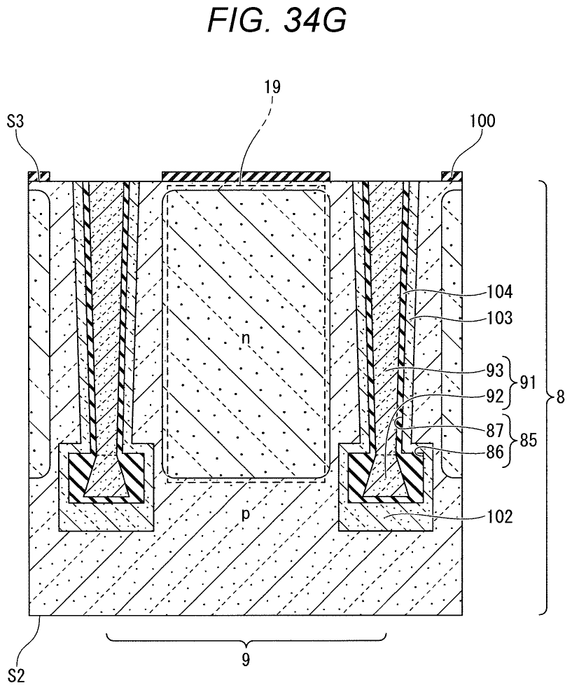

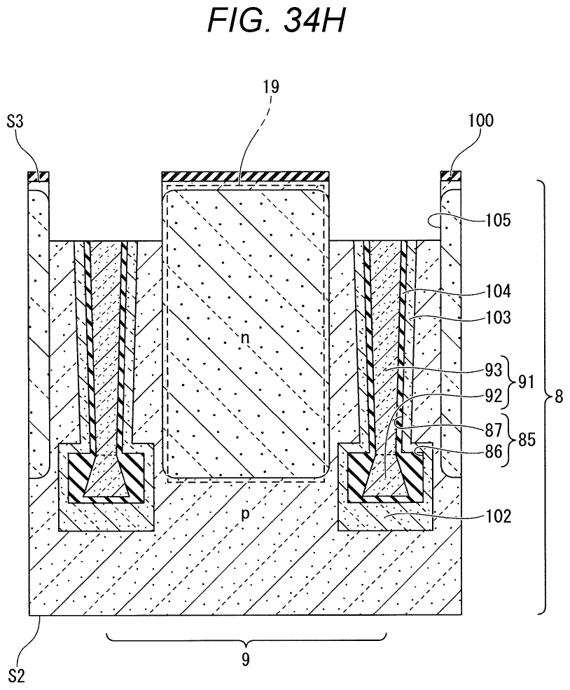

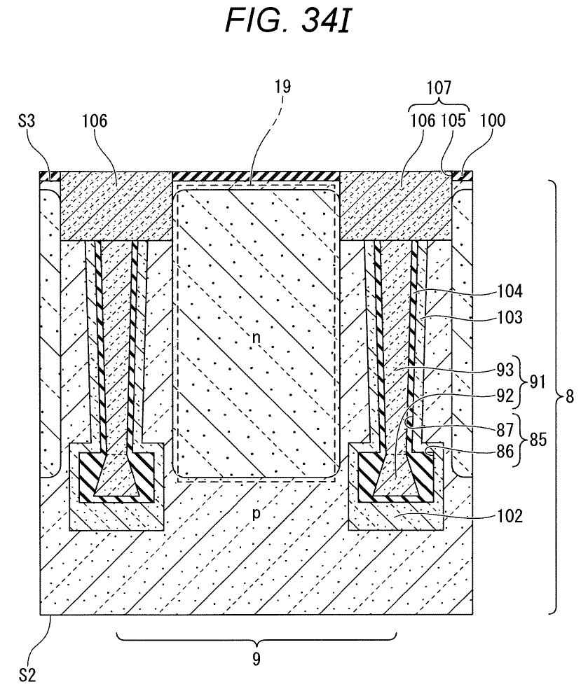

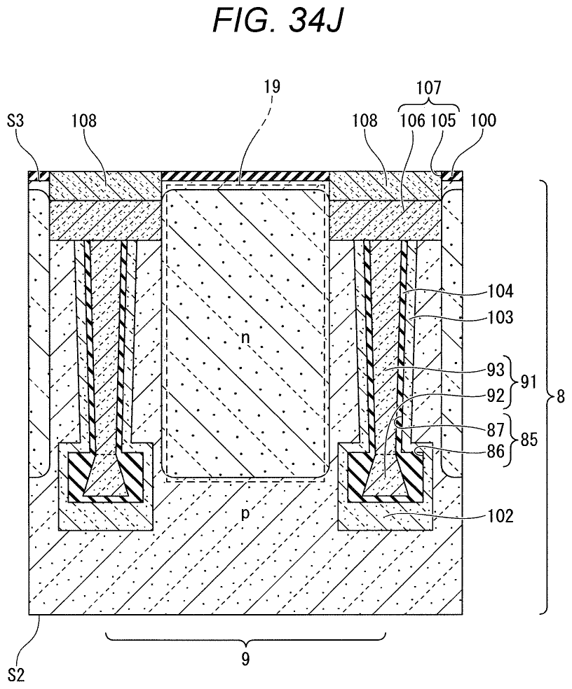

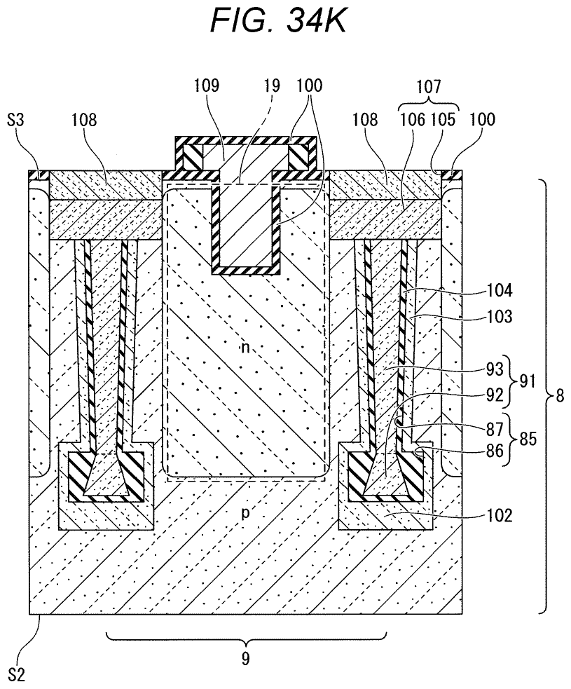

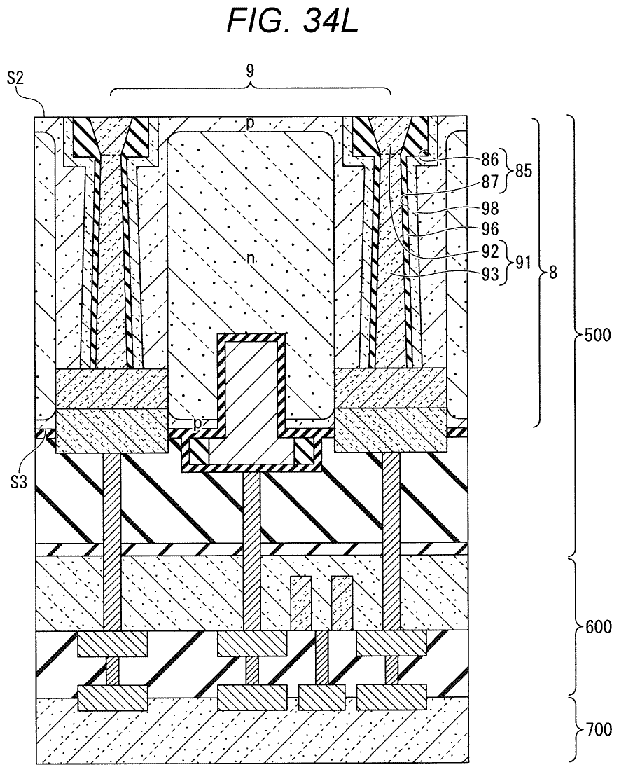

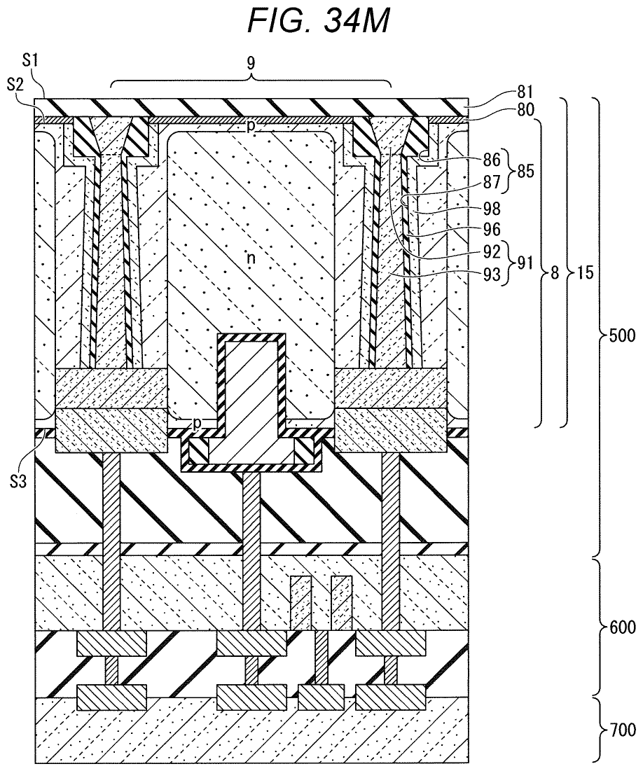

First, as illustrated in FIG. 34A, the semiconductor substrate 8 on which the photoelectric conversion portion 19 and the second trench portion 87 are formed is prepared. As the second trench portion 87, a bottomed trench portion dug from the front surface S3 side of the semiconductor substrate 8 is formed. Furthermore, a bottom surface S13 of the second trench portion 87 is formed at a position (position on the back surface S2 side) deeper than the opening portion 89 of the second trench portion 87 of the solid-state imaging device 1 illustrated in FIG. 31. As a method of forming the second trench portions 87, for example, a method of performing etching using a lithography method and a dry etching method can be adopted. FIG. 34A illustrates a case where an oxide film 100 is arranged on the front surface S3 of the semiconductor substrate 8.

Subsequently, as illustrated in FIG. 34B, a diffusion prevention film 101 is formed on the inner side surface side of the second trench portion 87. The diffusion prevention film 101 is formed to cover only the inner side surface of the second trench portion 87 by being formed to cover the inner side surface and the bottom surface of the second trench portion 87 and then removing only a portion covering the bottom surface using anisotropic etching. The diffusion prevention film 101 is a film having a high selection ratio with respect to silicon (Si) constituting the semiconductor substrate 8. As a method of forming the diffusion prevention film 101, for example, a method of forming a silicon oxide film (SiO₂) and a silicon nitride film (SiN) can be adopted. Therefore, it is possible to prevent the inner side surface of the second trench portion 87 from being scraped when the first trench portion 86 is formed in a process to be described later.

Subsequently, as illustrated in FIG. 34C, etching is performed from the front surface S3 side of the semiconductor substrate 8 to form the first trench portions 86 on the bottom surface S13 side of the second trench portions 87. As the first trench portion 86, a bottomed trench portion dug from the bottom surface S13 side of the second trench portion 87 is formed. Subsequently, as illustrated in FIG. 34D, sidewall doping for diffusing the p-type impurities from the inner side surface of the first trench portion 86 to the photoelectric conversion portion 19 side is performed, and a first pinning region 102 including a p-type semiconductor region is formed along the inner side surface of the first trench portion 86. The first pinning region 102 constitutes a part of the pinning region 98 illustrated in FIG. 31. As the method of sidewall doping, for example, a plasma doping method (PLAD method) or a solid phase diffusion method can be adopted. In particular, as will be described later, in a case where the width W₁ of the first trench portion 86 is configured to be increased toward the back surface S2 of the semiconductor substrate 8, solid phase diffusion having excellent conformality is preferable. FIG. 34D illustrates a case where the plasma doping method is adopted, and the depth of the first pinning region 102 becomes deeper on the bottom surface side than on the inner side surface side of the first trench portion 86 due to the plasma traveling straight. Subsequently, an annealing (ANL) treatment is performed to activate p-type impurities.

Subsequently, cleaning is performed to remove the diffusion prevention film 101 from the inner side surface of the second trench portion 87 as illustrated in FIG. 34E. Subsequently, sidewall doping for diffusing the p-type impurities from the inner side surface of the second trench portion 87 to the photoelectric conversion portion 19 side is performed, and a second pinning region 103 including a p-type semiconductor region is formed along the inner side surface of the second trench portion 87. Note that, as the method of sidewall doping, for example, a method different from the method used for forming the first pinning region 102 may be adopted, or the same method may be adopted. In a case where the same method is adopted, sidewall doping for forming the first pinning regions 102 and sidewall doping for forming the second pinning regions 103 may be performed simultaneously. FIG. 34E illustrates a case where the plasma doping method is adopted, and the depth of the first pinning region 102 becomes deeper on the bottom surface side of the first trench portion 86 due to the plasma traveling straight. Subsequently, an annealing treatment is performed to activate p-type impurities. Subsequently, as illustrated in FIG. 34F, an oxide film (SiO₂) 104 is formed on the inner surfaces (inner side surface, bottom surface) of the first trench portion 86 and the second trench portion 87.

Subsequently, as illustrated in FIG. 34G, the conductor portion 91 is formed in the first trench portion 86 and the second trench portion 87. The conductor portion 91 is formed such that the insides of the first trench portion 86 and the second trench portion 87 are filled with a predetermined conductor. Subsequently, as illustrated in FIG. 34H, etching is performed from the back surface S2 side of the semiconductor substrate 8 to form a groove portion 105 for forming a shallow trench isolation (STI) portion 107 illustrated in FIG. 34I on the back surface S2 side of the semiconductor substrate 8. Subsequently, as illustrated in FIG. 34I, an oxide film (SiO₂) 106 is formed in the groove portion 105. The oxide film (SiO₂) 106 is formed such that the inside of the groove portion 105 is filled with silicon oxide (SiO₂). The groove portion 105 and the oxide film (SiO₂) 106 constitute the STI portion 107.

Subsequently, as illustrated in FIG. 34J, polysilicon 108 for forming an FD diffusion layer and an FD contact is buried on the front surface S3 side of the semiconductor substrate 8. FIG. 34J illustrates a case where an embedded contact is formed in the STI portion 107. Note that the method of forming the FD diffusion layer and the structure and layout of the FD contact are not limited to the formation method and the like illustrated in FIG. 34J. Subsequently, as illustrated in FIG. 34K, a transfer gate 109 is formed. As the transfer gate 109, for example, a transfer gate of a plane type or a transfer gate of a digging type (vertical transfer) can be adopted.

Subsequently, as illustrated in FIG. 34L, after the first substrate 500 is formed, transistor formation and wiring layer formation of the SF circuit are performed, and the second substrate 600 is stacked on the first substrate 500. As the structure of the transistor, for example, a planar layout or a two-layer structure can be adopted. Subsequently, the third substrate 700 having the logic circuit is bonded to the second substrate 600. Subsequently, a portion on the back surface S2 side of the semiconductor substrate 8 is removed by using the CMP method to form the through-trench portion 85.

Subsequently, as illustrated in FIG. 34M, the pinning film 80 and the insulating film 81 are formed in this order on the back surface S2 side of the first substrate 500 (semiconductor substrate 8). Subsequently, the color filter 16 and the microlens 17 are formed in this order on the back surface S1 side of the insulating film 81.

The solid-state imaging device 1 illustrated in FIG. 31 is manufactured by such a procedure.

Here, for example, a case will be considered in which after the second substrate 600 and the third substrate 700 are stacked on the first substrate 500, the first trench portion 86 is formed by being dug from the back surface S2 side of the semiconductor substrate 8, and p-type impurities are diffused from the inner side surface side of the first trench portion 86. In this case, since the logic circuit of the third substrate 700 is weak against high temperature, the annealing (ANL) treatment cannot be performed. Therefore, p-type impurities cannot be activated, and generation of a dark current cannot be suppressed.

On the other hand, in the third embodiment, before the second substrate 600 and the third substrate 700 are stacked on the first substrate 500, the first trench portion 86 is formed by being dug from the front surface S3 side of the semiconductor substrate 8, and p-type impurities are diffused from the inner side surface side of the first trench portion 86. Therefore, since the logic circuit of the third substrate 700 is not exposed to a high temperature, an annealing treatment can be performed, p-type impurities can be activated, and generation of a dark current can be suppressed.

### 3-3 Modification Example

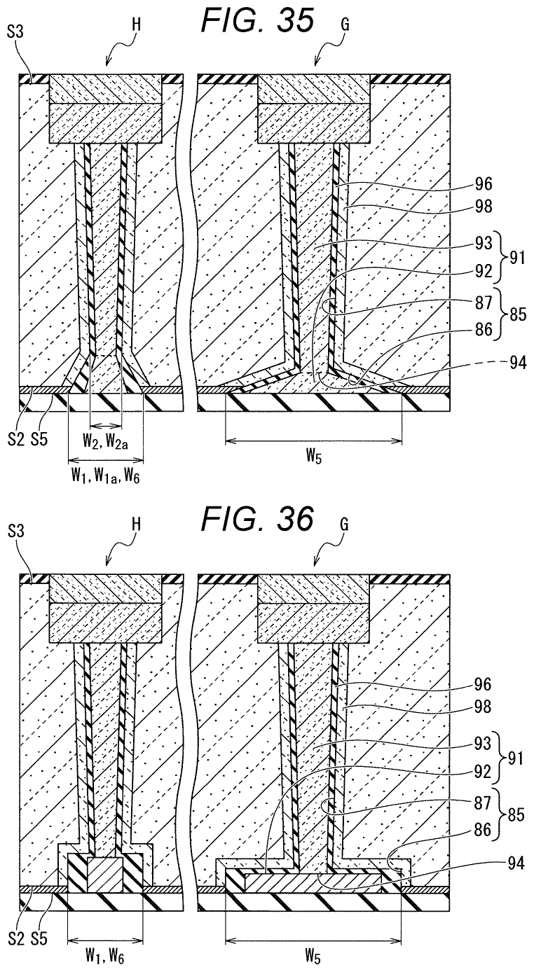

(1) In the first embodiment, an example in which the width W₁ of the first trench portion 86 is constant regardless of the position in the depth direction of the semiconductor substrate 8 has been described, but other configurations can be adopted. For example, as illustrated in FIG. 35, the width W₁ of the first trench portion 86 may be configured to be increased toward the back surface S2 side of the semiconductor substrate 8. Here, for example, as illustrated in FIGS. 34D and 34E, in a case where sidewall doping is performed first on the inner wall surface of the first trench portion 86 and then on the inner wall surface of the second trench portion 87 in this order, sidewall doping is performed twice on the inner wall surface of the first trench portion 86. On the other hand, in a case where the width W₁ of the first trench portion 86 is increased toward the back surface S2 side of the semiconductor substrate 8, it is possible to make it difficult for the p-type impurities to enter the inner wall surface of the first trench portion 86 in the second sidewall doping, and it is possible to prevent the concentration of the p-type impurities on the inner wall surface of the first trench portion 86 from becoming too high. Furthermore, as compared with a case where the width W₁ of the first trench portion 86 is constant, a range in which the first trench portion 86 is formed, that is, a range in which the groove having a relatively wide width is formed can be narrowed, and a decrease in the volume of the photoelectric conversion portion 19 can be suppressed.

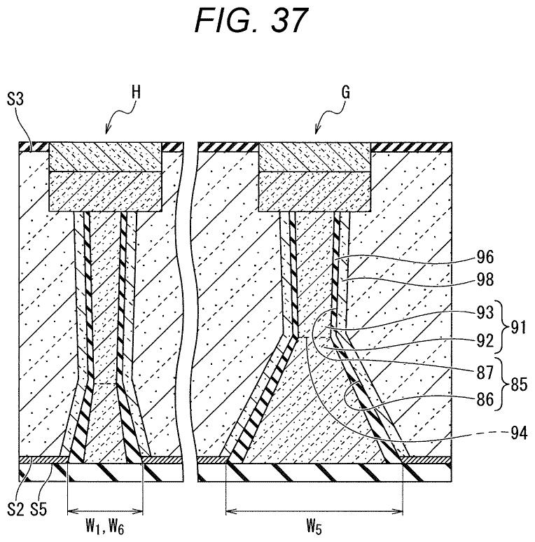

Furthermore, a difference between a taper angle of the first trench portion 86 (an angle formed by the inner wall surfaces facing each other) and a taper angle of the second trench portion 87 is desirably made as small as possible for the convenience of sidewall doping. Note that, in a case where the width W₁ of the first trench portion 86 is increased toward the back surface S2 side of the semiconductor substrate 8, a width W₁ₐ of the end portion of the first trench portion 86 on the back surface S2 side is made larger than the width W₂ₐ of the boundary portion of the second trench portion 87 with the first trench portion 86.
(2) Furthermore, in the first embodiment, an example has been described in which the first conductor portion 92 and the second conductor portion 93 include the same material, but other configurations can also be adopted. For example, as illustrated in FIG. 36, the first conductor portion 92 and the second conductor portion 93 may include different materials. As a material of the second conductor portion 93, for example, polysilicon to which at least one of phosphorus (P) and boron (B) is added can be adopted. Furthermore, examples of the material of the first conductor portion 92 include a material having a resistivity lower than that of the material of the second conductor portion 93. Therefore, the resistance value of the conductor portion 91 can be further reduced, and the potential drop of the negative bias applied from the outside of the pixel region 2 can be more appropriately suppressed. Therefore, it is possible to more appropriately suppress deterioration of shading characteristics in the pixel 9 far from the outer periphery of the pixel region 2, that is, the pixel 9 in the central portion of the pixel region 2. Examples of the material having a resistivity lower than that of the second conductor portion 93 include a metal material (tungsten (W), aluminum (Al), copper (Cu), and the like) and ITO. FIG. 36 illustrates a case where the first conductor portion 92 includes a metal material functioning as an embedded light-shielding metal. Furthermore, the first conductor portion 92 may have a configuration in which a plurality of dissimilar materials is stacked.
(3) Furthermore, in the first embodiment, an example has been described in which the interface between the first trench portion 86 and the second trench portion 87 is formed at a position (refer to FIG. 33) on the back surface S2 side of the semiconductor substrate 8 as much as possible, but other configurations can be adopted. For example, as illustrated in FIG. 37, the interface between the first trench portion 86 and the second trench portion 87 may be formed on a side closer to the front surface S3 of the semiconductor substrate 8 than the position illustrated in FIG. 33. Moreover, FIG. 37 illustrates a case where, the interface between the first trench portion 86 and the second trench portion 87 in the cross portion G is formed closer to the front surface S3 side than the interface in the slit portion H.
(4) Furthermore, in the first embodiment, an example has been described in which one color filter 16 is formed for one photoelectric conversion portion 19, but other configurations can also be adopted. For example, one color filter 16 may be formed for the 2×2, 3×3, 4×4, or 1×2 photoelectric conversion portions 19. In a case where one color filter 16 is formed for the 2×2 photoelectric conversion portions 19, for example, a Quad Bayer array can be adopted as the array of the color filters 16. Furthermore, in a case where one color filter 16 is formed for the 1×2 photoelectric conversion portions 19, for example, a configuration in which two photoelectric conversion portions 19 are formed in one pixel 9 and one color filter 16 is formed for one pixel 9, or a configuration in which one photoelectric conversion portion 19 is formed in one pixel 9 and one color filter 16 is formed for two pixels 9 can be adopted.
(5) Furthermore, the present technology is applicable to any photodetection device including not only the above-described solid-state imaging device 1 as an image sensor but also a ranging sensor, which is also referred to as a time of flight (ToF) sensor and measures a distance, and the like. The ranging sensor is a sensor that emits irradiation light toward an object, detects reflected light obtained by the irradiation light being reflected by a front surface of the object, and calculates a distance to the object on the basis of a flight time from the emission of the irradiation light to the reception of the reflected light. As a light receiving pixel structure of the ranging sensor, the structure of the pixel 9 described above may be adopted.

### 4. Fourth Embodiment: Application Example to Electronic Apparatus

The technology (present technology) according to the present disclosure may be applied to various electronic apparatuses.

FIG. 38 is a diagram illustrating an example of a schematic configuration of an imaging device (video camera, digital still camera, or the like) as an electronic apparatus to which the present technology is applied.

As illustrated in FIG. 38, an imaging device 1000 includes a lens group 1001, a solid-state imaging device 1002 (the solid-state imaging device 1 according to the first embodiment), a digital signal processor (DSP) circuit 1003, a frame memory 1004, a monitor 1005, and a memory 1006. The DSP circuit 1003, the frame memory 1004, the monitor 1005, and the memory 1006 are connected to each other via a bus line 1007.

The lens group 1001 guides incident light (image light) from a subject to the solid-state imaging device 1002 to form an image on a light receiving surface (pixel region) of the solid-state imaging device 1002.

The solid-state imaging device 1002 includes the CMOS image sensor of the first embodiment described above. The solid-state imaging device 1002 converts an amount of incident light an image of which is formed on the light receiving surface by the lens group 1001 into an electrical signal in units of pixels, and supplies the electrical signal to the DSP circuit 1003 as a pixel signal.

The DSP circuit 1003 performs predetermined image processing on the pixel signal supplied from the solid-state imaging device 1002. Then, the DSP circuit 1003 supplies an image signal subjected to the image processing to the frame memory 1004 in units of frames, and temporarily stores the image signal in the frame memory 1004.

The monitor 1005 includes, for example, a panel type display device such as a liquid crystal panel or an organic electro luminescence (EL) panel. The monitor 1005 displays an image (moving image) of the subject on the basis of the pixel signal in units of frames temporarily stored in the frame memory 1004.

The memory 1006 includes a DVD, a flash memory, and the like. The memory 1006 reads and records the pixel signal in units of frames temporarily stored in the frame memory 1004.

Note that the electronic apparatus to which the solid-state imaging device 1 can be applied is not limited to the imaging device 1000, and the solid-state imaging device 1 can also be applied to other electronic apparatuses. Furthermore, the solid-state imaging device 1 according to the first embodiment is used as the solid-state imaging device 1002, but other configurations can also be employed. For example, a configuration may be adopted in which another photodetection device to which the present technology is applied, such as the solid-state imaging device 1 according to the second embodiment, the solid-state imaging device 1 according to the third embodiment, the solid-state imaging device 1 according to the modification examples of the first to third embodiments, and the like is used.

Note that, the present technology may also have the following configurations.
(1)
A photodetection device including:
a semiconductor substrate;
a plurality of photoelectric conversion portions formed in a two-dimensional array on the semiconductor substrate;
a plurality of microlenses arranged on a first surface side as a light receiving surface of the semiconductor substrate; and
a through-trench portion that is formed in at least a part of a region between the photoelectric conversion portions of the semiconductor substrate and penetrates the semiconductor substrate in a thickness direction of the semiconductor substrate,
in which the through-trench portion has
a first trench portion that is formed on the first surface side of the semiconductor substrate and has an opening portion on the first surface, and
a second trench portion that is formed on a second surface side opposite to the first surface and has opening portions respectively on a bottom surface of the first trench portion and the second surface,
a width of the first trench portion is wider than a width of the second trench portion, and
the photodetection device further comprises
a first conductor portion that is arranged in the first trench portion and includes a first conductor;
a second conductor portion which is arranged in the second trench portion, of which an end portion on the first surface side is in contact with the first conductor portion, and which includes a second conductor different from the first conductor; and
an insulating film arranged between an inner side surface of the second trench portion and the second conductor portion.
(2)
The photodetection device according to (1),
in which the width of the first trench portion is larger than the width of the second trench portion by 100 nm or more.
(3)
The photodetection device according to (1) or (2),
in which the end portion of the second conductor portion on the first surface side protrudes from the opening portion on the bottom surface of the first trench portion to the microlens side, and
the first conductor portion is in contact with the end portion, which protrudes from the opening portion on the bottom surface side, of the second conductor portion on the first surface side, in the first trench portion.
(4)
The photodetection device according to any one of (1) to (3), further including:
a fixed charge film that continuously covers an inner surface of the first trench portion and the first surface of the semiconductor substrate.
(5)
The photodetection device according to any one of (1) to (4),
in which the second conductor is polysilicon to which at least one of phosphorus and boron is added.
(6)
The photodetection device according to any one of (1) to (5),
in which the first conductor is a material having a resistivity lower than a resistivity of the second conductor.
(7)
The photodetection device according to (6),
in which the first conductor is a metal material or ITO. (8)
The photodetection device according to any one of (1) to (7),
in which, in a case of being viewed from a thickness direction of the semiconductor substrate, each of a center of the first trench portion in a width direction and a center of the first conductor portion in the width direction is positioned closer to a center portion side of the two-dimensional array than a center of the second trench portion in the width direction.
(9)
The photodetection device according to any one of (1) to (8), further including:
a diffraction structure that diffracts incident light, on the first surface side of the semiconductor substrate.
(10)
The photodetection device according to any one of (1) to (9),
in which the through-trench portion is formed in one or both of a region extending along a row direction and a region extending along a column direction of the two-dimensional array, among regions between the photoelectric conversion portions of the semiconductor substrate. (11)
The photodetection device according to any one of (1) to (9),
in which, in a case of being viewed from a thickness direction of the semiconductor substrate, the through-trench portion is formed only at a position where a region extending along a row direction and a region extending along a column direction of the two-dimensional array intersect each other among regions between the photoelectric conversion portions of the semiconductor substrate, and
the photodetection device further includes
a third conductor portion that is arranged between the first conductor portion and the microlens, electrically connects the first conductor portions, and includes a third conductor.
(12)
The photodetection device according to (11),
in which the third conductor is the same material as the first conductor or a material having a resistivity lower than a resistivity of the second conductor.
(13)
The photodetection device according to (12),
in which the third conductor is a metal material or ITO. (14)
The photodetection device according to any one of (1) to (13),
in which, in a case of being viewed from a thickness direction of the semiconductor substrate, the third conductor portion is formed at one or both of a position overlapping the region extending along the row direction and a position overlapping the region extending along the column direction of the two-dimensional array, among the regions between the photoelectric conversion portions of the semiconductor substrate.

(15)
The photodetection device according to any one of (1) to (5),
in which the end portion of the second conductor portion on the first surface side is recessed to the second surface side from the bottom surface of the first trench portion such that the end portion is positioned in the second trench portion, and
the first conductor portion enters the second trench portion, and is in contact with the end portion of the second conductor portion on the first surface side.
(16)
The photodetection device according to (15), further including:
an interlayer film that is arranged between the first conductor portion and an inner side surface of the second trench portion,
in which the interlayer film is an insulating film, a fixed charge film, or a multilayer film in which the insulating film and the fixed charge film are stacked.
(17)
A photodetection device including:
a semiconductor substrate;
a plurality of photoelectric conversion portions formed in a two-dimensional array on the semiconductor substrate;
a plurality of microlenses arranged on a first surface side as a light receiving surface of the semiconductor substrate;
a through-trench portion that is formed in at least a part of a region between the photoelectric conversion portions of the semiconductor substrate and penetrates the semiconductor substrate in a thickness direction of the semiconductor substrate;
a fixed charge film that is arranged to cover the first surface of the semiconductor substrate;
a first conductor portion that is arranged between the fixed charge film and the microlens and includes a first conductor;
a second conductor portion which is arranged in the through-trench portion, of which an end portion on the first surface side is in contact with the first conductor portion, and which includes a second conductor different from the first conductor; and
an insulating film arranged between an inner side surface of the through-trench portion and the second conductor portion,
in which an end portion of the insulating film on the first surface side protrudes from an opening portion on the first surface side of the through-trench portion to the microlens side.
(18)
The photodetection device according to (17),
in which the first conductor portion is a transparent conductive film arranged between the photoelectric conversion portion and the microlens.
(19)
The photodetection device according to (17),
in which the first conductor portion is an inter-pixel light shielding portion arranged between the through-trench portion and the microlens.
(20)
The photodetection device according to any one of (17) to (19),
in which the end portion of the second conductor portion on the first surface side protrudes from the first surface to the microlens side such that a height of the second conductor portion from the first surface of the semiconductor substrate is the same as a height of the insulating film from the first surface of the semiconductor substrate.
(21)
The photodetection device according to (17),
in which the end portion of the second conductor portion on the first surface side protrudes from the first surface to the microlens side such that a height of the second conductor portion from the first surface of the semiconductor substrate is higher than a height of the insulating film from the first surface, and
the first conductor portion is in contact with a top surface and a side surface of the end portion of the second conductor portion on the first surface side.
(22)
The photodetection device according to any one of (17) to (21),
in which a plurality of types of conductors are arranged in the through-trench portion.
(23)
The photodetection device according to any one of (17) to (22),
in which a recessed structure recessed to a second surface side opposite to the first surface is provided on the first surface of the semiconductor substrate.
(24)
The photodetection device according to any one of (17) to (23),
in which a plurality of the microlenses includes one shared microlens arranged for one photoelectric conversion portion group including two or more adjacent photoelectric conversion portions.
(25)
The photodetection device according to any one of (17) to (24),
in which the through-trench portion has protrusion portions that protrude to an inside of the photoelectric conversion portion, at portions facing each other with the photoelectric conversion portion interposed therebetween.
(26)
The photodetection device according to any one of (17) to (25),
in which a bottomed trench portion that is formed in a region other than a region in which the through-trench portion is formed among the regions between the photoelectric conversion portions and has an opening portion only on one of the first surface or a second surface on a side opposite to the first surface of the semiconductor substrate is provided.
(27)
The photodetection device according to any one of (17) to (26),
in which a stacked structure in which a first substrate having the semiconductor substrate, a second semiconductor substrate having a pixel transistor, and a third semiconductor substrate having a logic circuit are stacked in this order is provided.
(28)
A photodetection device including:
a semiconductor substrate;
a plurality of photoelectric conversion portions formed in a two-dimensional array on the semiconductor substrate;
a plurality of microlenses arranged on a first surface side as a light receiving surface of the semiconductor substrate; and
a through-trench portion that is formed in at least a part of a region between the photoelectric conversion portions of the semiconductor substrate and penetrates the semiconductor substrate in a thickness direction of the semiconductor substrate,
in which the through-trench portion has
a first trench portion that is formed on the first surface side of the semiconductor substrate and has an opening portion on the first surface, and
a second trench portion that is formed on a second surface side opposite to the first surface and has opening portions respectively on a bottom surface of the first trench portion and the second surface,
a width of the first trench portion is wider than a width of a boundary portion of the second trench portion with the first trench portion, and
the photodetection device further includes
a conductor portion arranged in the first trench portion and the second trench portion; and
an insulating film arranged between an inner side surface of the first trench portion and the conductor portion and between an inner side surface of the second trench portion and the conductor portion,
the photoelectric conversion portion includes a first conductivity type semiconductor region, and
the semiconductor substrate has a pinning region that is formed between the photoelectric conversion portion and the through-trench portion to be continuously along the inner side surface of the first trench portion and the inner side surface of the second trench portion and that includes a semiconductor region of a conductivity type opposite to the first conductivity type.
(29)
The photodetection device according to (28),
in which, in a case of being viewed from a thickness direction of the semiconductor substrate, at a position where a region extending along a row direction and a region extending along a column direction of the two-dimensional array intersect each other among the regions between the photoelectric conversion portions of the semiconductor substrate, an interface between the first trench portion and the second trench portion is formed on a side closer to the first surface than the interface at another position.
(30)
The photodetection device according to (28) or (29),
in which a width of the first trench portion is increased toward the first surface side of the semiconductor substrate, and a width of an end portion of the first trench portion on the first surface side is wider than a width of a boundary portion of the second trench portion with the first trench portion.
(31)
The photodetection device according to any one of (28) to (30),
in which the conductor portion includes a first conductor portion formed on the first surface side of the semiconductor substrate, and a second conductor portion formed on the second surface side of the semiconductor substrate, and
the first conductor portion and the second conductor portion include different materials.
(32)
The photodetection device according to (31),
in which the material of the first conductor portion is a material having a resistivity lower than a resistivity of the material of the second conductor portion.
(33)
The photodetection device according to (31) or (32),
in which the material of the second conductor portion is polysilicon to which at least one of phosphorus and boron is added.
(34)
An electronic apparatus including:
a photodetection device including
a semiconductor substrate,
a plurality of photoelectric conversion portions formed in a two-dimensional array on the semiconductor substrate,
a plurality of microlenses arranged on a first surface side as a light receiving surface of the semiconductor substrate, and
a through-trench portion that is formed in at least a part of a region between the photoelectric conversion portions of the semiconductor substrate and penetrates the semiconductor substrate in a thickness direction of the semiconductor substrate,
in which the through-trench portion has a first trench portion that is formed on the first surface side of the semiconductor substrate and has an opening portion on the first surface, and a second trench portion that is formed on a second surface side opposite to the first surface and has opening portions respectively on a bottom surface of the first trench portion and the second surface,
a width of the first trench portion is wider than a width of the second trench portion, and
the photodetection device further includes
a first conductor portion that is arranged in the first trench portion and includes a first conductor,
a second conductor portion which is arranged in the second trench portion, of which an end portion on the first surface side is in contact with the first conductor portion, and which includes a second conductor different from the first conductor, and
an insulating film arranged between an inner side surface of the second trench portion and the second conductor portion.
(35)
An electronic apparatus including:
a photodetection device including
a semiconductor substrate,
a plurality of photoelectric conversion portions formed in a two-dimensional array on the semiconductor substrate,
a plurality of microlenses arranged on a first surface side as a light receiving surface of the semiconductor substrate,
a through-trench portion that is formed in at least a part of a region between the photoelectric conversion portions of the semiconductor substrate and penetrates the semiconductor substrate in a thickness direction of the semiconductor substrate,
a fixed charge film that is arranged to cover the first surface of the semiconductor substrate,
a first conductor portion that is arranged between the fixed charge film and the microlens and includes a first conductor,
a second conductor portion which is arranged in the through-trench portion, of which an end portion on the first surface side is in contact with the first conductor portion, and which includes a second conductor different from the first conductor, and
an insulating film arranged between an inner side surface of the through-trench portion and the second conductor portion,
in which an end portion of the insulating film on the first surface side protrudes from an opening portion on the first surface side of the through-trench portion to the microlens side.
(36)
An electronic apparatus including:
a photodetection device including
a semiconductor substrate,
a plurality of photoelectric conversion portions formed in a two-dimensional array on the semiconductor substrate,
a plurality of microlenses arranged on a first surface side as a light receiving surface of the semiconductor substrate, and
a through-trench portion that is formed in at least a part of a region between the photoelectric conversion portions of the semiconductor substrate and penetrates the semiconductor substrate in a thickness direction of the semiconductor substrate,
in which the through-trench portion has a first trench portion that is formed on the first surface side of the semiconductor substrate and has an opening portion on the first surface, and a second trench portion that is formed on a second surface side opposite to the first surface and has opening portions respectively on a bottom surface of the first trench portion and the second surface,
a width of the first trench portion is wider than a width of a boundary portion of the second trench portion with the first trench portion, and
the photodetection device further includes
a conductor portion arranged in the first trench portion and the second trench portion, and
an insulating film arranged between an inner side surface of the first trench portion and the conductor portion and between an inner side surface of the second trench portion and the conductor portion,
the photoelectric conversion portion includes a first conductivity type semiconductor region, and
the semiconductor substrate has a pinning region that is formed between the photoelectric conversion portion and the through-trench portion to be continuously along the inner side surface of the first trench portion and the inner side surface of the second trench portion and that includes a semiconductor region of a conductivity type opposite to the first conductivity type.

### REFERENCE SIGNS LIST

1 Solid-state imaging device
2 Pixel region
3 Vertical drive circuit
4 Column signal processing circuit
5 Horizontal drive circuit
6 Output circuit
7 Control circuit
8 Semiconductor substrate
9 Pixel
10 Pixel drive wiring
11 Vertical signal line
12 Horizontal signal line
13 Fixed charge film
14 Insulating film
15 Light receiving layer
16 Color filter
17 Microlens
18 Wiring layer
19 Photoelectric conversion portion
20 p-type semiconductor region
21 n-type semiconductor region
22 p-well region
23 Through-trench portion
24 First trench portion
25 Second trench portion
26 Opening portion
27 End portion
28 Opening portion
29 Opening portion
30 Second conductor portion
31 Insulating film
32 End portion
33 First conductor portion
34 Interlayer insulating film
35 Groove
36 Conductor layer
37 Diffraction structure
38 Third conductor portion
39 End portion
40 Interlayer film
49 Fixed charge film
50 Anti-reflective film
51 Transparent conductive film
51a First transparent conductive film
51b Second transparent conductive film
52 Through-trench portion
53 Conductor portion
54 End portion
55 Opening portion
56 Insulating film
57 End portion
58 Inter-pixel light shielding portion
59 First light shielding film
60 Second light shielding film
61, 62 Insulating film
63 Recessed structure
64 Photoelectric conversion portion group
65 Opening portion
66 Trench portion
67 Protrusion portion
68 Pixel transistor
69 Logic circuit
70 Transfer gate
71 Floating diffusion
72 Pad portion
80 Pinning film
81 Insulating film
82 p-type semiconductor region
83 n-type semiconductor region
84 p-type semiconductor region
85 Through-trench portion
86 First trench portion
87 Second trench portion
88 Opening portion
89 Opening portion
90 Opening portion
91 Conductor portion
92 First conductor portion
93 Second conductor portion
94 End portion
95 End portion
96 Insulating film
97 End portion
98 Pinning region
99 Inter-pixel light shielding portion
100 Oxide film
101 Diffusion prevention film
102 First pinning region
103 Second pinning region
104 Oxide film
105 Groove portion
106 Oxide film
107 STI portion
108 Polysilicon
109 Transfer gate
500 First substrate
600 Second semiconductor substrate
700 Third semiconductor substrate
1000 Imaging device
1001 Lens group
1002 Solid-state imaging device
1003 DSP circuit
1004 Frame memory
1005 Monitor
1006 Memory
1007 Bus line

1. A photodetection device comprising:
a semiconductor substrate;
a plurality of photoelectric conversion portions formed in a two-dimensional array on the semiconductor substrate;
a plurality of microlenses arranged on a first surface side as a light receiving surface of the semiconductor substrate; and
a through-trench portion that is formed in at least a part of a region between the photoelectric conversion portions of the semiconductor substrate and penetrates the semiconductor substrate in a thickness direction of the semiconductor substrate,
wherein the through-trench portion has
a first trench portion that is formed on the first surface side of the semiconductor substrate and has an opening portion on the first surface, and
a second trench portion that is formed on a second surface side opposite to the first surface and has opening portions respectively on a bottom surface of the first trench portion and the second surface,
a width of the first trench portion is wider than a width of the second trench portion, and
the photodetection device further comprises
a first conductor portion that is arranged in the first trench portion and includes a first conductor;
a second conductor portion which is arranged in the second trench portion, of which an end portion on the first surface side is in contact with the first conductor portion, and which includes a second conductor different from the first conductor; and
an insulating film arranged between an inner side surface of the second trench portion and the second conductor portion.

2. The photodetection device according to claim 1,
wherein the width of the first trench portion is larger than the width of the second trench portion by 100 nm or more.

3. The photodetection device according to claim 1,
wherein the end portion of the second conductor portion on the first surface side protrudes from the opening portion on the bottom surface of the first trench portion to the microlens side, and
the first conductor portion is in contact with the end portion, which protrudes from the opening portion on the bottom surface side, of the second conductor portion on the first surface side, in the first trench portion.

4. The photodetection device according to claim 1, further comprising:
a fixed charge film that continuously covers an inner surface of the first trench portion and the first surface of the semiconductor substrate.

5. The photodetection device according to claim 1,
wherein the second conductor is polysilicon to which at least one of phosphorus and boron is added.

6. The photodetection device according to claim 1,
wherein the first conductor is a material having a resistivity lower than a resistivity of the second conductor.

7. The photodetection device according to claim 6,
wherein the first conductor is a metal material or ITO.

8. The photodetection device according to claim 1,
wherein, in a case of being viewed from a thickness direction of the semiconductor substrate, each of a center of the first trench portion in a width direction and a center of the first conductor portion in the width direction is positioned closer to a center portion side of the two-dimensional array than a center of the second trench portion in the width direction.

9. The photodetection device according to claim 1, further comprising:
a diffraction structure that diffracts incident light, on the first surface side of the semiconductor substrate.

10. The photodetection device according to claim 1,
wherein the through-trench portion is formed in one or both of a region extending along a row direction and a region extending along a column direction of the two-dimensional array, among regions between the photoelectric conversion portions of the semiconductor substrate.

11. The photodetection device according to claim 1,
wherein, in a case of being viewed from a thickness direction of the semiconductor substrate, the through-trench portion is formed only at a position where a region extending along a row direction and a region extending along a column direction of the two-dimensional array intersect each other among regions between the photoelectric conversion portions of the semiconductor substrate, and
the photodetection device further comprises
a third conductor portion that is arranged between the first conductor portion and the microlens, electrically connects the first conductor portions, and includes a third conductor.

12. The photodetection device according to claim 11,
wherein the third conductor is the same material as the first conductor or a material having a resistivity lower than a resistivity of the second conductor.

13. The photodetection device according to claim 12,
wherein the third conductor is a metal material or ITO.

14. The photodetection device according to claim 11,
wherein, in a case of being viewed from a thickness direction of the semiconductor substrate, the third conductor portion is formed at one or both of a position overlapping the region extending along the row direction and a position overlapping the region extending along the column direction of the two-dimensional array, among the regions between the photoelectric conversion portions of the semiconductor substrate.

15. The photodetection device according to claim 1,
wherein the end portion of the second conductor portion on the first surface side is recessed to the second surface side from the bottom surface of the first trench portion such that the end portion is positioned in the second trench portion, and
the first conductor portion enters the second trench portion, and is in contact with the end portion of the second conductor portion on the first surface side.

16. The photodetection device according to claim 15, further comprising:
an interlayer film that is arranged between the first conductor portion and an inner side surface of the second trench portion,
wherein the interlayer film is an insulating film, a fixed charge film, or a multilayer film in which the insulating film and the fixed charge film are stacked.

17. A photodetection device comprising:
a semiconductor substrate;
a plurality of photoelectric conversion portions formed in a two-dimensional array on the semiconductor substrate;
a plurality of microlenses arranged on a first surface side as a light receiving surface of the semiconductor substrate;
a through-trench portion that is formed in at least a part of a region between the photoelectric conversion portions of the semiconductor substrate and penetrates the semiconductor substrate in a thickness direction of the semiconductor substrate;
a fixed charge film that is arranged to cover the first surface of the semiconductor substrate;
a first conductor portion that is arranged between the fixed charge film and the microlens and includes a first conductor;
a second conductor portion which is arranged in the through-trench portion, of which an end portion on the first surface side is in contact with the first conductor portion, and which includes a second conductor different from the first conductor; and
an insulating film arranged between an inner side surface of the through-trench portion and the second conductor portion,
wherein an end portion of the insulating film on the first surface side protrudes from an opening portion on the first surface side of the through-trench portion to the microlens side.

18. The photodetection device according to claim 17,
wherein the first conductor portion is a transparent conductive film arranged between the photoelectric conversion portion and the microlens.

19. The photodetection device according to claim 17,
wherein the first conductor portion is an inter-pixel light shielding portion arranged between the through-trench portion and the microlens.

20. The photodetection device according to claim 17,
wherein the end portion of the second conductor portion on the first surface side protrudes from the first surface to the microlens side such that a height of the second conductor portion from the first surface of the semiconductor substrate is the same as a height of the insulating film from the first surface of the semiconductor substrate.

21. The photodetection device according to claim 17,
wherein the end portion of the second conductor portion on the first surface side protrudes from the first surface to the microlens side such that a height of the second conductor portion from the first surface of the semiconductor substrate is higher than a height of the insulating film from the first surface, and
the first conductor portion is in contact with a top surface and a side surface of the end portion of the second conductor portion on the first surface side.

22. The photodetection device according to claim 17,
wherein a plurality of types of conductors are arranged in the through-trench portion.

23. The photodetection device according to claim 17,
wherein a recessed structure recessed to a second surface side opposite to the first surface is provided on the first surface of the semiconductor substrate.

24. The photodetection device according to claim 17,
wherein a plurality of the microlenses includes one shared microlens arranged for one photoelectric conversion portion group including two or more adjacent photoelectric conversion portions.

25. The photodetection device according to claim 17,
wherein the through-trench portion has protrusion portions that protrude to an inside of the photoelectric conversion portion, at portions facing each other with the photoelectric conversion portion interposed therebetween.

26. The photodetection device according to claim 17,
wherein a bottomed trench portion that is formed in a region other than a region in which the through-trench portion is formed among the regions between the photoelectric conversion portions and has an opening portion only on one of the first surface or a second surface on a side opposite to the first surface of the semiconductor substrate is provided.

27. The photodetection device according to claim 17,
wherein a stacked structure in which a first substrate having the semiconductor substrate, a second semiconductor substrate having a pixel transistor, and a third semiconductor substrate having a logic circuit are stacked in this order is provided.

28. A photodetection device comprising:
a semiconductor substrate;
a plurality of photoelectric conversion portions formed in a two-dimensional array on the semiconductor substrate;
a plurality of microlenses arranged on a first surface side as a light receiving surface of the semiconductor substrate; and
a through-trench portion that is formed in at least a part of a region between the photoelectric conversion portions of the semiconductor substrate and penetrates the semiconductor substrate in a thickness direction of the semiconductor substrate,
wherein the through-trench portion has
a first trench portion that is formed on the first surface side of the semiconductor substrate and has an opening portion on the first surface, and
a second trench portion that is formed on a second surface side opposite to the first surface and has opening portions respectively on a bottom surface of the first trench portion and the second surface,
a width of the first trench portion is wider than a width of a boundary portion of the second trench portion with the first trench portion, and
the photodetection device further comprises
a conductor portion arranged in the first trench portion and the second trench portion; and
an insulating film arranged between an inner side surface of the first trench portion and the conductor portion and between an inner side surface of the second trench portion and the conductor portion,
the photoelectric conversion portion includes a first conductivity type semiconductor region, and
the semiconductor substrate has a pinning region that is formed between the photoelectric conversion portion and the through-trench portion to be continuously along the inner side surface of the first trench portion and the inner side surface of the second trench portion and that includes a semiconductor region of a conductivity type opposite to the first conductivity type.

29. The photodetection device according to claim 28,
wherein, in a case of being viewed from a thickness direction of the semiconductor substrate, at a position where a region extending along a row direction and a region extending along a column direction of the two-dimensional array intersect each other among the regions between the photoelectric conversion portions of the semiconductor substrate, an interface between the first trench portion and the second trench portion is formed on a side closer to the first surface than the interface at another position.

30. The photodetection device according to claim 28,
wherein a width of the first trench portion is increased toward the first surface side of the semiconductor substrate, and a width of an end portion of the first trench portion on the first surface side is wider than a width of a boundary portion of the second trench portion with the first trench portion.

31. The photodetection device according to claim 28,
wherein the conductor portion includes a first conductor portion formed on the first surface side of the semiconductor substrate, and a second conductor portion formed on the second surface side of the semiconductor substrate, and
the first conductor portion and the second conductor portion include different materials.

32. The photodetection device according to claim 31,
wherein the material of the first conductor portion is a material having a resistivity lower than a resistivity of the material of the second conductor portion.

33. The photodetection device according to claim 31,
wherein the material of the second conductor portion is polysilicon to which at least one of phosphorus and boron is added.

34. An electronic apparatus comprising:
a photodetection device including
a semiconductor substrate,
a plurality of photoelectric conversion portions formed in a two-dimensional array on the semiconductor substrate,
a plurality of microlenses arranged on a first surface side as a light receiving surface of the semiconductor substrate, and
a through-trench portion that is formed in at least a part of a region between the photoelectric conversion portions of the semiconductor substrate and penetrates the semiconductor substrate in a thickness direction of the semiconductor substrate,
wherein the through-trench portion has a first trench portion that is formed on the first surface side of the semiconductor substrate and has an opening portion on the first surface, and a second trench portion that is formed on a second surface side opposite to the first surface and has opening portions respectively on a bottom surface of the first trench portion and the second surface,
a width of the first trench portion is wider than a width of the second trench portion, and
the photodetection device further includes
a first conductor portion that is arranged in the first trench portion and includes a first conductor,
a second conductor portion which is arranged in the second trench portion, of which an end portion on the first surface side is in contact with the first conductor portion, and which includes a second conductor different from the first conductor, and
an insulating film arranged between an inner side surface of the second trench portion and the second conductor portion.

35. An electronic apparatus comprising:
a photodetection device including
a semiconductor substrate,
a plurality of photoelectric conversion portions formed in a two-dimensional array on the semiconductor substrate,
a plurality of microlenses arranged on a first surface side as a light receiving surface of the semiconductor substrate,
a through-trench portion that is formed in at least a part of a region between the photoelectric conversion portions of the semiconductor substrate and penetrates the semiconductor substrate in a thickness direction of the semiconductor substrate,
a fixed charge film that is arranged to cover the first surface of the semiconductor substrate,
a first conductor portion that is arranged between the fixed charge film and the microlens and includes a first conductor,
a second conductor portion which is arranged in the through-trench portion, of which an end portion on the first surface side is in contact with the first conductor portion, and which includes a second conductor different from the first conductor, and
an insulating film arranged between an inner side surface of the through-trench portion and the second conductor portion,
wherein an end portion of the insulating film on the first surface side protrudes from an opening portion on the first surface side of the through-trench portion to the microlens side.

36. An electronic apparatus comprising:
a photodetection device including
a semiconductor substrate,
a plurality of photoelectric conversion portions formed in a two-dimensional array on the semiconductor substrate,
a plurality of microlenses arranged on a first surface side as a light receiving surface of the semiconductor substrate, and
a through-trench portion that is formed in at least a part of a region between the photoelectric conversion portions of the semiconductor substrate and penetrates the semiconductor substrate in a thickness direction of the semiconductor substrate,
wherein the through-trench portion has a first trench portion that is formed on the first surface side of the semiconductor substrate and has an opening portion on the first surface, and a second trench portion that is formed on a second surface side opposite to the first surface and has opening portions respectively on a bottom surface of the first trench portion and the second surface,
a width of the first trench portion is wider than a width of a boundary portion of the second trench portion with the first trench portion, and
the photodetection device further includes
a conductor portion arranged in the first trench portion and the second trench portion, and
an insulating film arranged between an inner side surface of the first trench portion and the conductor portion and between an inner side surface of the second trench portion and the conductor portion,
the photoelectric conversion portion includes a first conductivity type semiconductor region, and
the semiconductor substrate has a pinning region that is formed between the photoelectric conversion portion and the through-trench portion to be continuously along the inner side surface of the first trench portion and the inner side surface of the second trench portion and that includes a semiconductor region of a conductivity type opposite to the first conductivity type.
